(19) United States
(12) Patent Application Publication
(10) Pub. No.: US 2018/0259591 A1
(43) Pub. Date: Sep. 13, 2018

(54) SUPPORT STRUCTURE FOR A GUIDED SURFACE WAVEGUIDE PROBE

(71) Applicant: CPG Technologies, LLC, Italy, TX (US)

(72) Inventors: James F. Corum, Morgantown, WV (US); Kenneth L. Corum, Plymouth, NH (US); Wes Pogorzelski, Scarborough (CA); Christopher R. Lamon, Southlake, TX (US); James M. Salvitti, JR., Fort Worth, TX (US); Robert S. Galloway, JR., Keller, TX (US)

(21) Appl. No.: 15/911,811

(22) Filed: Mar. 5, 2018

Related U.S. Application Data
(60) Provisional application No. 62/468,163, filed on Mar. 7, 2017.

(51) Int. Cl. G01R 33/00; G01R 33/02; H01P 5/08; H01Q 1/12; H02J 50/12

(52) U.S. Cl. CPC G01R 33/0047; G01R 33/02; H02J 50/12; H01Q 1/1242; H01P 5/082

(57) ABSTRACT

Disclosed is a support structure for a guided surface waveguide probe. In some embodiments, the support structure includes vertically oriented corner columns that define outer corners of the structure, vertically oriented intermediate columns that define portions of outer sides of the structure, each intermediate column being positioned between a pair of corner columns, framing members that extend between the corner columns and the intermediate columns, plates located at junctions between the framing members and the columns, and fasteners located at the junctions that secure the framing members and the plates to the corner columns and the intermediate columns, and that secure the framing members to the plates, wherein the corner columns, intermediate columns, framing members, plates, and fasteners are all made of a non-conductive material.

### CROSS-REFERENCE TO RELATED APPLICATION

This application claims priority to co-pending U.S. Provisional Application Ser. No. 62/468,163, filed Mar. 7, 2017, which is hereby incorporated by reference herein in its entirety.

### BACKGROUND

For over a century, signals transmitted by radio waves involved radiation fields launched using conventional antenna structures. In contrast to radio science, electrical power distribution systems in the last century involved the transmission of energy guided along electrical conductors. This understanding of the distinction between radio frequency (RF) and power transmission has existed since the early 1900's.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the disclosure. Moreover, in the drawings, like reference numerals designate corresponding parts throughout the several views.

FIG. 1 is a chart that depicts field strength as a function of distance for a guided electromagnetic field and a radiated electromagnetic field.

FIG. 2 is a drawing that illustrates a propagation interface with two regions employed for transmission of a guided surface wave according to various embodiments of the present disclosure.

FIG. 3 is a drawing that illustrates a guided surface waveguide probe disposed with respect to a propagation interface of FIG. 2 according to various embodiments of the present disclosure.

FIG. 4 is a plot of an example of the magnitudes of close-in and far-out asymptotes of first order Hankel functions according to various embodiments of the present disclosure.

FIGS. 5A and 5B are drawings that illustrate a complex angle of incidence of an electric field synthesized by a guided surface waveguide probe according to various embodiments of the present disclosure.

FIG. 6 is a graphical representation illustrating the effect of elevation of a charge terminal on the location where the electric field of FIG. 5A intersects with the lossy conducting medium at a Brewster angle according to various embodiments of the present disclosure.

FIGS. 7A through 7C are graphical representations of examples of guided surface waveguide probes according to various embodiments of the present disclosure.

FIGS. 8A through 8C are graphical representations illustrating examples of equivalent image plane models of the guided surface waveguide probe of FIGS. 3 and 7A-7C according to various embodiments of the present disclosure.

FIGS. 9A through 9C are graphical representations illustrating examples of single-wire transmission line and classic transmission line models of the equivalent image plane models of FIGS. 8B and 8C according to various embodiments of the present disclosure.

FIG. 9D is a plot illustrating an example of the reactance variation of a lumped element tank circuit with respect to operating frequency according to various embodiments of the present disclosure.

FIG. 10 is a flow chart illustrating an example of adjusting a guided surface waveguide probe of FIGS. 3 and 7A-7C to launch a guided surface wave along the surface of a lossy conducting medium according to various embodiments of the present disclosure.

FIG. 11 is a plot illustrating an example of the relationship between a wave tilt angle and the phase delay of a guided surface waveguide probe of FIGS. 3 and 7A-7C according to various embodiments of the present disclosure.

FIG. 12 is a drawing that illustrates an example of a guided surface waveguide probe according to various embodiments of the present disclosure.

FIG. 13 is a graphical representation illustrating the incidence of a synthesized electric field at a complex Brewster angle to match the guided surface waveguide mode at the Hankel crossover distance according to various embodiments of the present disclosure.

FIG. 14 is a graphical representation of an example of a guided surface waveguide probe of FIG. 12 according to various embodiments of the present disclosure.

FIG. 15A includes plots of an example of the imaginary and real parts of a phase delay (Φ_{U}) of a charge terminal T₁ of a guided surface waveguide probe according to various embodiments of the present disclosure.

FIG. 15B is a schematic diagram of the guided surface waveguide probe of FIG. 14 according to various embodiments of the present disclosure.

FIG. 16 is a drawing that illustrates an example of a guided surface waveguide probe according to various embodiments of the present disclosure.

FIG. 17 is a graphical representation of an example of a guided surface waveguide probe of FIG. 16 according to various embodiments of the present disclosure.

FIGS. 18A through 18C depict examples of receiving structures that can be employed to receive energy transmitted in the form of a guided surface wave launched by a guided surface waveguide probe according to the various embodiments of the present disclosure.

FIG. 18D is a flow chart illustrating an example of adjusting a receiving structure according to various embodiments of the present disclosure.

FIG. 19 depicts an example of an additional receiving structure that can be employed to receive energy transmitted in the form of a guided surface wave launched by a guided surface waveguide probe according to the various embodiments of the present disclosure.

FIG. 20 illustrates an example guided surface waveguide probe according to various embodiments of the present disclosure.

FIG. 21 illustrates the guided surface waveguide probe and substructure of the site shown in FIG. 20 according to various embodiments of the present disclosure.

FIG. 22 illustrates the guided surface waveguide probe shown in FIG. 20 with an exterior covering according to various embodiments of the present disclosure.

FIGS. 23 and 24 illustrate an example of the support structure of the probe shown in FIG. 20 according to various embodiments of the present disclosure.

FIG. 25 is the cross-sectional view A-A designated in FIG. 20 according to various embodiments of the present disclosure.

FIG. 26 is the cross-sectional view A-A designated in FIG. 20 and illustrates a number of sections of a coil of the probe according to various embodiments of the present disclosure.

FIG. 27 is an enlarged portion of the cross-sectional view A-A designated in FIG. 20 according to various embodiments of the present disclosure.

FIG. 28 is a cross-sectional view of the charge terminal of the probe shown in FIG. 20 according to various embodiments of the present disclosure.

FIGS. 29A and 29B illustrate top and bottom perspective views of a top support platform of the probe shown in FIG. 20 according to various embodiments of the present disclosure.

FIGS. 30 and 31 illustrate various components inside the substructure of the probe shown in FIG. 20 according to various embodiments of the present disclosure.

FIGS. 32A and 32B illustrate a grounding system of the probe shown in FIG. 20 according to various embodiments of the present disclosure.

FIGS. 33A and 33B illustrate examples of tank circuits of the probe according to various embodiments of the present disclosure.

FIG. 34 is a side view of an embodiment of the support structure of a guided surface waveguide probe.

FIG. 35 is an inner perspective view of an embodiment of a corner column that can be used to construct the support structure of FIG. 34.

FIG. 36 is an inner perspective view of an embodiment of an intermediate column that can be used to construct the support structure of FIG. 34.

FIG. 37 is an inner perspective view of an embodiment of a corner angle member that can be used to construct the support structure of FIG. 34.

FIG. 38 is an outer perspective view of an embodiment of a bottom corner junction that can be used to construct the support structure of FIG. 34.

FIG. 39 is an inner perspective view of the bottom corner junction of FIG. 38.

FIG. 40 is a cross-sectional view of the bottom corner junction of FIG. 38.

FIG. 41 is an outer perspective view of an embodiment of a bottom intermediate junction that can be used to construct the support structure of FIG. 34.

FIG. 42 is an inner perspective view of the bottom intermediate junction of FIG. 41.

FIG. 43 is a cross-sectional view of the bottom intermediate junction of FIG. 41.

FIG. 44 is an outer perspective view of an embodiment of a medial corner junction that can be used to construct the support structure of FIG. 34.

FIG. 45 is an inner perspective view of the medial corner junction of FIG. 44.

FIG. 46 is a cross-sectional view of the medial corner junction of FIG. 44.

FIG. 47 is an outer perspective view of an embodiment of a medial intermediate junction that can be used to construct the support structure of FIG. 34.

FIG. 48 is an inner perspective view of the medial intermediate junction of FIG. 47.

FIG. 49 is a cross-sectional view of the medial intermediate junction of FIG. 47.

FIG. 50 is an outer perspective view of an embodiment of a transitional corner junction that can be used to construct the support structure of FIG. 34.

FIG. 51 is an inner perspective view of the transitional corner junction of FIG. 50.

FIG. 52 is a cross-sectional view of the transitional corner junction of FIG. 50.

### DETAILED DESCRIPTION

To begin, some terminology shall be established to provide clarity in the discussion of concepts to follow. First, as contemplated herein, a formal distinction is drawn between radiated electromagnetic fields and guided electromagnetic fields.

As contemplated herein, a radiated electromagnetic field comprises electromagnetic energy that is emitted from a source structure in the form of waves that are not bound to a waveguide. For example, a radiated electromagnetic field is generally a field that leaves an electric structure such as an antenna and propagates through the atmosphere or other medium and is not bound to any waveguide structure. Once radiated electromagnetic waves leave an electric structure such as an antenna, they continue to propagate in the medium of propagation (such as air) independent of their source until they dissipate regardless of whether the source continues to operate. Once electromagnetic waves are radiated, they are not recoverable unless intercepted, and, if not intercepted, the energy inherent in the radiated electromagnetic waves is lost forever. Electrical structures such as antennas are designed to radiate electromagnetic fields by maximizing the ratio of the radiation resistance to the structure loss resistance. Radiated energy spreads out in space and is lost regardless of whether a receiver is present. The energy density of the radiated fields is a function of distance due to geometric spreading. Accordingly, the term “radiate” in all its forms as used herein refers to this form of electromagnetic propagation.

A guided electromagnetic field is a propagating electromagnetic wave whose energy is concentrated within or near boundaries between media having different electromagnetic properties. In this sense, a guided electromagnetic field is one that is bound to a waveguide and may be characterized as being conveyed by the current flowing in the waveguide. If there is no load to receive and/or dissipate the energy conveyed in a guided electromagnetic wave, then no energy is lost except for that which is dissipated in the conductivity of the guiding medium. Stated another way, if there is no load for a guided electromagnetic wave, then no energy is consumed. Thus, a generator or other source generating a guided electromagnetic field does not deliver real power unless a resistive load is present. To this end, such a generator or other source essentially runs idle until a load is presented. This is akin to running a generator to generate a 60 Hertz electromagnetic wave that is transmitted over power lines where there is no electrical load. It should be noted that a guided electromagnetic field or wave is the equivalent to what is termed a “transmission line mode.” This contrasts with radiated electromagnetic waves in which real power is supplied at all times in order to generate radiated waves. Unlike radiated electromagnetic waves, guided electromagnetic energy does not continue to propagate along a finite length waveguide after the energy source is turned off. Accordingly, the term “guide” in all its forms as used herein refers to this transmission mode of electromagnetic propagation.

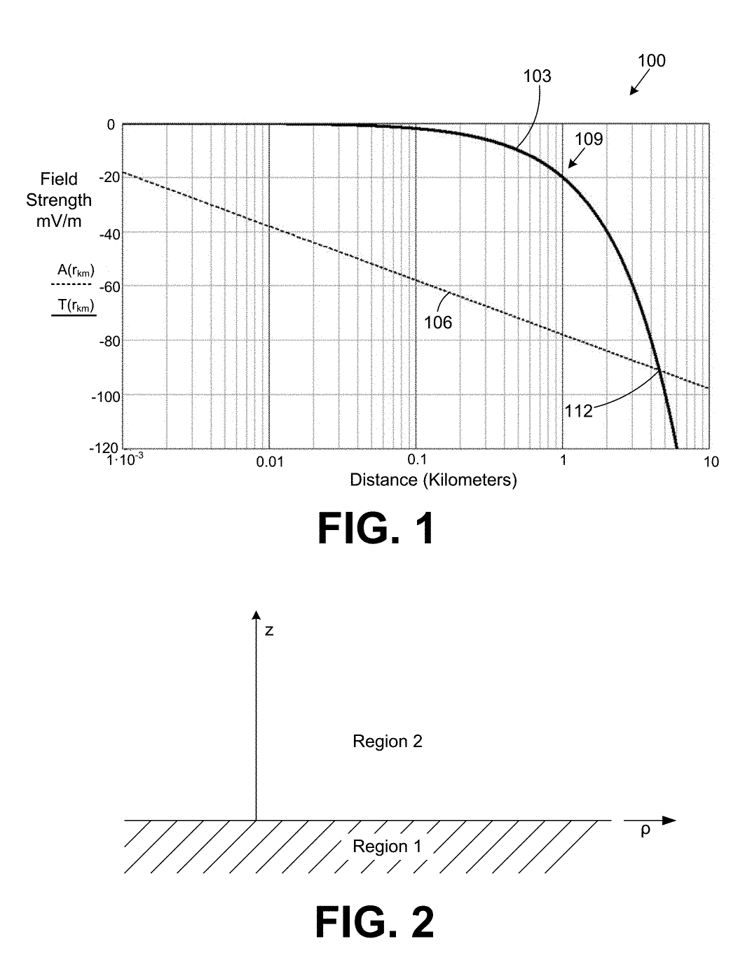

Referring now to FIG. 1, shown is a graph 100 of field strength in decibels (dB) above an arbitrary reference in volts per meter as a function of distance in kilometers on a log-dB plot to further illustrate the distinction between radiated and guided electromagnetic fields. The graph 100 of FIG. 1 depicts a guided field strength curve 103 that shows the field strength of a guided electromagnetic field as a function of distance. This guided field strength curve 103 is essentially the same as a transmission line mode. Also, the graph 100 of FIG. 1 depicts a radiated field strength curve 106 that shows the field strength of a radiated electromagnetic field as a function of distance.

Of interest are the shapes of the curves 103 and 106 for guided wave and for radiation propagation, respectively. The radiated field strength curve 106 falls off geometrically (1/d, where d is distance), which is depicted as a straight line on the log-log scale. The guided field strength curve 103, on the other hand, has a characteristic exponential decay of e^{-ad}/\sqrt{d} and exhibits a distinctive knee 109 on the log-log scale. The guided field strength curve 103 and the radiated field strength curve 106 intersect at point 112, which occurs at a crossing distance. At distances less than the crossing distance at intersection point 112, the field strength of a guided electromagnetic field is significantly greater at most locations than the field strength of a radiated electromagnetic field. At distances greater than the crossing distance, the opposite is true. Thus, the guided and radiated field strength curves 103 and 106 further illustrate the fundamental propagation difference between guided and radiated electromagnetic fields. For an informal discussion of the difference between guided and radiated electromagnetic fields, reference is made to Milligan, T., Modern Antenna Design, McGraw-Hill, 1^{st} Edition, 1985, pp. 8-9.

The distinction between radiated and guided electromagnetic waves, made above, is readily expressed formally and placed on a rigorous basis. That two such diverse solutions could emerge from one and the same linear partial differential equation, the wave equation, analytically follows from the boundary conditions imposed on the problem. The Green function for the wave equation, itself, contains the distinction between the nature of radiation and guided waves.

In empty space, the wave equation is a differential operator whose eigenfunctions possess a continuous spectrum of eigenvalues on the complex wave-number plane. This transverse electro-magnetic (TEM) field is called the radiation field, and those propagating fields are called “Hertzian waves.” However, in the presence of a conducting boundary, the wave equation plus boundary conditions mathematically lead to a spectral representation of wave-numbers composed of a continuous spectrum plus a sum of discrete spectra. To this end, reference is made to Sommerfeld, A., “Uber die Ausbreitung der Wellen in der Drahtlosen Telegraphie,” Annalen der Physik, Vol. 28, 1909, pp. 665-736. Also see Sommerfeld, A., “Problems of Radio,” published as Chapter 6 in Partial Differential Equations in Physics—Lectures on Theoretical Physics: Volume VI, Academic Press, 1949, pp. 236-289, 295-296; Collin, R. E., “Hertzian Dipole Radiating Over a Lossy Earth or Sea: Some Early and Late 20th Century Controversies,” IEEE Antennas and Propagation Magazine, Vol. 46, No. 2, April 2004, pp. 64-79; and Reich, H. J., Ordnung, P. F, Krauss, H. L., and Skalnik, J. G., Microwave Theory and Techniques, Van Nostrand, 1953, pp. 291-293.

The terms “ground wave” and “surface wave” identify two distinctly different physical propagation phenomena. A surface wave arises analytically from a distinct pole yielding a discrete component in the plane wave spectrum. See, e.g., “The Excitation of Plane Surface Waves” by Cullen, A. L., (Proceedings of the IEE (British), Vol. 101, Part IV, August 1954, pp. 225-235). In this context, a surface wave is considered to be a guided surface wave. The surface wave (in the Zenneck-Sommerfeld guided wave sense) is, physically and mathematically, not the same as the ground wave (in the Weyl-Norton-FCC sense) that is now so familiar from radio broadcasting. These two propagation mechanisms arise from the excitation of different types of eigenvalue spectra (continuum or discrete) on the complex plane. The field strength of the guided surface wave decays exponentially with distance as illustrated by guided field strength curve 103 of FIG. 1 (much like propagation in a lossy waveguide) and resembles propagation in a radial transmission line, as opposed to the classical Hertzian radiation of the ground wave, which propagates spherically, possesses a continuum of eigenvalues, falls off geometrically as illustrated by radiated field strength curve 106 of FIG. 1, and results from branch-cut integrals. As experimentally demonstrated by C. R. Burrows in “The Surface Wave in Radio Propagation over Plane Earth” (Proceedings of the IRE, Vol. 25, No. 2, February, 1937, pp. 219-229) and “The Surface Wave in Radio Transmission” (Bell Laboratories Record, Vol. 15, June 1937, pp. 321-324), vertical antennas radiate ground waves but do not launch guided surface waves.

To summarize the above, first, the continuous part of the wave-number eigenvalue spectrum, corresponding to branch-cut integrals, produces the radiation field, and second, the discrete spectra, and corresponding residue sum arising from the poles enclosed by the contour of integration, result in non-TEM traveling surface waves that are exponentially damped in the direction transverse to the propagation. Such surface waves are guided transmission line modes. For further explanation, reference is made to Friedman, B., Principles and Techniques of Applied Mathematics, Wiley, 1956, pp. pp. 214, 283-286, 290, 298-300.

In free space, antennas excite the continuum eigenvalues of the wave equation, which is a radiation field, where the outwardly propagating RF energy with E_{z} and H_{ϕ} in-phase is lost forever. On the other hand, waveguide probes excite discrete eigenvalues, which results in transmission line propagation. See Collin, R. E., Field Theory of Guided Waves, McGraw-Hill, 1960, pp. 453, 474-477. While such theoretical analyses have held out the hypothetical possibility of launching open surface guided waves over planar or spherical surfaces of lossy, homogeneous media, for more than a century no known structures in the engineering arts have existed for accomplishing this with any practical efficiency. Unfortunately, since it emerged in the early 1900's, the theoretical analysis set forth above has essentially remained a theory and there have been no known structures for practically accomplishing the launching of open surface guided waves over planar or spherical surfaces of lossy, homogeneous media.

According to the various embodiments of the present disclosure, various guided surface waveguide probes are described that are configured to excite electric fields that couple into a guided surface waveguide mode along the surface of a lossy conducting medium. Such guided electromagnetic fields are substantially mode-matched in magnitude and phase to a guided surface wave mode on the surface of the lossy conducting medium. Such a guided surface wave mode can also be termed a Zenneck waveguide mode. By virtue of the fact that the resultant fields excited by the guided surface waveguide probes described herein are substantially mode-matched to a guided surface waveguide mode on the surface of the lossy conducting medium, a guided electromagnetic field in the form of a guided surface wave is launched along the surface of the lossy conducting medium. According to one embodiment, the lossy conducting medium comprises a terrestrial medium such as the Earth.

Referring to FIG. 2, shown is a propagation interface that provides for an examination of the boundary value solutions to Maxwell's equations derived in 1907 by Jonathan Zenneck as set forth in his paper Zenneck, J., “On the Propagation of Plane Electromagnetic Waves Along a Flat Conducting Surface and their Relation to Wireless Telegraphy,” Annalen der Physik, Serial 4, Vol. 23, Sep. 20, 1907, pp. 846-866. FIG. 2 depicts cylindrical coordinates for radially propagating waves along the interface between a lossy conducting medium specified as Region 1 and an insulator specified as Region 2. Region 1 can comprise, for example, any lossy conducting medium. In one example, such a lossy conducting medium can comprise a terrestrial medium such as the Earth or other medium. Region 2 is a second medium that shares a boundary interface with Region 1 and has different constitutive parameters relative to Region 1. Region 2 can comprise, for example, any insulator such as the atmosphere or other medium. The reflection coefficient for such a boundary interface goes to zero only for incidence at a complex Brewster angle. See Stratton, J. A., Electromagnetic Theory, McGraw-Hill, 1941, p. 516.

According to various embodiments, the present disclosure sets forth various guided surface waveguide probes that generate electromagnetic fields that are substantially mode-matched to a guided surface waveguide mode on the surface of the lossy conducting medium comprising Region 1. According to various embodiments, such electromagnetic fields substantially synthesize a wave front incident at a complex Brewster angle of the lossy conducting medium that can result in zero reflection.

To explain further, in Region 2, where an e^{jωt} field variation is assumed and where ρ≠0 and z≥0 (with z being the vertical coordinate normal to the surface of Region 1, and ρ being the radial dimension in cylindrical coordinates), Zenneck's closed-form exact solution of Maxwell's equations satisfying the boundary conditions along the interface are expressed by the following electric field and magnetic field components:

$$\begin{matrix}{H}_{2 φ} = {Ae}^{- {u}_{2} z} {H}_{1}^{( 2 )} ( - j γ ρ ) , & ( 1 ) \\ {E}_{2 ρ} = A ( \frac{{u}_{2}}{j ω {ɛ}_{o}} ) {e}^{- {u}_{2} z} {H}_{1}^{( 2 )} ( - j γ ρ ) , and & ( 2 ) \\ {E}_{2 z} = A ( \frac{- γ}{ω {ɛ}_{o}} ) {e}^{- {u}_{2} z} {H}_{0}^{( 2 )} ( - j γ ρ ) . & ( 3 )\end{matrix}$$

In Region 1, where the e^{jωt} field variation is assumed and where ρ≠0 and z≤0, Zenneck's closed-form exact solution of Maxwell's equations satisfying the boundary conditions along the interface is expressed by the following electric field and magnetic field components:

$$\begin{matrix}{H}_{1 φ} = {Ae}^{{u}_{1} z} {H}_{1}^{( 2 )} ( - j γ ρ ) , & ( 4 ) \\ {E}_{1 ρ} = A ( \frac{- {u}_{1}}{{σ}_{1} + j ω {ɛ}_{1}} ) {e}^{{u}_{1} z} {H}_{1}^{( 2 )} ( - j γ ρ ) , and & ( 5 ) \\ {E}_{1 z} = A ( \frac{- j γ}{{σ}_{1} + j ω {ɛ}_{1}} ) {e}^{{u}_{1} z} {H}_{0}^{( 2 )} ( - j γ ρ ) . & ( 6 )\end{matrix}$$

In these expressions, z is the vertical coordinate normal to the surface of Region 1 and ρ is the radial coordinate, Hₙ⁽²⁾(−jγρ) is a complex argument Hankel function of the second kind and order n, u₁ is the propagation constant in the positive vertical (z) direction in Region 1, u₂ is the propagation constant in the vertical (z) direction in Region 2, σ₁ is the conductivity of Region 1, ω is equal to 2πf, where f is a frequency of excitation, εₒ is the permittivity of free space, ε₁ is the permittivity of Region 1, A is a source constant imposed by the source, and γ is a surface wave radial propagation constant.

The propagation constants in the ±z directions are determined by separating the wave equation above and below the interface between Regions 1 and 2, and imposing the boundary conditions. This exercise gives, in Region 2,

$${u}_{2} = \frac{- {jk}_{o}}{\sqrt{1 + ( {ɛ}_{r} - jx )}} \qquad ( 7 )$$

and gives, in Region 1,

u₁=−u₂(εᵣ−jx). (8)

The radial propagation constant γ is given by

$$γ = j \sqrt{{k}_{o}^{2} + {u}_{2}^{2}} = j \frac{{k}_{o} n}{\sqrt{1 + {n}^{2}}} , \qquad ( 9 )$$

which is a complex expression where n is the complex index of refraction given by

n=\sqrt{εᵣ−jx}. (10)

In all of the above Equations,

$$\begin{matrix}x = \frac{{σ}_{1}}{ω {ɛ}_{o}} , and & ( 11 ) \\ {k}_{o} = ω \sqrt{{μ}_{o} {ɛ}_{o}} = \frac{{λ}_{o}}{2 π} , & ( 12 )\end{matrix}$$

where εᵣ comprises the relative permittivity of Region 1, σ₁ is the conductivity of Region 1, εₒ is the permittivity of free space, and μₒ comprises the permeability of free space. Thus, the generated surface wave propagates parallel to the interface and exponentially decays vertical to it. This is known as evanescence.

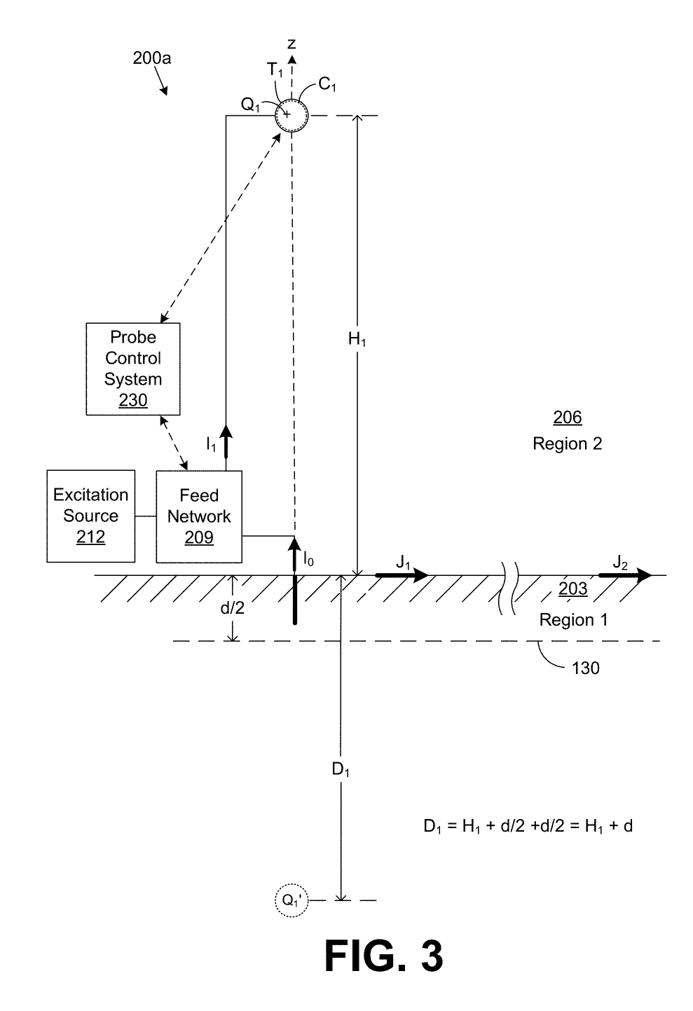

Thus, Equations (1)-(3) can be considered to be a cylindrically-symmetric, radially-propagating waveguide mode. See Barlow, H. M., and Brown, J., Radio Surface Waves, Oxford University Press, 1962, pp. 10-12, 29-33. The present disclosure details structures that excite this “open boundary” waveguide mode. Specifically, according to various embodiments, a guided surface waveguide probe is provided with a charge terminal of appropriate size that is fed with voltage and/or current and is positioned relative to the boundary interface between Region 2 and Region 1. This may be better understood with reference to FIG. 3, which shows an example of a guided surface waveguide probe 200a that includes a charge terminal T₁ elevated above a lossy conducting medium 203 (e.g., the Earth) along a vertical axis z that is normal to a plane presented by the lossy conducting medium 203. The lossy conducting medium 203 makes up Region 1, and a second medium 206 makes up Region 2 and shares a boundary interface with the lossy conducting medium 203.

According to one embodiment, the lossy conducting medium 203 can comprise a terrestrial medium such as the planet Earth. To this end, such a terrestrial medium comprises all structures or formations included thereon whether natural or man-made. For example, such a terrestrial medium can comprise natural elements such as rock, soil, sand, fresh water, sea water, trees, vegetation, and all other natural elements that make up our planet. In addition, such a terrestrial medium can comprise man-made elements such as concrete, asphalt, building materials, and other man-made materials. In other embodiments, the lossy conducting medium 203 can comprise some medium other than the Earth, whether naturally occurring or man-made. In other embodiments, the lossy conducting medium 203 can comprise other media such as man-made surfaces and structures such as automobiles, aircraft, man-made materials (such as plywood, plastic sheeting, or other materials) or other media.

In the case where the lossy conducting medium 203 comprises a terrestrial medium or Earth, the second medium 206 can comprise the atmosphere above the ground. As such, the atmosphere can be termed an “atmospheric medium” that comprises air and other elements that make up the atmosphere of the Earth. In addition, it is possible that the second medium 206 can comprise other media relative to the lossy conducting medium 203.

The guided surface waveguide probe 200a includes a feed network 209 that couples an excitation source 212 to the charge terminal T₁ via, e.g., a vertical feed line conductor. The excitation source 212 may comprise, for example, an Alternating Current (AC) source or some other source. As contemplated herein, an excitation source can comprise an AC source or other type of source. According to various embodiments, a charge Q₁ is imposed on the charge terminal T₁ to synthesize an electric field based upon the voltage applied to terminal T₁ at any given instant. Depending on the angle of incidence (θᵢ) of the electric field (E), it is possible to substantially mode-match the electric field to a guided surface waveguide mode on the surface of the lossy conducting medium 203 comprising Region 1.

By considering the Zenneck closed-form solutions of Equations (1)-(6), the Leontovich impedance boundary condition between Region 1 and Region 2 can be stated as

\hat{z}×\vec{H}₂(ρ,φ,0)=\vec{J}_{S} (13)

where \hat{z} is a unit normal in the positive vertical (+z) direction and \vec{H}₂ is the magnetic field strength in Region 2 expressed by Equation (1) above. Equation (13) implies that the electric and magnetic fields specified in Equations (1)-(3) may result in a radial surface current density along the boundary interface, where the radial surface current density can be specified by

J_{ρ}(ρ′)=−AH₁⁽²⁾(−jγρ′) (14)

where A is a constant. Further, it should be noted that close-in to the guided surface waveguide probe 200 (for ρ<<λ), Equation (14) above has the behavior

$${J}_{close} ( {ρ}^{′} ) = \frac{- A ( j 2 )}{π ( - j γ {ρ}^{′} )} = - {H}_{φ} = - \frac{{I}_{o}}{2 π {ρ}^{′}} . \qquad ( 15 )$$

The negative sign means that when source current (Iₒ) flows vertically upward as illustrated in FIG. 3, the “close-in” ground current flows radially inward. By field matching on H_{ϕ} “close-in,” it can be determined that

$$A = - \frac{{I}_{o} γ}{4} = - \frac{ω {q}_{1} γ}{4} \qquad ( 16 )$$

where q₁=C₁V₁, in Equations (1)-(6) and (14). Therefore, the radial surface current density of Equation (14) can be restated as

$${J}_{ρ} ( {ρ}^{′} ) = \frac{{I}_{o} γ}{4} {H}_{1}^{( 2 )} ( - j γ {ρ}^{′} ) . \qquad ( 17 )$$

The fields expressed by Equations (1)-(6) and (17) have the nature of a transmission line mode bound to a lossy interface, not radiation fields that are associated with groundwave propagation. See Barlow, H. M. and Brown, J., Radio Surface Waves, Oxford University Press, 1962, pp. 1-5.

At this point, a review of the nature of the Hankel functions used in Equations (1)-(6) and (17) is provided for these solutions of the wave equation. One might observe that the Hankel functions of the first and second kind and order n are defined as complex combinations of the standard Bessel functions of the first and second kinds

Hₙ⁽¹⁾(x)=Jₙ(x)+jNₙ(x), and (18)

Hₙ⁽²⁾(x)=Jₙ(x)−jNₙ(x) (19)

These functions represent cylindrical waves propagating radially inward (Hₙ⁽¹⁾) and outward (Hₙ²)), respectively. The definition is analogous to the relationship e^{±jx}=cos x±j sin x. See, for example, Harrington, R. F., Time-Harmonic Fields, McGraw-Hill, 1961, pp. 460-463.

That Hₙ⁽²⁾(k_{ρ}ρ) is an outgoing wave can be recognized from its large argument asymptotic behavior that is obtained directly from the series definitions of Jₙ(x) and Nₙ(x). Far-out from the guided surface waveguide probe:

$${H}_{n}^{( 2 )} ( x ) {\to }_{x \to ∞} \sqrt{\frac{2 j}{π x}} {j}^{n} {e}^{- jx} = \sqrt{\frac{2}{π x}} {j}^{n} {e}^{- j ( x - \frac{π}{4} )} , \qquad ( 20 a )$$

which, when multiplied by e^{jωt}, is an outward propagating cylindrical wave of the form e^{j(ωt-kρ)} with a 1/\sqrt{ρ}spatial variation. The first order (n=1) solution can be determined from Equation (20a) to be

$${H}_{1}^{( 2 )} ( x ) {\to }_{x \to ∞} j \sqrt{\frac{2 j}{π x}} {e}^{- jx} = \sqrt{\frac{2}{π x}} {e}^{- j ( x - \frac{π}{2} - \frac{π}{4} )} . \qquad ( 20 b )$$

Close-in to the guided surface waveguide probe (for ρ<<λ), the Hankel function of first order and the second kind behaves as

$${H}_{1}^{( 2 )} ( x ) {\to }_{x \to 0} \frac{2 j}{π x} . \qquad ( 21 )$$

Note that these asymptotic expressions are complex quantities. When x is a real quantity, Equations (20b) and (21) differ in phase by \sqrt{j}, which corresponds to an extra phase advance or “phase boost” of 45° or, equivalently, λ/8. The close-in and far-out asymptotes of the first order Hankel function of the second kind have a Hankel “crossover” or transition point where they are of equal magnitude at a distance of ρ=Rₓ.

Thus, beyond the Hankel crossover point the “far out” representation predominates over the “close-in” representation of the Hankel function. The distance to the Hankel crossover point (or Hankel crossover distance) can be found by equating Equations (20b) and (21) for −jγρ, and solving for Rₓ. With x=σ/ωεₒ, it can be seen that the far-out and close-in Hankel function asymptotes are frequency dependent, with the Hankel crossover point moving out as the frequency is lowered. It should also be noted that the Hankel function asymptotes may also vary as the conductivity (σ) of the lossy conducting medium changes. For example, the conductivity of the soil can vary with changes in weather conditions.

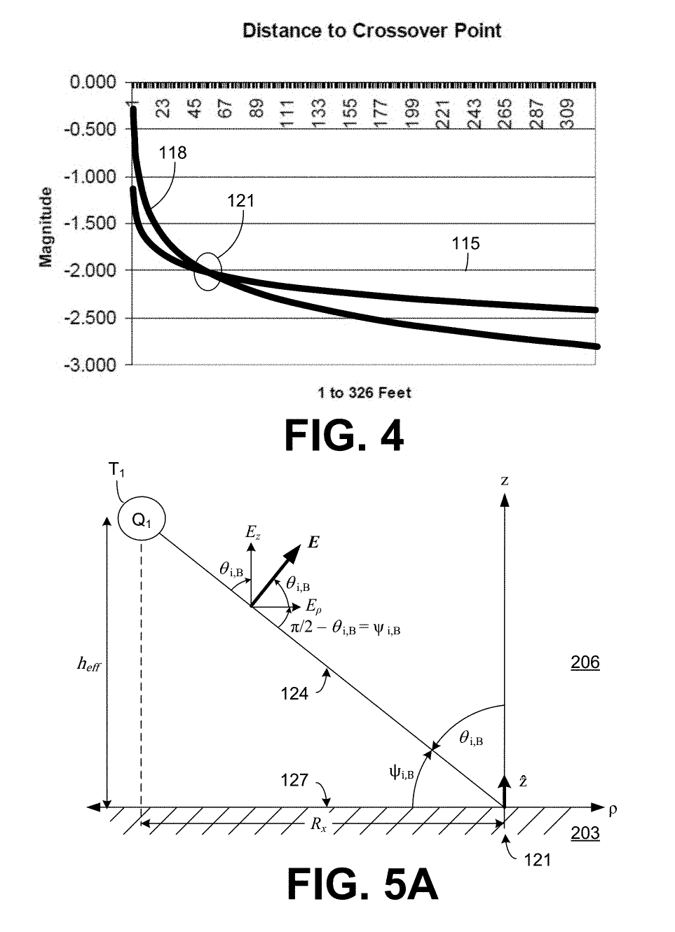

Referring to FIG. 4, shown is an example of a plot of the magnitudes of the first order Hankel functions of Equations (20b) and (21) for a Region 1 conductivity of σ=0.010 mhos/m and relative permittivity εᵣ=15, at an operating frequency of 1850 kHz. Curve 115 is the magnitude of the far-out asymptote of Equation (20b) and curve 118 is the magnitude of the close-in asymptote of Equation (21), with the Hankel crossover point 121 occurring at a distance of Rₓ=54 feet. While the magnitudes are equal, a phase offset exists between the two asymptotes at the Hankel crossover point 121. It can also be seen that the Hankel crossover distance is much less than a wavelength of the operation frequency.

Considering the electric field components given by Equations (2) and (3) of the Zenneck closed-form solution in Region 2, it can be seen that the ratio of εₓ and ε_{ρ} asymptotically passes to

$$\frac{{E}_{z}}{{E}_{ρ}} = ( \frac{- j γ}{{u}_{2}} ) \frac{{H}_{0}^{( 2 )} ( - j γ ρ )}{{H}_{1}^{( 2 )} ( - j γ ρ )} {\to }_{ρ \to ∞} \sqrt{{ɛ}_{r} - j \frac{σ}{ω {ɛ}_{0}}} = n = tan {θ}_{i} , \qquad ( 22 )$$

where n is the complex index of refraction of Equation (10) and θᵢ is the angle of incidence of the electric field. In addition, the vertical component of the mode-matched electric field of Equation (3) asymptotically passes to

$${E}_{2 z} {\to }_{ρ \to ∞} ( \frac{{q}_{free}}{{ɛ}_{0}} ) \sqrt{\frac{{γ}^{3}}{8 π}} {e}^{- {u}_{2} z} \frac{{e}^{- j ( γ ρ - π / 4 )}}{\sqrt{ρ}} , \qquad ( 23 )$$

which is linearly proportional to free charge on the isolated component of the elevated charge terminal's capacitance at the terminal voltage, q_{free}=C_{free}×V_{T}.

For example, the height H₁ of the elevated charge terminal T₁ in FIG. 3 affects the amount of free charge on the charge terminal T₁. When the charge terminal T₁ is near the ground plane of Region 1, most of the charge Q₁ on the terminal is “bound.” As the charge terminal T₁ is elevated, the bound charge is lessened until the charge terminal T₁ reaches a height at which substantially all of the isolated charge is free.

The advantage of an increased capacitive elevation for the charge terminal T₁ is that the charge on the elevated charge terminal T₁ is further removed from the ground plane, resulting in an increased amount of free charge q_{free} to couple energy into the guided surface waveguide mode. As the charge terminal T₁ is moved away from the ground plane, the charge distribution becomes more uniformly distributed about the surface of the terminal. The amount of free charge is related to the self-capacitance of the charge terminal T₁.

For example, the capacitance of a spherical terminal can be expressed as a function of physical height above the ground plane. The capacitance of a sphere at a physical height of h above a perfect ground is given by

C_{elevated sphere}=4πεₒa(1+M+M²+M³+2M⁴+3M⁵+ . . . ), (24)

where the diameter of the sphere is 2a, and where M=a/2h with h being the height of the spherical terminal. As can be seen, an increase in the terminal height h reduces the capacitance C of the charge terminal. It can be shown that for elevations of the charge terminal T₁ that are at a height of about four times the diameter (4D=8a) or greater, the charge distribution is approximately uniform about the spherical terminal, which can improve the coupling into the guided surface waveguide mode.

In the case of a sufficiently isolated terminal, the self-capacitance of a conductive sphere can be approximated by C=4πεₒa, where a is the radius of the sphere in meters, and the self-capacitance of a disk can be approximated by C=8εₒa, where a is the radius of the disk in meters. The charge terminal T₁ can include any shape such as a sphere, a disk, a cylinder, a cone, a torus, a hood, one or more rings, or any other randomized shape or combination of shapes. An equivalent spherical diameter can be determined and used for positioning of the charge terminal T₁.

This may be further understood with reference to the example of FIG. 3, where the charge terminal T₁ is elevated at a physical height of hₚ=H₁ above the lossy conducting medium 203. To reduce the effects of the “bound” charge, the charge terminal T₁ can be positioned at a physical height that is at least four times the spherical diameter (or equivalent spherical diameter) of the charge terminal T₁ to reduce the bounded charge effects.

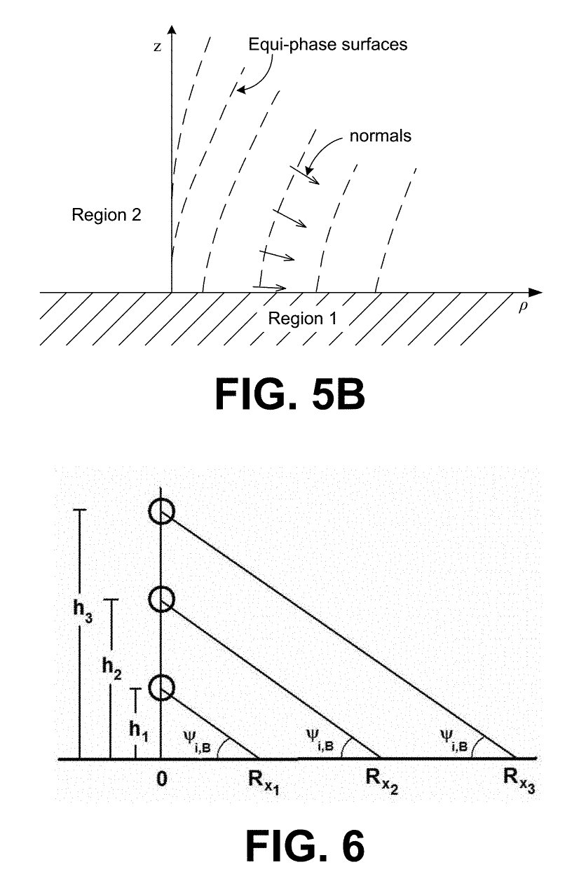

Referring next to FIG. 5A, shown is a ray optics interpretation of the electric field produced by the elevated charge Q₁ on charge terminal T₁ of FIG. 3. As in optics, minimizing the reflection of the incident electric field can improve and/or maximize the energy coupled into the guided surface waveguide mode of the lossy conducting medium 203. For an electric field (ε_{∥}) that is polarized parallel to the plane of incidence (not the boundary interface), the amount of reflection of the incident electric field may be determined using the Fresnel reflection coefficient, which can be expressed as

$${Γ}_{∥} ( {θ}_{i} ) = \frac{{E}_{∥ , R}}{{E}_{∥ , i}} = \frac{\sqrt{( {ɛ}_{r} - jx ) - {sin}^{2} {θ}_{i}} - ( {ɛ}_{r} - jx ) cos {θ}_{i}}{\sqrt{( {ɛ}_{r} - jx ) - {sin}^{2} {θ}_{i}} + ( {ɛ}_{r} - jx ) cos {θ}_{i}} , \qquad ( 25 )$$

where θᵢ is the conventional angle of incidence measured with respect to the surface normal.

In the example of FIG. 5A, the ray optic interpretation shows the incident field polarized parallel to the plane of incidence having an angle of incidence of θᵢ, which is measured with respect to the surface normal (2). There will be no reflection of the incident electric field when Γ_{∥}(θᵢ)=0 and thus the incident electric field will be completely coupled into a guided surface waveguide mode along the surface of the lossy conducting medium 203. It can be seen that the numerator of Equation (25) goes to zero when the angle of incidence is

θᵢ=arc tan(\sqrt{εᵣ−jx})=θ_{i,B}, (26)

where x=σ/ωεₒ. This complex angle of incidence (θ_{i,B}) is referred to as the Brewster angle. Referring back to Equation (22), it can be seen that the same complex Brewster angle (θ_{i,B}) relationship is present in both Equations (22) and (26).

As illustrated in FIG. 5A, the electric field vector E can be depicted as an incoming non-uniform plane wave, polarized parallel to the plane of incidence. The electric field vector E can be created from independent horizontal and vertical components as

\vec{E}(θᵢ)=E_{ρ}\hat{ρ}+E_{z}\hat{z}. (27)

Geometrically, the illustration in FIG. 5A suggests that the electric field vector E can be given by

$$\begin{matrix}{E}_{ρ} ( ρ , z ) = E ( ρ , z ) cos {θ}_{i} , and & ( 28 a ) \\ {E}_{z} ( ρ , z ) = E ( ρ , z ) cos ( \frac{π}{2} - {θ}_{i} ) = E ( ρ , z ) sin {θ}_{i} , & ( 28 b )\end{matrix}$$

which means that the field ratio is

$$\frac{{E}_{ρ}}{{E}_{z}} = \frac{1}{tan {θ}_{i}} = tan {ψ}_{i} . \qquad ( 29 )$$

A generalized parameter W, called “wave tilt,” is noted herein as the ratio of the horizontal electric field component to the vertical electric field component given by

$$\begin{matrix}W = \frac{{E}_{ρ}}{{E}_{z}} = \vert W \vert {e}^{j Ψ} , or & ( 30 a ) \\ \frac{1}{W} = \frac{{E}_{z}}{{E}_{ρ}} = tan {θ}_{i} = \frac{1}{\vert W \vert} {e}^{- j Ψ} , & ( 30 b )\end{matrix}$$

which is complex and has both magnitude and phase. For an electromagnetic wave in Region 2 (FIG. 2), the wave tilt angle (Ψ) is equal to the angle between the normal of the wave-front at the boundary interface with Region 1 (FIG. 2) and the tangent to the boundary interface. This may be easier to see in FIG. 5B, which illustrates equi-phase surfaces of an electromagnetic wave and their normals for a radial cylindrical guided surface wave. At the boundary interface (z=0) with a perfect conductor, the wave-front normal is parallel to the tangent of the boundary interface, resulting in W=0. However, in the case of a lossy dielectric, a wave tilt W exists because the wave-front normal is not parallel with the tangent of the boundary interface at z=0.

Applying Equation (30b) to a guided surface wave gives

$$tan {θ}_{i , B} = \frac{{E}_{z}}{{E}_{ρ}} = \frac{{u}_{2}}{γ} = \sqrt{{ɛ}_{r} - jx} = n = \frac{1}{W} = \frac{1}{\vert W \vert} {e}^{- j Ψ} . \qquad ( 31 )$$

With the angle of incidence equal to the complex Brewster angle (θ_{i,B}), the Fresnel reflection coefficient of Equation (25) vanishes, as shown by

$${{Γ}_{∥} ( {θ}_{i , B} ) = \frac{\sqrt{( {ɛ}_{r} - jx ) - {sin}^{2} {θ}_{i}} - ( {ɛ}_{r} - jx ) cos {θ}_{i}}{\sqrt{( {ɛ}_{r} - jx ) - {sin}^{2} {θ}_{i}} + ( {ɛ}_{r} - jx ) cos {θ}_{i}} \vert}_{{θ}_{i} = {θ}_{i , B}} = 0. \qquad ( 32 )$$

By adjusting the complex field ratio of Equation (22), an incident field can be synthesized to be incident at a complex angle at which the reflection is reduced or eliminated. Establishing this ratio as n=\sqrt{εᵣ−jx} results in the synthesized electric field being incident at the complex Brewster angle, making the reflections vanish.

The concept of an electrical effective height can provide further insight into synthesizing an electric field with a complex angle of incidence with a guided surface waveguide probe 200. The electrical effective height (h_{eff}) has been defined as

$${h}_{eff} = \frac{1}{{I}_{0}} {\int }_{0}^{{h}_{p}} I ( z ) dz \qquad ( 33 )$$

for a monopole with a physical height (or length) of hₚ. Since the expression depends upon the magnitude and phase of the source distribution along the structure, the effective height (or length) is complex in general. The integration of the distributed current I(z) of the structure is performed over the physical height of the structure (hₚ), and normalized to the ground current (I₀) flowing upward through the base (or input) of the structure. The distributed current along the structure can be expressed by

I(z)=I_{C} cos(β₀z), (34)

where β₀ is the propagation factor for current propagating on the structure. In the example of FIG. 3, I_{C} is the current that is distributed along the vertical structure of the guided surface waveguide probe 200a.

For example, consider a feed network 209 that includes a low loss coil (e.g., a helical coil) at the bottom of the structure and a vertical feed line conductor connected between the coil and the charge terminal T₁. The phase delay due to the coil (or helical delay line) is θ_{c}=βₚl_{C}, with a physical length of l_{C} and a propagation factor of

$${β}_{p} = \frac{2 π}{{λ}_{p}} = \frac{2 π}{{V}_{f} {λ}_{0}} , \qquad ( 35 )$$

where V_{f} is the velocity factor on the structure, λ₀ is the wavelength at the supplied frequency, and λₚ is the propagation wavelength resulting from the velocity factor V_{f}. The phase delay is measured relative to the ground (stake or system) current I₀.

In addition, the spatial phase delay along the length l_{w} of the vertical feed line conductor can be given by θ_{y}=β_{w}l_{w} where β_{w} is the propagation phase constant for the vertical feed line conductor. In some implementations, the spatial phase delay may be approximated by θ_{y}=β_{w}hₚ, since the difference between the physical height hₚ of the guided surface waveguide probe 200a and the vertical feed line conductor length l_{w} is much less than a wavelength at the supplied frequency (λ₀). As a result, the total phase delay through the coil and vertical feed line conductor is Φ=θ_{c}+θ_{y}, and the current fed to the top of the coil from the bottom of the physical structure is

I_{C}(θ_{c}+θ_{y})=I₀e^{jΦ}, (36)

with the total phase delay Φ measured relative to the ground (stake or system) current I₀. Consequently, the electrical effective height of a guided surface waveguide probe 200 can be approximated by

$${h}_{eff} = \frac{1}{{I}_{0}} {\int }_{0}^{{h}_{p}} {I}_{0} {e}^{j Φ} cos ( {β}_{0} z ) dz ≅ {h}_{p} {e}^{j Φ} , \qquad ( 37 )$$

for the case where the physical height hₚ<<λ₀. The complex effective height of a monopole, h_{eff}=hₚ at an angle (or phase delay) of Φ, may be adjusted to cause the source fields to match a guided surface waveguide mode and cause a guided surface wave to be launched on the lossy conducting medium 203.

In the example of FIG. 5A, ray optics are used to illustrate the complex angle trigonometry of the incident electric field (E) having a complex Brewster angle of incidence (θ_{i,B}) at the Hankel crossover distance (Rₓ) 121. Recall from Equation (26) that, for a lossy conducting medium, the Brewster angle is complex and specified by

$$tan {θ}_{i , B} = \sqrt{{ɛ}_{r} - j \frac{σ}{ω {ɛ}_{0}}} = n . \qquad ( 38 )$$

Electrically, the geometric parameters are related by the electrical effective height (h_{eff}) of the charge terminal T₁ by

Rₓ tan ψ_{i,B}=Rₓ×W=h_{eff}=hₚe^{jΦ}, (39)

where ψ_{i,B}=(π/2)−θ_{i,B} is the Brewster angle measured from the surface of the lossy conducting medium. To couple into the guided surface waveguide mode, the wave tilt of the electric field at the Hankel crossover distance can be expressed as the ratio of the electrical effective height and the Hankel crossover distance

$$\frac{{h}_{eff}}{{R}_{x}} = tan {ψ}_{i , B} = {W}_{Rx} . \qquad ( 40 )$$

Since both the physical height (hₚ) and the Hankel crossover distance (Rₓ) are real quantities, the angle (Ψ) of the desired guided surface wave tilt at the Hankel crossover distance (Rₓ) is equal to the phase (Φ) of the complex effective height (h_{eff}). This implies that by varying the phase at the supply point of the coil, and thus the phase delay in Equation (37), the phase, Φ, of the complex effective height can be manipulated to match the angle of the wave tilt, Ψ, of the guided surface waveguide mode at the Hankel crossover point 121: Φ=Ψ.

In FIG. 5A, a right triangle is depicted having an adjacent side of length Rₓ along the lossy conducting medium surface and a complex Brewster angle ψ_{i,B} measured between a ray 124 extending between the Hankel crossover point 121 at R, and the center of the charge terminal T₁, and the lossy conducting medium surface 127 between the Hankel crossover point 121 and the charge terminal T₁. With the charge terminal T₁ positioned at physical height hₚ and excited with a charge having the appropriate phase delay Φ, the resulting electric field is incident with the lossy conducting medium boundary interface at the Hankel crossover distance Rₓ, and at the Brewster angle. Under these conditions, the guided surface waveguide mode can be excited without reflection or substantially negligible reflection.

If the physical height of the charge terminal T₁ is decreased without changing the phase delay Φ of the effective height (h_{eff}), the resulting electric field intersects the lossy conducting medium 203 at the Brewster angle at a reduced distance from the guided surface waveguide probe 200. FIG. 6 graphically illustrates the effect of decreasing the physical height of the charge terminal T₁ on the distance where the electric field is incident at the Brewster angle. As the height is decreased from h₃ through h₂ to h₁, the point where the electric field intersects with the lossy conducting medium (e.g., the Earth) at the Brewster angle moves closer to the charge terminal position. However, as Equation (39) indicates, the height H₁ (FIG. 3) of the charge terminal T₁ should be at or higher than the physical height (hₚ) in order to excite the far-out component of the Hankel function. With the charge terminal T₁ positioned at or above the effective height (h_{eff}), the lossy conducting medium 203 can be illuminated at the Brewster angle of incidence (ψ_{i,B}=(π/2)−θ_{i,B}) at or beyond the Hankel crossover distance (Rₓ) 121 as illustrated in FIG. 5A. To reduce or minimize the bound charge on the charge terminal T₁, the height should be at least four times the spherical diameter (or equivalent spherical diameter) of the charge terminal T₁ as mentioned above.

A guided surface waveguide probe 200 can be configured to establish an electric field having a wave tilt that corresponds to a wave illuminating the surface of the lossy conducting medium 203 at a complex Brewster angle, thereby exciting radial surface currents by substantially mode-matching to a guided surface wave mode at (or beyond) the Hankel crossover point 121 at Rₓ.

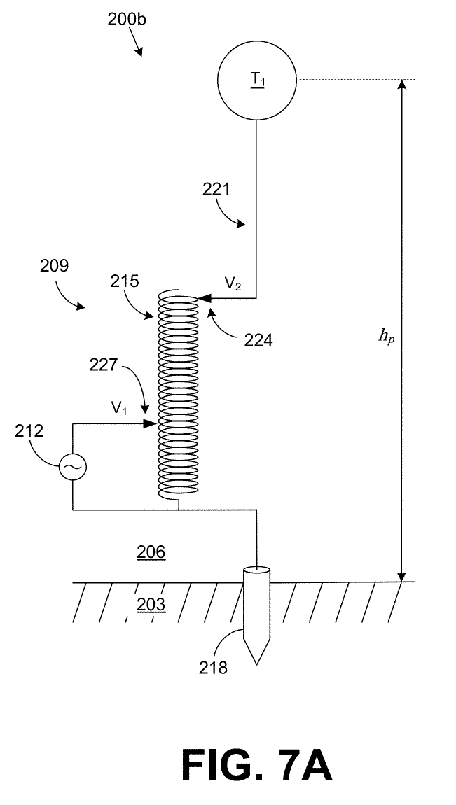

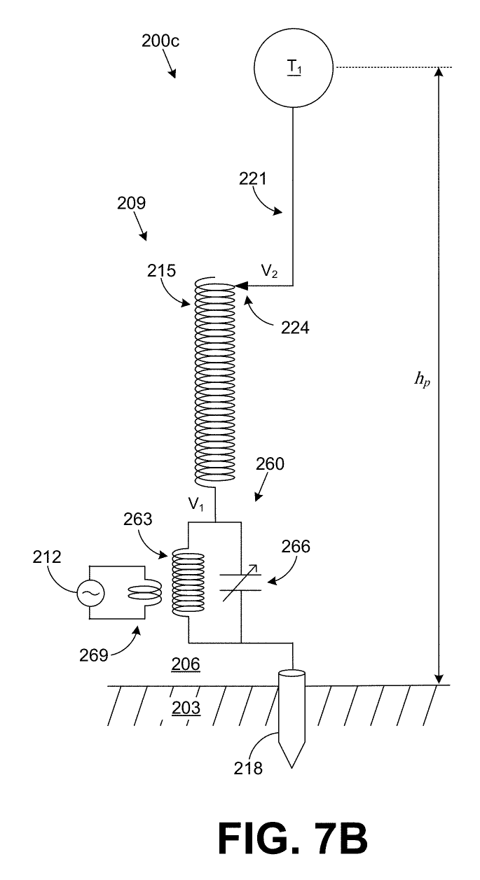

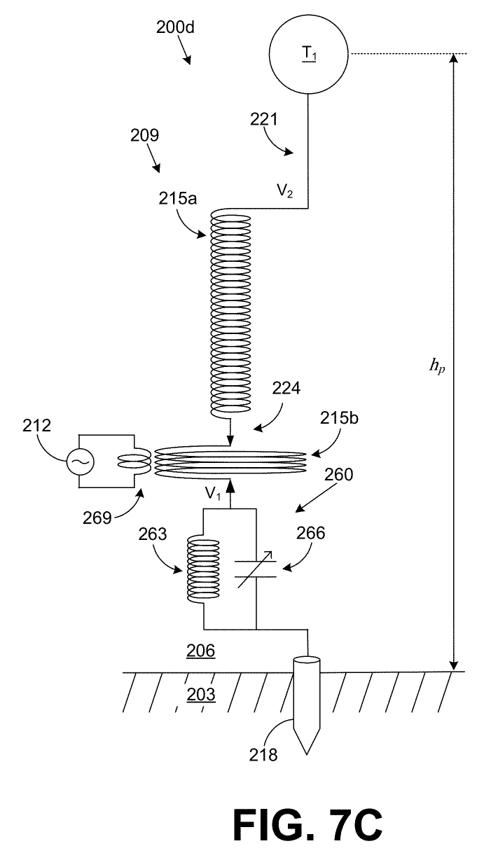

Referring to FIG. 7A, shown is a graphical representation of an example of a guided surface waveguide probe 200b that includes a charge terminal T₁. As shown in FIG. 7A, an excitation source 212 such as an AC source acts as the excitation source for the charge terminal T₁, which is coupled to the guided surface waveguide probe 200b through a feed network 209 (FIG. 3) comprising a coil 215 such as, e.g., a helical coil. In other implementations, the excitation source 212 can be inductively coupled to the coil 215 through a primary coil. In some embodiments, an impedance matching network may be included to improve and/or maximize coupling of the excitation source 212 to the coil 215.

As shown in FIG. 7A, the guided surface waveguide probe 200b can include the upper charge terminal T₁ (e.g., a sphere at height hₚ) that is positioned along a vertical axis z that is substantially normal to the plane presented by the lossy conducting medium 203. A second medium 206 is located above the lossy conducting medium 203. The charge terminal T₁ has a self-capacitance C_{T}. During operation, charge Q₁ is imposed on the terminal T₁ depending on the voltage applied to the terminal T₁ at any given instant.

In the example of FIG. 7A, the coil 215 is coupled to a ground stake (or grounding system) 218 at a first end and to the charge terminal T₁ via a vertical feed line conductor 221. In some implementations, the coil connection to the charge terminal T₁ can be adjusted using a tap 224 of the coil 215 as shown in FIG. 7A. The coil 215 can be energized at an operating frequency by the excitation source 212 comprising, for example, an excitation source through a tap 227 at a lower portion of the coil 215. In other implementations, the excitation source 212 can be inductively coupled to the coil 215 through a primary coil. The charge terminal T₁ can be configured to adjust its load impedance seen by the vertical feed line conductor 221, which can be used to adjust the probe impedance.

FIG. 7B shows a graphical representation of another example of a guided surface waveguide probe 200c that includes a charge terminal T₁. As in FIG. 7A, the guided surface waveguide probe 200c can include the upper charge terminal T₁ positioned over the lossy conducting medium 203 (e.g., at height hₚ). In the example of FIG. 7B, the phasing coil 215 is coupled at a first end to a ground stake (or grounding system) 218 via a lumped element tank circuit 260 and to the charge terminal T₁ at a second end via a vertical feed line conductor 221. The phasing coil 215 can be energized at an operating frequency by the excitation source 212 through, e.g., a tap 227 at a lower portion of the coil 215, as shown in FIG. 7A. In other implementations, the excitation source 212 can be inductively coupled to the phasing coil 215 or an inductive coil 263 of a tank circuit 260 through a primary coil 269. The inductive coil 263 may also be called a “lumped element” coil as it behaves as a lumped element or inductor. In the example of FIG. 7B, the phasing coil 215 is energized by the excitation source 212 through inductive coupling with the inductive coil 263 of the lumped element tank circuit 260. The lumped element tank circuit 260 comprises the inductive coil 263 and a capacitor 266. The inductive coil 263 and/or the capacitor 266 can be fixed or variable to allow for adjustment of the tank circuit resonance, and thus the probe impedance.

FIG. 7C shows a graphical representation of another example of a guided surface waveguide probe 200d that includes a charge terminal T₁. As in FIG. 7A, the guided surface waveguide probe 200d can include the upper charge terminal T₁ positioned over the lossy conducting medium 203 (e.g., at height hₚ). The feed network 209 can comprise a plurality of phasing coils (e.g., helical coils) instead of a single phasing coil 215 as illustrated in FIGS. 7A and 7B. The plurality of phasing coils can include a combination of helical coils to provide the appropriate phase delay (e.g., θ_{c}=θ_{ca}+θ_{cb}, where θ_{ca} and θ_{cb} correspond to the phase delays of coils 215a and 215b, respectively) to launch a guided surface wave. In the example of FIG. 7C, the feed network includes two phasing coils 215a and 215b connected in series with the lower coil 215b coupled to a ground stake (or grounding system) 218 via a lumped element tank circuit 260 and the upper coil 215a coupled to the charge terminal T₁ via a vertical feed line conductor 221. The phasing coils 215a and 215b can be energized at an operating frequency by the excitation source 212 through, e.g., inductive coupling via a primary coil 269 with, e.g., the upper phasing coil 215a, the lower phasing coil 215b, and/or an inductive coil 263 of the tank circuit 260. For example, as shown in FIG. 7C, the coil 215 can be energized by the excitation source 212 through inductive coupling from the primary coil 269 to the lower phasing coil 215b. Alternatively, as in the example shown in FIG. 7B, the coil 215 can be energized by the excitation source 212 through inductive coupling from the primary coil 269 to the inductive coil 263 of the lumped element tank circuit 260. The inductive coil 263 and/or the capacitor 266 of the lumped element tank circuit 260 can be fixed or variable to allow for adjustment of the tank circuit resonance, and thus the probe impedance.

At this point, it should be pointed out that there is a distinction between phase delays for traveling waves and phase shifts for standing waves. Phase delays for traveling waves, θ=βl, are due to propagation time delays on distributed element wave guiding structures such as, e.g., the coil(s) 215 and vertical feed line conductor 221. A phase delay is not experienced as the traveling wave passes through the lumped element tank circuit 260. As a result, the total traveling wave phase delay through, e.g., the guided surface waveguide probes 200c and 200d is still Φ=θ_{c}+θ_{y}.

However, the position dependent phase shifts of standing waves, which comprise forward and backward propagating waves, and load dependent phase shifts depend on both the line-length propagation delay and at transitions between line sections of different characteristic impedances. It should be noted that phase shifts do occur in lumped element circuits. Phase shifts also occur at the impedance discontinuities between transmission line segments and between line segments and loads. This comes from the complex reflection coefficient, Γ=|Γ|e^{jϕ}, arising from the impedance discontinuities, and results in standing waves (wave interference patterns of forward and backward propagating waves) on the distributed element structures. As a result, the total standing wave phase shift of the guided surface waveguide probes 200c and 200d includes the phase shift produced by the lumped element tank circuit 260.

Accordingly, it should be noted that coils that produce both a phase delay for a traveling wave and a phase shift for standing waves can be referred to herein as “phasing coils.” The coils 215 are examples of phasing coils. It should be further noted that coils in a tank circuit, such as the lumped element tank circuit 260 as described above, act as a lumped element and an inductor, where the tank circuit produces a phase shift for standing waves without a corresponding phase delay for traveling waves. Such coils acting as lumped elements or inductors can be referred to herein as “inductor coils” or “lumped element” coils. Inductive coil 263 is an example of such an inductor coil or lumped element coil. Such inductor coils or lumped element coils are assumed to have a uniform current distribution throughout the coil, and are electrically small relative to the wavelength of operation of the guided surface waveguide probe 200 such that they produce a negligible delay of a traveling wave.

The construction and adjustment of the guided surface waveguide probe 200 is based upon various operating conditions, such as the transmission frequency, conditions of the lossy conducting medium (e.g., soil conductivity a and relative permittivity εᵣ), and size of the charge terminal T₁. The index of refraction can be calculated from Equations (10) and (11) as

n=\sqrt{εᵣ−jx}, (41)

where x=σ/ωεₒ with ω=2πf. The conductivity σ and relative permittivity εᵣ can be determined through test measurements of the lossy conducting medium 203. The complex Brewster angle (θ_{i,B}) measured from the surface normal can also be determined from Equation (26) as

θ_{i,B}=arc tan(\sqrt{εᵣ−jx}), (42)

or measured from the surface as shown in FIG. 5A as

$${ψ}_{i , B} = \frac{π}{2} - {θ}_{i , B} . \qquad ( 43 )$$

The wave tilt at the Hankel crossover distance (W_{Rx}) can also be found using Equation (40).

The Hankel crossover distance can also be found by equating the magnitudes of Equations (20b) and (21) for −jγρ, and solving for Rₓ as illustrated by FIG. 4. The electrical effective height can then be determined from Equation (39) using the Hankel crossover distance and the complex Brewster angle as

h_{eff}=hₚe^{jΦ}=Rₓ tan ψ_{i,B} (44)

As can be seen from Equation (44), the complex effective height (h_{eff}) includes a magnitude that is associated with the physical height (hₚ) of the charge terminal T₁ and a phase delay)) that is to be associated with the angle (Ψ) of the wave tilt at the Hankel crossover distance (Rₓ). With these variables and the selected charge terminal T₁ configuration, it is possible to determine the configuration of a guided surface waveguide probe 200.

With the charge terminal T₁ positioned at or above the physical height (hₚ), the feed network 209 (FIG. 3) and/or the vertical feed line connecting the feed network to the charge terminal T₁ can be adjusted to match the phase delay (Φ) of the charge Q₁ on the charge terminal T₁ to the angle (Ψ) of the wave tilt (W). The size of the charge terminal T₁ can be chosen to provide a sufficiently large surface for the charge Q₁ imposed on the terminals. In general, it is desirable to make the charge terminal T₁ as large as practical. The size of the charge terminal T₁ should be large enough to avoid ionization of the surrounding air, which can result in electrical discharge or sparking around the charge terminal.

The phase delay θ_{c} of a helically-wound coil can be determined from Maxwell's equations as has been discussed by Corum, K. L. and J. F. Corum, “RF Coils, Helical Resonators and Voltage Magnification by Coherent Spatial Modes,” Microwave Review, Vol. 7, No. 2, September 2001, pp. 36-45. For a helical coil with H/D>1, the ratio of the velocity of propagation (υ) of a wave along the coil's longitudinal axis to the speed of light (c), or the “velocity factor,” is given by

$${V}_{f} = \frac{υ}{c} = \frac{1}{\sqrt{1 + 20 {( \frac{D}{s} )}^{2.5} {( \frac{D}{{λ}_{0}} )}^{0.5}}} , \qquad ( 45 )$$

where H is the axial length of the solenoidal helix, D is the coil diameter, N is the number of turns of the coil, s=H/N is the turn-to-turn spacing (or helix pitch) of the coil, and λₒ is the free-space wavelength. Based upon this relationship, the electrical length, or phase delay, of the helical coil is given by

$${θ}_{c} = {β}_{p} H = \frac{2 π}{{λ}_{p}} H = \frac{2 π}{{V}_{f} {λ}_{0}} H . \qquad ( 46 )$$

The principle is the same if the helix is wound spirally or is short and fat, but V_{f} and θ_{c} are easier to obtain by experimental measurement. The expression for the characteristic (wave) impedance of a helical transmission line has also been derived as

$${Z}_{c} = \frac{60}{{V}_{f}} [ 𝓁 n ( \frac{{V}_{f} {λ}_{0}}{D} ) - 1.027 ] . \qquad ( 47 )$$

The spatial phase delay θ_{y} of the structure can be determined using the traveling wave phase delay of the vertical feed line conductor 221 (FIGS. 7A-7C). The capacitance of a cylindrical vertical conductor above a prefect ground plane can be expressed as

$${C}_{A} = \frac{2 π {ɛ}_{0} {h}_{w}}{𝓁 n ( \frac{h}{a} ) - 1} Farads , \qquad ( 48 )$$

where h_{w} is the vertical length (or height) of the conductor and a is the radius (in mks units). As with the helical coil, the traveling wave phase delay of the vertical feed line conductor can be given by

$${θ}_{y} = {β}_{w} {h}_{w} = \frac{2 π}{{λ}_{w}} {h}_{w} = \frac{2 π}{{V}_{w} {λ}_{0}} {h}_{w} , \qquad ( 49 )$$

where β_{w} is the propagation phase constant for the vertical feed line conductor, h_{w} is the vertical length (or height) of the vertical feed line conductor, V_{w} is the velocity factor on the wire, λ₀ is the wavelength at the supplied frequency, and λ_{w} is the propagation wavelength resulting from the velocity factor V_{w}. For a uniform cylindrical conductor, the velocity factor is a constant with V_{w}≈0.94, or in a range from about 0.93 to about 0.98. If the mast is considered to be a uniform transmission line, its average characteristic impedance can be approximated by

$${Z}_{w} = \frac{60}{{V}_{w}} [ 𝓁 n ( \frac{{h}_{w}}{a} ) - 1 ] , \qquad ( 50 )$$

where V_{w}≈0.94 for a uniform cylindrical conductor and a is the radius of the conductor. An alternative expression that has been employed in amateur radio literature for the characteristic impedance of a single-wire feed line can be given by

$${Z}_{w} = 138 log ( \frac{1.123 {V}_{w} {λ}_{0}}{2 π a} ) . \qquad ( 51 )$$

Equation (51) implies that Z_{w} for a single-wire feeder varies with frequency. The phase delay can be determined based upon the capacitance and characteristic impedance.

With a charge terminal T₁ positioned over the lossy conducting medium 203 as shown in FIG. 3, the feed network 209 can be adjusted to excite the charge terminal T₁ with the phase delay (Φ) of the complex effective height (h_{eff}) equal to the angle (Ψ) of the wave tilt at the Hankel crossover distance, or Φ=W. When this condition is met, the electric field produced by the charge oscillating Q₁ on the charge terminal T₁ is coupled into a guided surface waveguide mode traveling along the surface of a lossy conducting medium 203. For example, if the Brewster angle (θ_{i,B}), the phase delay (θ_{y}) associated with the vertical feed line conductor 221 (FIGS. 7A-7C), and the configuration of the coil(s) 215 (FIGS. 7A-7C) are known, then the position of the tap 224 (FIGS. 7A-7C) can be determined and adjusted to impose an oscillating charge Q₁ on the charge terminal T₁ with phase Φ=Ψ. The position of the tap 224 may be adjusted to maximize coupling the traveling surface waves into the guided surface waveguide mode. Excess coil length beyond the position of the tap 224 can be removed to reduce the capacitive effects. The vertical wire height and/or the geometrical parameters of the helical coil may also be varied.

The coupling to the guided surface waveguide mode on the surface of the lossy conducting medium 203 can be improved and/or optimized by tuning the guided surface waveguide probe 200 for standing wave resonance with respect to a complex image plane associated with the charge Q₁ on the charge terminal T₁. By doing this, the performance of the guided surface waveguide probe 200 can be adjusted for increased and/or maximum voltage (and thus charge Q₁) on the charge terminal T₁. Referring back to FIG. 3, the effect of the lossy conducting medium 203 in Region 1 can be examined using image theory analysis.

Physically, an elevated charge Q₁ placed over a perfectly conducting plane attracts the free charge on the perfectly conducting plane, which then “piles up” in the region under the elevated charge Q₁. The resulting distribution of “bound” electricity on the perfectly conducting plane is similar to a bell-shaped curve. The superposition of the potential of the elevated charge Q₁, plus the potential of the induced “piled up” charge beneath it, forces a zero equipotential surface for the perfectly conducting plane. The boundary value problem solution that describes the fields in the region above the perfectly conducting plane may be obtained using the classical notion of image charges, where the field from the elevated charge is superimposed with the field from a corresponding “image” charge below the perfectly conducting plane.

This analysis may also be used with respect to a lossy conducting medium 203 by assuming the presence of an effective image charge Q₁′ beneath the guided surface waveguide probe 200. The effective image charge Q₁′ coincides with the charge Q₁ on the charge terminal T₁ about a conducting image ground plane 130, as illustrated in FIG. 3. However, the image charge Q₁′ is not merely located at some real depth and 180° out of phase with the primary source charge Q₁ on the charge terminal T₁, as they would be in the case of a perfect conductor. Rather, the lossy conducting medium 203 (e.g., a terrestrial medium) presents a phase shifted image. That is to say, the image charge Q₁′ is at a complex depth below the surface (or physical boundary) of the lossy conducting medium 203. For a discussion of complex image depth, reference is made to Wait, J. R., “Complex Image Theory—Revisited,” IEEE Antennas and Propagation Magazine, Vol. 33, No. 4, August 1991, pp. 27-29.

Instead of the image charge Q₁′ being at a depth that is equal to the physical height (H₁) of the charge Q₁, the conducting image ground plane 130 (representing a perfect conductor) is located at a complex depth of z=−d/2 and the image charge Q₁′ appears at a complex depth (i.e., the “depth” has both magnitude and phase), given by −D₁=−(d/2+d/2+H₁)≠H₁. For vertically polarized sources over the Earth,

$$d = \frac{2 \sqrt{{γ}_{e}^{2} + {k}_{0}^{2}}}{{γ}_{e}^{2}} \approx \frac{2}{{γ}_{e}} = {d}_{r} + {jd}_{i} = \vert d \vert ∠ζ , \qquad ( 52 )$$

where

Yₑ²=jωμ₁σ₁−ω²μ₁ε₁, and (53)

kₒ=ω\sqrt{μₒεₒ}, (54)

as indicated in Equation (12). The complex spacing of the image charge, in turn, implies that the external field will experience extra phase shifts not encountered when the interface is either a dielectric or a perfect conductor. In the lossy conducting medium, the wave front normal is parallel to the tangent of the conducting image ground plane 130 at z=−d/2, and not at the boundary interface between Regions 1 and 2.

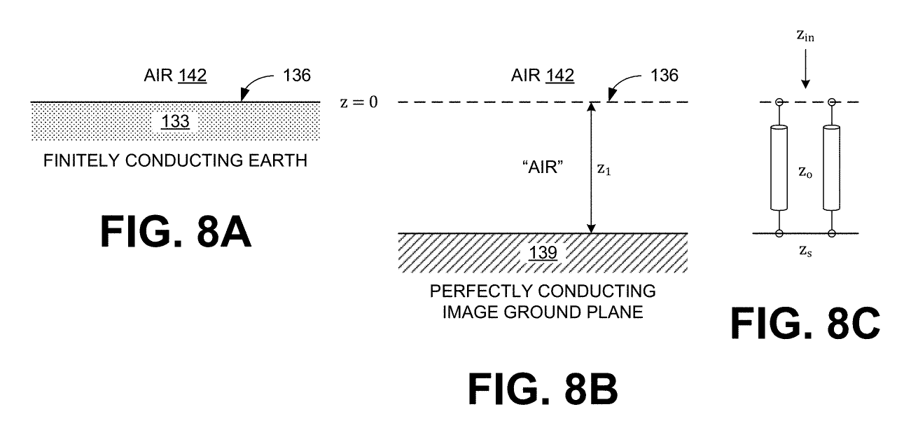

Consider the case illustrated in FIG. 8A where the lossy conducting medium 203 is a finitely conducting Earth 133 with a physical boundary 136. The finitely conducting Earth 133 may be replaced by a perfectly conducting image ground plane 139 as shown in FIG. 8B, which is located at a complex depth z₁ below the physical boundary 136. This equivalent representation exhibits the same impedance when looking down into the interface at the physical boundary 136. The equivalent representation of FIG. 8B can be modeled as an equivalent transmission line, as shown in FIG. 8C. The cross-section of the equivalent structure is represented as a (z-directed) end-loaded transmission line, with the impedance of the perfectly conducting image plane being a short circuit (zₛ=0). The depth z₁ can be determined by equating the TEM wave impedance looking down at the Earth to an image ground plane impedance zᵢₙ seen looking into the transmission line of FIG. 8C.

In the case of FIG. 8A, the propagation constant and wave intrinsic impedance in the upper region (air) 142 are

$$\begin{matrix}{γ}_{o} = j ω \sqrt{{μ}_{o} {ɛ}_{o}} = 0 + j {β}_{o} , and & ( 55 ) \\ {z}_{o} = \frac{j ω {μ}_{o}}{{γ}_{o}} = \sqrt{\frac{{μ}_{o}}{{ɛ}_{o}}} . & ( 56 )\end{matrix}$$

In the lossy Earth 133, the propagation constant and wave intrinsic impedance are

$$\begin{matrix}{γ}_{e} = \sqrt{j ω {μ}_{1} ( {σ}_{1} + j ω {ɛ}_{1} )} , and & ( 57 ) \\ {Z}_{e} = \frac{j ω {μ}_{1}}{{γ}_{e}} . & ( 58 )\end{matrix}$$

For normal incidence, the equivalent representation of FIG. 8B is equivalent to a TEM transmission line whose characteristic impedance is that of air (z₀), with propagation constant of γₒ, and whose length is z₁. As such, the image ground plane impedance Zᵢₙ seen at the interface for the shorted transmission line of FIG. 8C is given by

Zᵢₙ=Zₒ tan h(γₒz₁). (59)

Equating the image ground plane impedance Zᵢₙ associated with the equivalent model of FIG. 8C to the normal incidence wave impedance of FIG. 8A and solving for z₁ gives the distance to a short circuit (the perfectly conducting image ground plane 139) as

$${z}_{1} = \frac{1}{{γ}_{o}} tan {h}^{- 1} ( \frac{{Z}_{e}}{{Z}_{o}} ) = \frac{1}{{γ}_{o}} tan {h}^{- 1} ( \frac{{γ}_{o}}{{γ}_{e}} ) \approx \frac{1}{{γ}_{e}} , \qquad ( 60 )$$

where only the first term of the series expansion for the inverse hyperbolic tangent is considered for this approximation. Note that in the air region 142, the propagation constant is γₒ=jβₒ, so Zᵢₙ=jZₒ tan βₒz₁ (which is a purely imaginary quantity for a real z₁), but zₑ is a complex value if σ≠0. Therefore, Zᵢₙ=Zₑ only when z₁ is a complex distance.

Since the equivalent representation of FIG. 8B includes a perfectly conducting image ground plane 139, the image depth for a charge or current lying at the surface of the Earth (physical boundary 136) is equal to distance z₁ on the other side of the image ground plane 139, or d=2×z₁ beneath the Earth's surface (which is located at z=0). Thus, the distance to the perfectly conducting image ground plane 139 can be approximated by

$$d = 2 {z}_{1} \approx \frac{2}{{γ}_{e}} . \qquad ( 61 )$$

Additionally, the “image charge” will be “equal and opposite” to the real charge, so the potential of the perfectly conducting image ground plane 139 at depth z₁=−d/2 will be zero.

If a charge Q₁ is elevated a distance H₁ above the surface of the Earth as illustrated in FIG. 3, then the image charge Q₁′ resides at a complex distance of D₁=d+H₁ below the surface, or a complex distance of d/2+H₁ below the image ground plane 130. The guided surface waveguide probes 200 of FIGS. 7A-7C can be modeled as an equivalent single-wire transmission line image plane model that can be based upon the perfectly conducting image ground plane 139 of FIG. 8B.

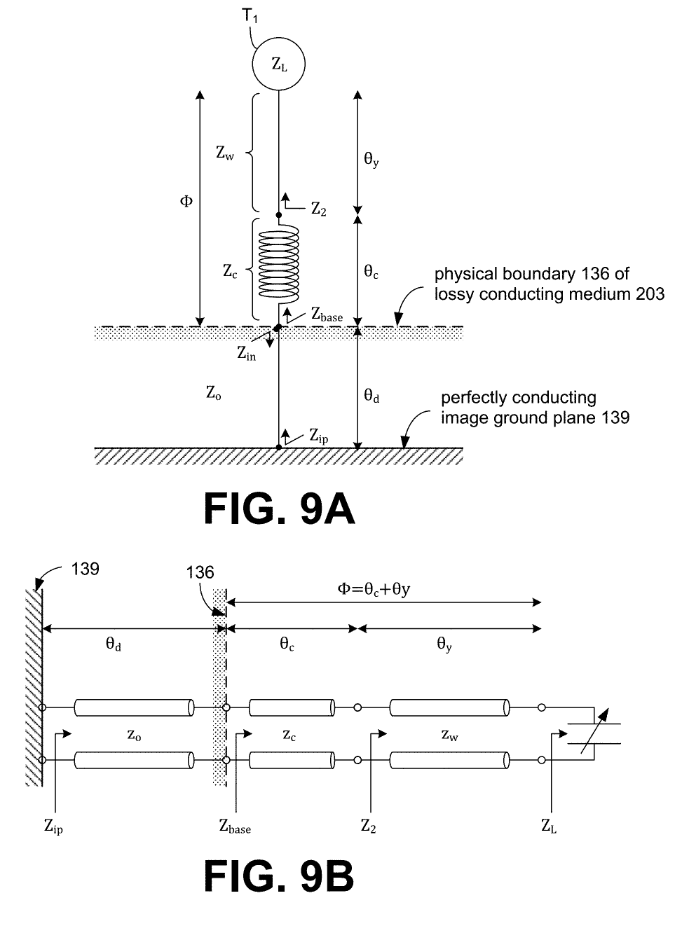

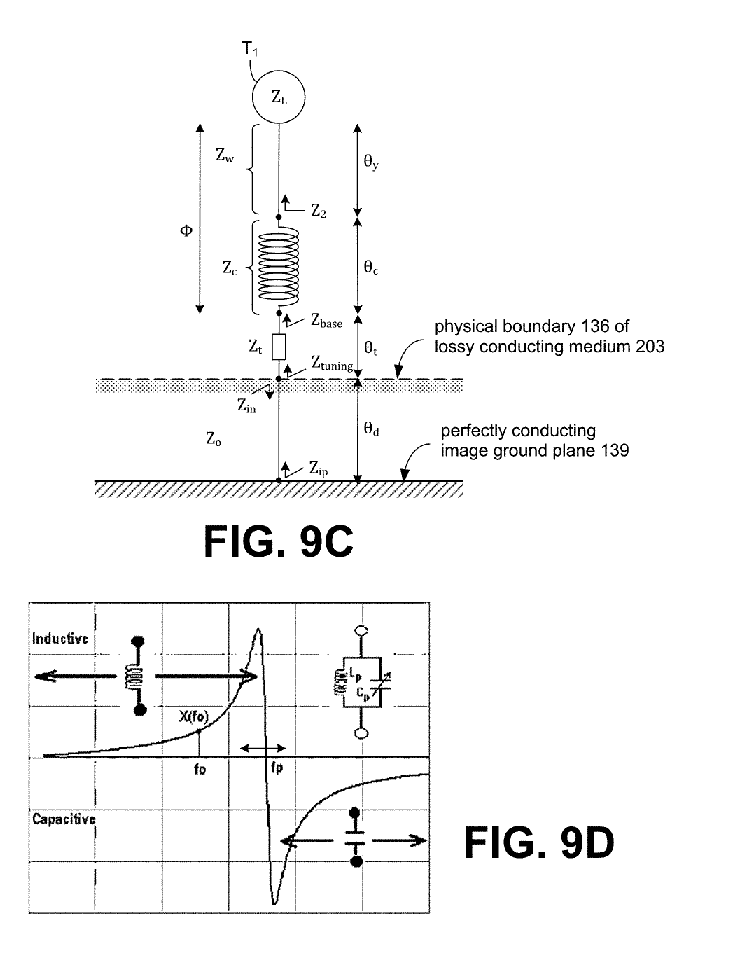

FIG. 9A shows an example of the equivalent single-wire transmission line image plane model, and FIG. 9B illustrates an example of the equivalent classic transmission line model, including the shorted transmission line of FIG. 8C. FIG. 9C illustrates an example of the equivalent classic transmission line model including the lumped element tank circuit 260.

In the equivalent image plane models of FIGS. 9A-9C, Φ=θ_{y}+θ_{c} is the traveling wave phase delay of the guided surface waveguide probe 200 referenced to Earth 133 (or the lossy conducting medium 203), θ_{c}=βₚH is the electrical length of the coil or coils 215 (FIGS. 7A-7C), of physical length H, expressed in degrees, θ_{y}=β_{w}h_{w} is the electrical length of the vertical feed line conductor 221 (FIGS. 7A-7C), of physical length h_{w}, expressed in degrees. In addition, θ_{d}=βₒ d/2 is the phase shift between the image ground plane 139 and the physical boundary 136 of the Earth 133 (or lossy conducting medium 203). In the example of FIGS. 9A-9C, Z_{w} is the characteristic impedance of the elevated vertical feed line conductor 221 in ohms, Z_{c} is the characteristic impedance of the coil(s) 215 in ohms, and Z₀ is the characteristic impedance of free space. In the example of FIG. 9C, Zₜ is the characteristic impedance of the lumped element tank circuit 260 in ohms and θₜ is the corresponding phase shift at the operating frequency.

At the base of the guided surface waveguide probe 200, the impedance seen “looking up” into the structure is Z_{↑}=Z_{base}. With a load impedance of:

$${Z}_{L} = \frac{1}{j ω {C}_{T}} , \qquad ( 62 )$$

where C_{T} is the self-capacitance of the charge terminal T₁, the impedance seen “looking up” into the vertical feed line conductor 221 (FIGS. 7A-7C) is given by:

$${Z}_{2} = {Z}_{w} \frac{{Z}_{L} + {Z}_{w} tanh ( j {β}_{w} {h}_{w} )}{{Z}_{w} + {Z}_{L} tanh ( j {β}_{w} {h}_{w} )} = {Z}_{w} \frac{{Z}_{L} + {Z}_{w} tanh ( j {θ}_{y} )}{{Z}_{w} + {Z}_{L} tanh ( j {θ}_{y} )} , \qquad ( 63 )$$

and the impedance seen “looking up” into the coil 215 (FIGS. 7A and 7B) is given by:

$${Z}_{base} = {Z}_{c} \frac{{Z}_{2} + {Z}_{c} tanh ( j {β}_{p} H )}{{Z}_{c} + {Z}_{2} tanh ( j {β}_{p} H )} = {Z}_{c} \frac{{Z}_{2} + {Z}_{c} tanh ( j {θ}_{c} )}{{Z}_{c} + {Z}_{2} tan h ( j {θ}_{c} )} , \qquad ( 64 )$$

Where the feed network 209 includes a plurality of coils 215 (e.g., FIG. 7C), the impedance seen at the base of each coil 215 can be sequentially determined using Equation (64). For example, the impedance seen “looking up” into the upper coil 215a of FIG. 7C is given by:

$${Z}_{coil} = {Z}_{ca} \frac{{Z}_{2} + {Z}_{ca} tanh ( j {β}_{p} H )}{{Z}_{ca} + {Z}_{2} tanh ( j {β}_{p} H )} = {Z}_{ca} \frac{{Z}_{2} + {Z}_{ca} tanh ( j {θ}_{ca} )}{{Z}_{ca} + {Z}_{2} tanh ( j {θ}_{ca} )} , \qquad ( 64.1 )$$

and the impedance seen “looking up” into the lower coil 215b of FIG. 7C can be given by:

$${Z}_{base} = {Z}_{cb} \frac{{Z}_{coil} + {Z}_{cb} tanh ( j {β}_{p} H )}{{Z}_{cb} + {Z}_{coil} tanh ( j {β}_{p} H )} = {Z}_{cb} \frac{{Z}_{coil} + {Z}_{cb} tanh ( j {θ}_{cb} )}{{Z}_{cb} + {Z}_{coil} tanh ( j {θ}_{c} b )} , \qquad ( 64.2 )$$

where Z_{ca} and Z_{cb} are the characteristic impedances of the upper and lower coils. This can be extended to account for additional coils 215 as needed. At the base of the guided surface waveguide probe 200, the impedance seen “looking down” into the lossy conducting medium 203 is Z_{↓}=Zᵢₙ, which is given by:

$${Z}_{in} = {Z}_{o} \frac{{Z}_{s} + {Z}_{o} tanh [ j {β}_{o} ( d \text{/} 2 ) ]}{{Z}_{o} + {Z}_{s} tanh [ j {β}_{o} ( d \text{/} 2 ) ]} = {Z}_{o} tanh ( j {θ}_{d} ) , \qquad ( 65 )$$

where Zₛ=0.

Neglecting losses, the equivalent image plane model can be tuned to resonance when Z_{↓}+Z_{↑}=0 at the physical boundary 136. Or, in the low loss case, X_{↓}+X_{↑}=0 at the physical boundary 136, where X is the corresponding reactive component. Thus, the impedance at the physical boundary 136 “looking up” into the guided surface waveguide probe 200 is the conjugate of the impedance at the physical boundary 136 “looking down” into the lossy conducting medium 203. By adjusting the probe impedance via the load impedance Z_{L} of the charge terminal T₁ while maintaining the traveling wave phase delay Φ equal to the angle of the media's wave tilt IF, so that Φ=Ψ, which improves and/or maximizes coupling of the probe's electric field to a guided surface waveguide mode along the surface of the lossy conducting medium 203 (e.g., Earth), the equivalent image plane models of FIGS. 9A and 9B can be tuned to resonance with respect to the image ground plane 139. In this way, the impedance of the equivalent complex image plane model is purely resistive, which maintains a superposed standing wave on the probe structure that maximizes the voltage and elevated charge on terminal T₁, and by equations (1)-(3) and (16) maximizes the propagating surface wave.

While the load impedance Z_{L} of the charge terminal T₁ can be adjusted to tune the probe 200 for standing wave resonance with respect to the image ground plane 139, in some embodiments a lumped element tank circuit 260 located between the coil(s) 215 (FIGS. 7B and 7C) and the ground stake (or grounding system) 218 can be adjusted to tune the probe 200 for standing wave resonance with respect to the image ground plane 139 as illustrated in FIG. 9C. A phase delay is not experienced as the traveling wave passes through the lumped element tank circuit 260. As a result, the total traveling wave phase delay through, e.g., the guided surface waveguide probes 200c and 200d is still Φ=θ_{c}+θ_{y}. However, it should be noted that phase shifts do occur in lumped element circuits. Phase shifts also occur at impedance discontinuities between transmission line segments and between line segments and loads. Thus, the tank circuit 260 may also be referred to as a “phase shift circuit.”

With the lumped element tank circuit 260 coupled to the base of the guided surface waveguide probe 200, the impedance seen “looking up” into the tank circuit 260 is Z_{↑}=Z_{tuning}, which can be given by:

Z_{tuning}=Z_{base}−Zₜ,

where Zₜ is the characteristic impedance of the tank circuit 260 and Z_{base} is the impedance seen “looking up” into the coil(s) as given in, e.g., Equations (64) or (64.2). FIG. 9D illustrates the variation of the impedance of the lumped element tank circuit 260 with respect to operating frequency (fₒ) based upon the resonant frequency (fₚ) of the tank circuit 260. As shown in FIG. 9D, the impedance of the lumped element tank 260 can be inductive or capacitive depending on the tuned self-resonant frequency of the tank circuit. When operating the tank circuit 260 at a frequency below its self-resonant frequency (fₚ), its terminal point impedance is inductive, and for operation above fₚ the terminal point impedance is capacitive. Adjusting either the inductance 263 or the capacitance 266 of the tank circuit 260 changes fₚ and shifts the impedance curve in FIG. 9D, which affects the terminal point impedance seen at a given operating frequency fₒ.

Neglecting losses, the equivalent image plane model with the tank circuit 260 can be tuned to resonance when Z_{↓}+Z_{↑}=0 at the physical boundary 136. Or, in the low loss case, X_{↓}+X_{↑}=0 at the physical boundary 136, where X is the corresponding reactive component. Thus, the impedance at the physical boundary 136 “looking up” into the lumped element tank circuit 260 is the conjugate of the impedance at the physical boundary 136 “looking down” into the lossy conducting medium 203. By adjusting the lumped element tank circuit 260 while maintaining the traveling wave phase delay Φ equal to the angle of the media's wave tilt Ψ, so that Φ=Ψ, the equivalent image plane models can be tuned to resonance with respect to the image ground plane 139. In this way, the impedance of the equivalent complex image plane model is purely resistive, which maintains a superposed standing wave on the probe structure that maximizes the voltage and elevated charge on terminal T₁, and improves and/or maximizes coupling of the probe's electric field to a guided surface waveguide mode along the surface of the lossy conducting medium 203 (e.g., earth).

It follows from the Hankel solutions, that the guided surface wave excited by the guided surface waveguide probe 200 is an outward propagating traveling wave. The source distribution along the feed network 209 between the charge terminal T₁ and the ground stake (or grounding system) 218 of the guided surface waveguide probe 200 (FIGS. 3 and 7A-7C) is actually composed of a superposition of a traveling wave plus a standing wave on the structure. With the charge terminal T₁ positioned at or above the physical height hₚ, the phase delay of the traveling wave moving through the feed network 209 is matched to the angle of the wave tilt associated with the lossy conducting medium 203. This mode-matching allows the traveling wave to be launched along the lossy conducting medium 203. Once the phase delay has been established for the traveling wave, the load impedance Z_{L} of the charge terminal T₁ and/or the lumped element tank circuit 260 can be adjusted to bring the probe structure into standing wave resonance with respect to the image ground plane (130 of FIG. 3 or 139 of FIG. 8), which is at a complex depth of −d/2. In that case, the impedance seen from the image ground plane has zero reactance and the charge on the charge terminal T₁ is maximized.

The distinction between the traveling wave phenomenon and standing wave phenomena is that (1) the phase delay of traveling waves (θ=βd) on a section of transmission line of length d (sometimes called a “delay line”) is due to propagation time delays; whereas (2) the position-dependent phase of standing waves (which are composed of forward and backward propagating waves) depends on both the line length propagation time delay and impedance transitions at interfaces between line sections of different characteristic impedances. In addition to the phase delay that arises due to the physical length of a section of transmission line operating in sinusoidal steady-state, there is an extra reflection coefficient phase at impedance discontinuities that is due to the ratio of Zₒₐ/Z_{ob}, where Zₒₐ and Z_{ob} are the characteristic impedances of two sections of a transmission line such as, e.g., a helical coil section of characteristic impedance Zₒₐ=Z_{c} (FIG. 9B) and a straight section of vertical feed line conductor of characteristic impedance Z_{ob}=Z_{w} (FIG. 9B).

As a result of this phenomenon, two relatively short transmission line sections of widely differing characteristic impedance may be used to provide a very large phase shift. For example, a probe structure composed of two sections of transmission line, one of low impedance and one of high impedance, together totaling a physical length of, say, 0.05λ, may be fabricated to provide a phase shift of 90°, which is equivalent to a 0.25λ resonance. This is due to the large jump in characteristic impedances. In this way, a physically short probe structure can be electrically longer than the two physical lengths combined. This is illustrated in FIGS. 9A and 9B, where the discontinuities in the impedance ratios provide large jumps in phase. The impedance discontinuity provides a substantial phase shift where the sections are joined together.

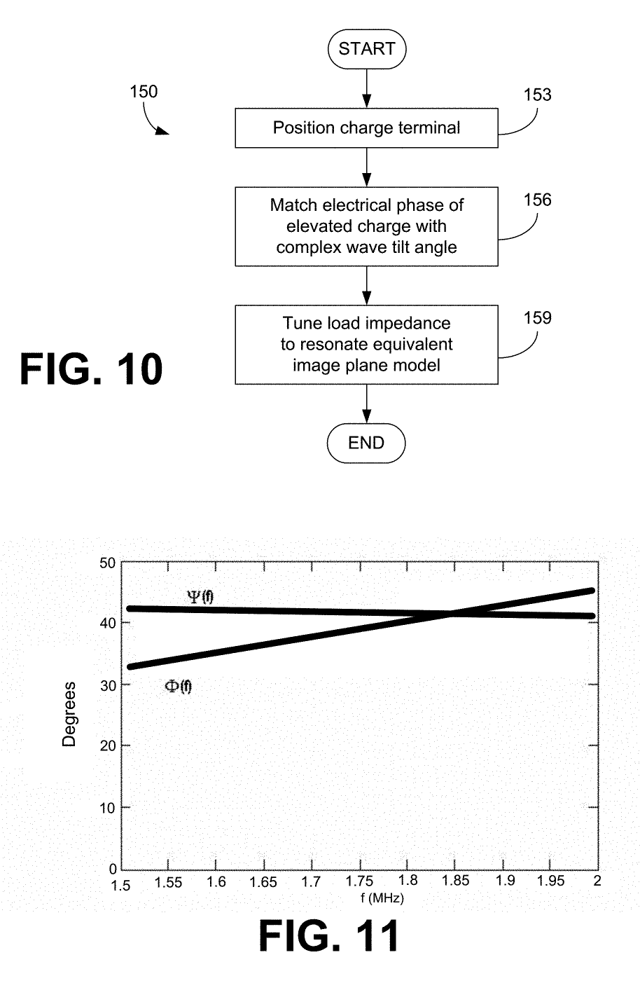

Referring to FIG. 10, shown is a flow chart 150 illustrating an example of adjusting a guided surface waveguide probe 200 (FIGS. 3 and 7A-7C) to substantially mode-match to a guided surface waveguide mode on the surface of the lossy conducting medium, which launches a guided surface traveling wave along the surface of a lossy conducting medium 203 (FIGS. 3 and 7A-7C). Beginning with 153, the charge terminal T₁ of the guided surface waveguide probe 200 is positioned at a defined height above a lossy conducting medium 203. Utilizing the characteristics of the lossy conducting medium 203 and the operating frequency of the guided surface waveguide probe 200, the Hankel crossover distance can also be found by equating the magnitudes of Equations (20b) and (21) for −jγρ, and solving for Rₓ as illustrated by FIG. 4. The complex index of refraction (n) can be determined using Equation (41), and the complex Brewster angle (θ_{i,B}) can then be determined from Equation (42). The physical height (hₚ) of the charge terminal T₁ can then be determined from Equation (44). The charge terminal T₁ should be at or higher than the physical height (hₚ) in order to excite the far-out component of the Hankel function. This height relationship is initially considered when launching surface waves. To reduce or minimize the bound charge on the charge terminal T₁, the height should be at least four times the spherical diameter (or equivalent spherical diameter) of the charge terminal T₁.

At 156, the electrical phase delay Φ of the elevated charge Q₁ on the charge terminal T₁ is matched to the complex wave tilt angle Ψ. The phase delay (θ_{c}) of the helical coil(s) and/or the phase delay (θ_{y}) of the vertical feed line conductor can be adjusted to make Φ equal to the angle (Ψ) of the wave tilt (W). Based on Equation (31), the angle (Ψ) of the wave tilt can be determined from:

$$W = \frac{{E}_{ρ}}{{E}_{z}} = \frac{1}{tan {θ}_{i , B}} = \frac{1}{n} = \vert W \vert {e}^{j Ψ} . \qquad ( 66 )$$

The electrical phase delay Φ can then be matched to the angle of the wave tilt. This angular (or phase) relationship is next considered when launching surface waves. For example, the electrical phase delay Φ=θ_{c}+θ_{y} can be adjusted by varying the geometrical parameters of the coil(s) 215 (FIGS. 7A-7C) and/or the length (or height) of the vertical feed line conductor 221 (FIGS. 7A-7C). By matching Φ=Ψ an electric field can be established at or beyond the Hankel crossover distance (Rₓ) with a complex Brewster angle at the boundary interface to excite the surface waveguide mode and launch a traveling wave along the lossy conducting medium 203.

Next at 159, the impedance of the charge terminal T₁ and/or the lumped element tank circuit 260 can be tuned to resonate the equivalent image plane model of the guided surface waveguide probe 200. The depth (d/2) of the conducting image ground plane 139 of FIGS. 9A and 9B (or 130 of FIG. 3) can be determined using Equations (52), (53) and (54) and the values of the lossy conducting medium 203 (e.g., the Earth), which can be measured. Using that depth, the phase shift (θ_{d}) between the image ground plane 139 and the physical boundary 136 of the lossy conducting medium 203 can be determined using θ_{d}=βₒ d/2. The impedance (Zᵢₙ) as seen “looking down” into the lossy conducting medium 203 can then be determined using Equation (65). This resonance relationship can be considered to maximize the launched surface waves.

Based upon the adjusted parameters of the coil(s) 215 and the length of the vertical feed line conductor 221, the velocity factor, phase delay, and impedance of the coil(s) 215 and vertical feed line conductor 221 can be determined using Equations (45) through (51). In addition, the self-capacitance (C_{T}) of the charge terminal T₁ can be determined using, e.g., Equation (24). The propagation factor (βₚ) of the coil(s) 215 can be determined using Equation (35) and the propagation phase constant (β_{w}) for the vertical feed line conductor 221 can be determined using Equation (49). Using the self-capacitance and the determined values of the coil(s) 215 and vertical feed line conductor 221, the impedance (Z_{base}) of the guided surface waveguide probe 200 as seen “looking up” into the coil(s) 215 can be determined using Equations (62), (63), (64), (64.1) and/or (64.2).

The equivalent image plane model of the guided surface waveguide probe 200 can be tuned to resonance by, e.g., adjusting the load impedance Z_{L} such that the reactance component X_{base} of Z_{base} cancels out the reactance component Xᵢₙ of Zᵢₙ, or X_{base}+Xᵢₙ=0. Thus, the impedance at the physical boundary 136 “looking up” into the guided surface waveguide probe 200 is the conjugate of the impedance at the physical boundary 136 “looking down” into the lossy conducting medium 203. The load impedance Z_{L} can be adjusted by varying the capacitance (C_{T}) of the charge terminal T₁ without changing the electrical phase delay Φ=θ_{c}+θ_{y} of the charge terminal T₁. An iterative approach may be taken to tune the load impedance Z_{L} for resonance of the equivalent image plane model with respect to the conducting image ground plane 139 (or 130). In this way, the coupling of the electric field to a guided surface waveguide mode along the surface of the lossy conducting medium 203 (e.g., Earth) can be improved and/or maximized.

The equivalent image plane model of the guided surface waveguide probe 200 can also be tuned to resonance by, e.g., adjusting the lumped element tank circuit 260 such that the reactance component X_{tuning} of Z_{tuning} cancels out the reactance component Xᵢₙ of Zᵢₙ, or X_{tuning}+Xᵢₙ=0. Consider the parallel resonance curve in FIG. 9D, whose terminal point impedance at some operating frequency (fₒ) is given by

$${jX}_{T} ( f ) = \frac{( j 2 π {fL}_{p} ) {( j 2 π {fC}_{p} )}^{- 1}}{( j 2 π {fL}_{p} ) + {( j 2 π {fC}_{p} )}^{- 1}} = j \frac{2 π {fL}_{p}}{1 - {( 2 π {fL}_{p} )}^{2} {L}_{p} {C}_{p}} .$$

As Cₚ (or Lₚ) is varied, the self-resonant frequency (fₚ) of the parallel tank circuit 260 changes and the terminal point reactance X_{T}(fₒ) at the frequency of operation varies from inductive (+) to capacitive (−) depending on whether fₒ<fₚ or fₚ<fₒ. By adjusting fₚ, a wide range of reactance at fₒ (e.g., a large inductance L_{eq}(fₒ)=X_{T}(fₒ)/ω or a small capacitance C_{eq}(fₒ)=−1/ωX_{T}(fₒ)) can be seen at the terminals of the tank circuit 260.

To obtain the electrical phase delay (Φ) for coupling into the guided surface waveguide mode, the coil(s) 215 and vertical feed line conductor 221 are usually less than a quarter wavelength. For this, an inductive reactance can be added by the lumped element tank circuit 260 so that the impedance at the physical boundary 136 “looking up” into the lumped element tank circuit 260 is the conjugate of the impedance at the physical boundary 136 “looking down” into the lossy conducting medium 203.

As seen in FIG. 9D, adjusting fₚ of the tank circuit 260 (FIG. 7C) above the operating frequency (fₒ) can provide the needed impedance, without changing the electrical phase delay Φ=θ_{c}+θ_{y} of the charge terminal T₁, to tune for resonance of the equivalent image plane model with respect to the conducting image ground plane 139 (or 130). In some cases, a capacitive reactance may be needed and can be provided by adjusting fₚ of the tank circuit 260 below the operating frequency. In this way, the coupling of the electric field to a guided surface waveguide mode along the surface of the lossy conducting medium 203 (e.g., earth) can be improved and/or maximized.

This may be better understood by illustrating the situation with a numerical example. Consider a guided surface waveguide probe 200b (FIG. 7A) comprising a top-loaded vertical stub of physical height hₚ with a charge terminal T₁ at the top, where the charge terminal T₁ is excited through a helical coil and vertical feed line conductor at an operational frequency (fₒ) of 1.85 MHz. With a height (H₁) of 16 feet and the lossy conducting medium 203 (e.g., Earth) having a relative permittivity of εᵣ=15 and a conductivity of σ₁=0.010 mhos/m, several surface wave propagation parameters can be calculated for fₒ=1.850 MHz. Under these conditions, the Hankel crossover distance can be found to be Rₓ=54.5 feet with a physical height of hₚ=5.5 feet, which is well below the actual height of the charge terminal T₁. While a charge terminal height of H₁=5.5 feet could have been used, the taller probe structure reduced the bound capacitance, permitting a greater percentage of free charge on the charge terminal T₁ providing greater field strength and excitation of the traveling wave.

The wave length can be determined as:

$${β}_{w} = \frac{2 π}{{λ}_{w}} = \frac{2 π}{{V}_{w} {λ}_{0}} = 0.042 {m}^{- 1} . \qquad ( 71 )$$

where c is the speed of light. The complex index of refraction is:

n=\sqrt{εᵣ−jx}=7.529−j6.546, (68)

from Equation (41), where x=σ₁/ωεₒ with ω=2πfₒ, and the complex Brewster angle is:

θ_{i,B}=arc tan(\sqrt{εᵣ−jx})=85.6−j3.744°. (69)

from Equation (42). Using Equation (66), the wave tilt values can be determined to be:

$${λ}_{o} = \frac{c}{{f}_{o}} = 162.162 meters , \qquad ( 67 )$$

Thus, the helical coil can be adjusted to match Φ=Ψ=40.614°

The velocity factor of the vertical feed line conductor (approximated as a uniform cylindrical conductor with a diameter of 0.27 inches) can be given as V_{w}≈0.93. Since hₚ<<λ₀, the propagation phase constant for the vertical feed line conductor can be approximated as:

$$W = \frac{1}{tan {θ}_{i , B}} = \frac{1}{n} = \vert W \vert {e}^{j Ψ} = 0.101 {e}^{j 40.614 °} . \qquad ( 70 )$$

From Equation (49) the phase delay of the vertical feed line conductor is:

θ_{y}=β_{w}h_{w}≈β_{w}hₚ=11.640°. (72)

By adjusting the phase delay of the helical coil so that θ_{c}=28.974°=40.614°−11.640°, Φ will equal Ψ to match the guided surface waveguide mode. To illustrate the relationship between Φ and Ψ, FIG. 11 shows a plot of both over a range of frequencies. As both Φ and Ψ are frequency dependent, it can be seen that their respective curves cross over each other at approximately 1.85 MHz.

For a helical coil having a conductor diameter of 0.0881 inches, a coil diameter (D) of 30 inches and a turn-to-turn spacing (s) of 4 inches, the velocity factor for the coil can be determined using Equation (45) as:

$${V}_{f} = \frac{1}{\sqrt{1 + 20 {( \frac{D}{s} )}^{2.5} {( \frac{D}{{λ}_{0}} )}^{0.5}}} = 0.069 , \qquad ( 73 )$$

and the propagation factor from Equation (35) is:

$${β}_{p} = \frac{2 π}{{V}_{f} {λ}_{0}} = 0.564 {m}^{- 1} . \qquad ( 74 )$$

With θ_{c}=28.974°, the axial length of the solenoidal helix (H) can be determined using Equation (46) such that:

$$H = \frac{{θ}_{c}}{{β}_{p}} = 35.2732 inches . \qquad ( 75 )$$

This height determines the location on the helical coil where the vertical feed line conductor is connected, resulting in a coil with 8.818 turns (N=H/s).

With the traveling wave phase delay of the coil and vertical feed line conductor adjusted to match the wave tilt angle (Φ=θ_{c}+θ_{y}=Ψ), the load impedance (Z_{L}) of the charge terminal T₁ can be adjusted for standing wave resonance of the equivalent image plane model of the guided surface waveguide probe 200. From the measured permittivity, conductivity and permeability of the Earth, the radial propagation constant can be determined using Equation (57)

γₑ=\sqrt{jωu₁(σ₁+jωε₁)}=0.25+j0.292m⁻¹, (76)

and the complex depth of the conducting image ground plane can be approximated from Equation (52) as:

$$d \approx \frac{2}{{γ}_{e}} = 3.364 + j 3.963 meters , \qquad ( 77 )$$

with a corresponding phase shift between the conducting image ground plane and the physical boundary of the Earth given by:

θ_{d}=βₒ(d/2)=4.015−j4.73°. (78)

Using Equation (65), the impedance seen “looking down” into the lossy conducting medium 203 (i.e., Earth) can be determined as:

Zᵢₙ=Zₒ tan h(jθ_{d})=Rᵢₙ+jXᵢₙ=31.191+j26.27 ohms. (79)

By matching the reactive component (Xᵢₙ) seen “looking down” into the lossy conducting medium 203 with the reactive component (X_{base}) seen “looking up” into the guided surface waveguide probe 200, the coupling into the guided surface waveguide mode may be maximized. This can be accomplished by adjusting the capacitance of the charge terminal T₁ without changing the traveling wave phase delays of the coil and vertical feed line conductor. For example, by adjusting the charge terminal capacitance (C_{T}) to 61.8126 pF, the load impedance from Equation (62) is:

$${Z}_{L} = \frac{1}{j ω {C}_{T}} = - j 1392 ohms , \qquad ( 80 )$$

and the reactive components at the boundary are matched.

Using Equation (51), the impedance of the vertical feed line conductor (having a diameter (2a) of 0.27 inches) is given as

$${Z}_{w} = 138 log ( \frac{1.123 {V}_{w} {λ}_{0}}{2 π a} ) = 537.534 ohms , \qquad ( 81 )$$

and the impedance seen “looking up” into the vertical feed line conductor is given by Equation (63) as:

$${Z}_{2} = {Z}_{W} \frac{{Z}_{L} + {Z}_{w} tan h ( j {θ}_{y} )}{{Z}_{w} + {Z}_{L} tan h ( j {θ}_{y} )} = - j 835.438 ohms . \qquad ( 82 )$$

Using Equation (47), the characteristic impedance of the helical coil is given as

$${Z}_{c} = \frac{60}{{V}_{f}} [ 𝓁 n ( \frac{{V}_{f} {λ}_{0}}{D} ) - 1.027 ] = 1446 ohms , \qquad ( 83 )$$

and the impedance seen “looking up” into the coil at the base is given by Equation (64) as:

$${Z}_{base} = {Z}_{c} \frac{{Z}_{2} + {Z}_{c} tan h ( j {θ}_{c} )}{{Z}_{c} + {Z}_{2} tan h ( j {θ}_{c} )} = - j 26.271 ohms . \qquad ( 84 )$$

When compared to the solution of Equation (79), it can be seen that the reactive components are opposite and approximately equal, and thus are conjugates of each other. Thus, the impedance (Zᵢₚ) seen “looking up” into the equivalent image plane model of FIGS. 9A and 9B from the perfectly conducting image ground plane is only resistive or Zᵢₚ=R+j0.

When the electric fields produced by a guided surface waveguide probe 200 (FIG. 3) are established by matching the traveling wave phase delay of the feed network to the wave tilt angle and the probe structure is resonated with respect to the perfectly conducting image ground plane at complex depth z=−d/2, the fields are substantially mode-matched to a guided surface waveguide mode on the surface of the lossy conducting medium, a guided surface traveling wave is launched along the surface of the lossy conducting medium. As illustrated in FIG. 1, the guided field strength curve 103 of the guided electromagnetic field has a characteristic exponential decay of e^{-αd}/\sqrt{d} and exhibits a distinctive knee 109 on the log-log scale.

If the reactive components of the impedance seen “looking up” into the coil and “looking down” into the lossy conducting medium are not opposite and approximately equal, then a lumped element tank circuit 260 (FIG. 7C) can be included between the coil 215 (FIG. 7A) and ground stake 218 (FIG. 7A) (or grounding system). The self-resonant frequency of the lumped element tank circuit can then be adjusted so that the reactive components “looking up” into the tank circuit of the guided surface waveguide probe and “looking down” into the into the lossy conducting medium are opposite and approximately equal. Under that condition, by adjusting the impedance (Zᵢₚ) seen “looking up” into the equivalent image plane model of FIG. 9C from the perfectly conducting image ground plane is only resistive or Zᵢₚ=R+j0.

In summary, both analytically and experimentally, the traveling wave component on the structure of the guided surface waveguide probe 200 has a phase delay (Φ) at its upper terminal that matches the angle (Ψ) of the wave tilt of the surface traveling wave (Φ=Ψ). Under this condition, the surface waveguide may be considered to be “mode-matched”. Furthermore, the resonant standing wave component on the structure of the guided surface waveguide probe 200 has a V_{MAX} at the charge terminal T₁ and a V_{MIN} down at the image plane 139 (FIG. 8B) where Zᵢₚ=Rᵢₚ+j0 at a complex depth of z=−d/2, not at the connection at the physical boundary 136 of the lossy conducting medium 203 (FIG. 8B). Lastly, the charge terminal T₁ is of sufficient height H₁ of FIG. 3 (h≥Rₓ tan ψ_{i,B}) so that electromagnetic waves incident onto the lossy conducting medium 203 at the complex Brewster angle do so out at a distance (≥Rₓ) where the 1/\sqrt{r} term is predominant. Receive circuits can be utilized with one or more guided surface waveguide probes to facilitate wireless transmission and/or power delivery systems.

Referring back to FIG. 3, operation of a guided surface waveguide probe 200 may be controlled to adjust for variations in operational conditions associated with the guided surface waveguide probe 200. For example, an adaptive probe control system 230 can be used to control the feed network 209 and/or the charge terminal T₁ to control the operation of the guided surface waveguide probe 200. Operational conditions can include, but are not limited to, variations in the characteristics of the lossy conducting medium 203 (e.g., conductivity σ and relative permittivity εᵣ), variations in field strength and/or variations in loading of the guided surface waveguide probe 200. As can be seen from Equations (31), (41) and (42), the index of refraction (n), the complex Brewster angle (θ_{i,B}), and the wave tilt (|W|e^{jΨ}) can be affected by changes in soil conductivity and permittivity resulting from, e.g., weather conditions.

Equipment such as, e.g., conductivity measurement probes, permittivity sensors, ground parameter meters, field meters, current monitors and/or load receivers can be used to monitor for changes in the operational conditions and provide information about current operational conditions to the adaptive probe control system 230. The probe control system 230 can then make one or more adjustments to the guided surface waveguide probe 200 to maintain specified operational conditions for the guided surface waveguide probe 200. For instance, as the moisture and temperature vary, the conductivity of the soil will also vary. Conductivity measurement probes and/or permittivity sensors may be located at multiple locations around the guided surface waveguide probe 200. Generally, it would be desirable to monitor the conductivity and/or permittivity at or about the Hankel crossover distance Rₓ for the operational frequency. Conductivity measurement probes and/or permittivity sensors may be located at multiple locations (e.g., in each quadrant) around the guided surface waveguide probe 200.

The conductivity measurement probes and/or permittivity sensors can be configured to evaluate the conductivity and/or permittivity on a periodic basis and communicate the information to the probe control system 230. The information may be communicated to the probe control system 230 through a network such as, but not limited to, a LAN, WLAN, cellular network, or other appropriate wired or wireless communication network. Based upon the monitored conductivity and/or permittivity, the probe control system 230 may evaluate the variation in the index of refraction (n), the complex Brewster angle (θ_{i,B}), and/or the wave tilt (|W|e^{jΨ}) and adjust the guided surface waveguide probe 200 to maintain the phase delay (Φ) of the feed network 209 equal to the wave tilt angle (Ψ) and/or maintain resonance of the equivalent image plane model of the guided surface waveguide probe 200. This can be accomplished by adjusting, e.g., θ_{y}, θ_{c} and/or C_{T}. For instance, the probe control system 230 can adjust the self-capacitance of the charge terminal T₁ and/or the phase delay (θ_{y}, θ_{c}) applied to the charge terminal T₁ to maintain the electrical launching efficiency of the guided surface wave at or near its maximum. For example, the self-capacitance of the charge terminal T₁ can be varied by changing the size of the terminal. The charge distribution can also be improved by increasing the size of the charge terminal T₁, which can reduce the chance of an electrical discharge from the charge terminal T₁. In other embodiments, the charge terminal T₁ can include a variable inductance that can be adjusted to change the load impedance Z_{L}. The phase applied to the charge terminal T₁ can be adjusted by varying the tap position on the coil(s) 215 (FIGS. 7A-7C), and/or by including a plurality of predefined taps along the coil(s) 215 and switching between the different predefined tap locations to maximize the launching efficiency.

Field or field strength (FS) meters may also be distributed about the guided surface waveguide probe 200 to measure field strength of fields associated with the guided surface wave. The field or FS meters can be configured to detect the field strength and/or changes in the field strength (e.g., electric field strength) and communicate that information to the probe control system 230. The information may be communicated to the probe control system 230 through a network such as, but not limited to, a LAN, WLAN, cellular network, or other appropriate communication network. As the load and/or environmental conditions change or vary during operation, the guided surface waveguide probe 200 may be adjusted to maintain specified field strength(s) at the FS meter locations to ensure appropriate power transmission to the receivers and the loads they supply.

For example, the phase delay (Φ=θ_{y}+θ_{c}) applied to the charge terminal T₁ can be adjusted to match the wave tilt angle (Ψ). By adjusting one or both phase delays, the guided surface waveguide probe 200 can be adjusted to ensure the wave tilt corresponds to the complex Brewster angle. This can be accomplished by adjusting a tap position on the coil(s) 215 (FIGS. 7A-7C) to change the phase delay supplied to the charge terminal T₁. The voltage level supplied to the charge terminal T₁ can also be increased or decreased to adjust the electric field strength. This may be accomplished by adjusting the output voltage of the excitation source 212 or by adjusting or reconfiguring the feed network 209. For instance, the position of the tap 227 (FIG. 7A) for the excitation source 212 can be adjusted to increase the voltage seen by the charge terminal T₁, where the excitation source 212 comprises, for example, an AC source as mentioned above. Maintaining field strength levels within predefined ranges can improve coupling by the receivers, reduce ground current losses, and avoid interference with transmissions from other guided surface waveguide probes 200.

The probe control system 230 can be implemented with hardware, firmware, software executed by hardware, or a combination thereof. For example, the probe control system 230 can include processing circuitry including a processor and a memory, both of which can be coupled to a local interface such as, for example, a data bus with an accompanying control/address bus as can be appreciated by those with ordinary skill in the art. A probe control application may be executed by the processor to adjust the operation of the guided surface waveguide probe 200 based upon monitored conditions. The probe control system 230 can also include one or more network interfaces for communicating with the various monitoring devices. Communications can be through a network such as, but not limited to, a LAN, WLAN, cellular network, or other appropriate communication network. The probe control system 230 may comprise, for example, a computer system such as a server, desktop computer, laptop, or other system with like capability.

Referring back to the example of FIG. 5A, the complex angle trigonometry is shown for the ray optic interpretation of the incident electric field (E) of the charge terminal T₁ with a complex Brewster angle (θ_{i,B}) at the Hankel crossover distance (Rₓ). Recall that, for a lossy conducting medium, the Brewster angle is complex and specified by equation (38). Electrically, the geometric parameters are related by the electrical effective height (h_{eff}) of the charge terminal T₁ by Equation (39). Since both the physical height (hₚ) and the Hankel crossover distance (Rₓ) are real quantities, the angle of the desired guided surface wave tilt at the Hankel crossover distance (W_{Rx}) is equal to the phase delay)) of the complex effective height (h_{eff}). With the charge terminal T₁ positioned at the physical height hₚ and excited with a charge having the appropriate phase Φ, the resulting electric field is incident with the lossy conducting medium boundary interface at the Hankel crossover distance Rₓ, and at the Brewster angle. Under these conditions, the guided surface waveguide mode can be excited without reflection or substantially negligible reflection.

However, Equation (39) means that the physical height of the guided surface waveguide probe 200 can be relatively small. While this will excite the guided surface waveguide mode, this can result in an unduly large bound charge with little free charge. To compensate, the charge terminal T₁ can be raised to an appropriate elevation to increase the amount of free charge. As one example rule of thumb, the charge terminal T₁ can be positioned at an elevation of about 4-5 times (or more) the effective diameter of the charge terminal T₁. FIG. 6 illustrates the effect of raising the charge terminal T₁ above the physical height (hₚ) shown in FIG. 5A. The increased elevation causes the distance at which the wave tilt is incident with the lossy conductive medium to move beyond the Hankel crossover point 121 (FIG. 5A). To improve coupling in the guided surface waveguide mode, and thus provide for a greater launching efficiency of the guided surface wave, a lower compensation terminal T₂ can be used to adjust the total effective height (h_{TE}) of the charge terminal T₁ such that the wave tilt at the Hankel crossover distance is at the Brewster angle.

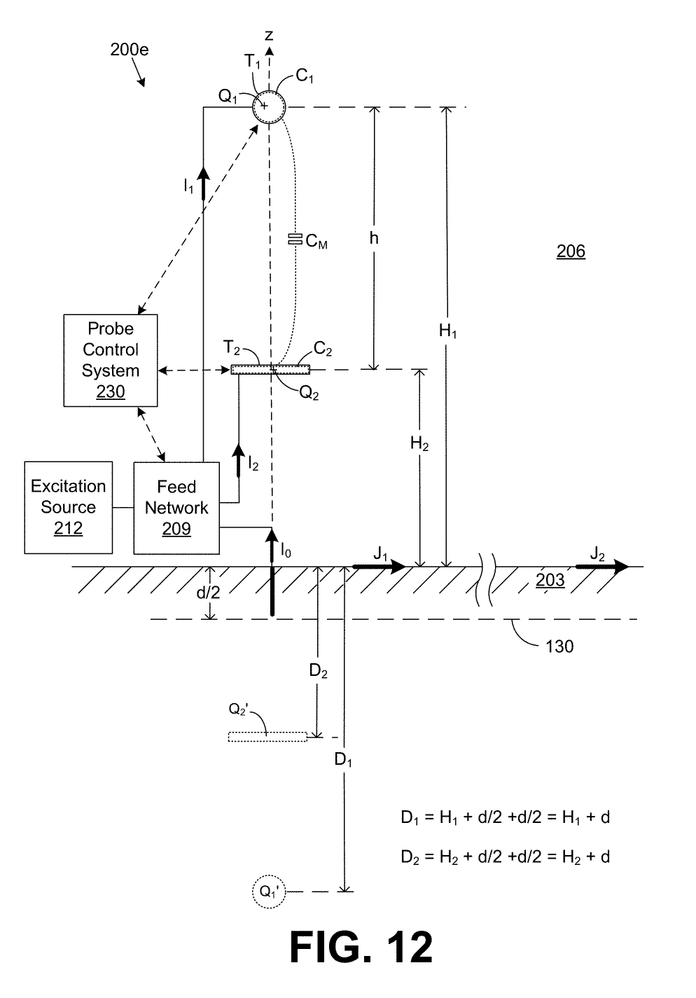

Referring to FIG. 12, shown is an example of a guided surface waveguide probe 200e that includes an elevated charge terminal T₁ and a lower compensation terminal T₂ that are arranged along a vertical axis z that is normal to a plane presented by the lossy conducting medium 203. In this respect, the charge terminal T₁ is placed directly above the compensation terminal T₂ although it is possible that some other arrangement of two or more charge and/or compensation terminals TN can be used. The guided surface waveguide probe 200e is disposed above a lossy conducting medium 203 according to an embodiment of the present disclosure. The lossy conducting medium 203 makes up Region 1 with a second medium 206 that makes up Region 2 sharing a boundary interface with the lossy conducting medium 203.

The guided surface waveguide probe 200e includes a feed network 209 that couples an excitation source 212 to the charge terminal T₁ and the compensation terminal T₂. According to various embodiments, charges Q₁ and Q₂ can be imposed on the respective charge and compensation terminals T₁ and T₂, depending on the voltages applied to terminals T₁ and T₂ at any given instant. I₁ is the conduction current feeding the charge Q₁ on the charge terminal T₁ via the terminal lead, and I₂ is the conduction current feeding the charge Q₂ on the compensation terminal T₂ via the terminal lead.

According to the embodiment of FIG. 12, the charge terminal T₁ is positioned over the lossy conducting medium 203 at a physical height H₁, and the compensation terminal T₂ is positioned directly below T₁ along the vertical axis z at a physical height H₂, where H₂ is less than H₁. The height h of the transmission structure may be calculated as h=H₁−H₂. The charge terminal T₁ has an isolated (or self) capacitance C₁, and the compensation terminal T₂ has an isolated (or self) capacitance C₂. A mutual capacitance CM can also exist between the terminals T₁ and T₂ depending on the distance therebetween. During operation, charges Q₁ and Q₂ are imposed on the charge terminal T₁ and the compensation terminal T₂, respectively, depending on the voltages applied to the charge terminal T₁ and the compensation terminal T₂ at any given instant.

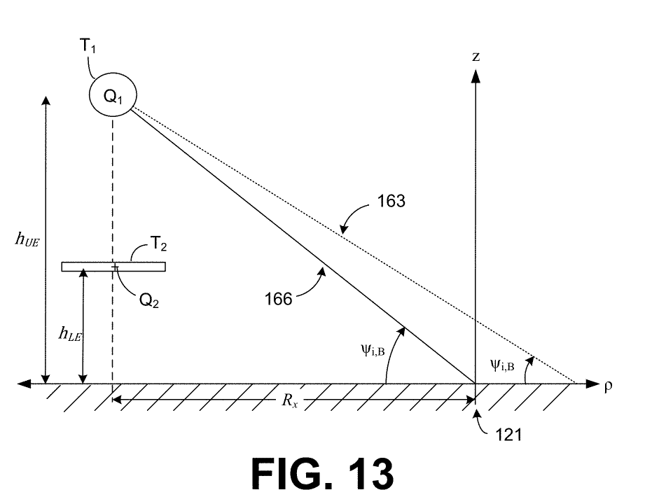

Referring next to FIG. 13, shown is a ray optics interpretation of the effects produced by the elevated charge Q₁ on charge terminal T₁ and compensation terminal T₂ of FIG. 12. With the charge terminal T₁ elevated to a height where the ray intersects with the lossy conductive medium at the Brewster angle at a distance greater than the Hankel crossover point 121 as illustrated by line 163, the compensation terminal T₂ can be used to adjust h_{TE} by compensating for the increased height. The effect of the compensation terminal T₂ is to reduce the electrical effective height of the guided surface waveguide probe (or effectively raise the lossy medium interface) such that the wave tilt at the Hankel crossover distance is at the Brewster angle as illustrated by line 166.

The total effective height can be written as the superposition of an upper effective height (h_{UE}) associated with the charge terminal T₁ and a lower effective height (h_{LE}) associated with the compensation terminal T₂ such that

h_{TE}=h_{HU}+h_{LE}=hₚe^{j(βh}^{ₚ}^{+Φ}^{_{U}}⁾+h_{d}e^{j(βh}^{ₚ}^{+Φ}^{_{U}}⁾=Rₓ×W, (85)

where Φ_{U} is the phase delay applied to the upper charge terminal T₁, Φ_{L} is the phase delay applied to the lower compensation terminal T₂, β=2π/λₚ is the propagation factor from Equation (35), hₚ is the physical height of the charge terminal T₁ and h_{d} is the physical height of the compensation terminal T₂. If extra lead lengths are taken into consideration, they can be accounted for by adding the charge terminal lead length z to the physical height hₚ of the charge terminal T₁ and the compensation terminal lead length y to the physical height h_{d} of the compensation terminal T₂ as shown in

h_{TE}=(hₚ+z)e^{j(β(h}^{ₚ}^{+z)+Φ}^{_{U}}⁾+h_{d}+y)e^{j(β(h}^{_{d}}^{+y)+Φ}^{_{L}}⁾=Rₓ×W, (86)

The lower effective height can be used to adjust the total effective height (h_{TE}) to equal the complex effective height (h_{eff}) of FIG. 5A.

Equations (85) or (86) can be used to determine the physical height of the lower disk of the compensation terminal T₂ and the phase angles to feed the terminals in order to obtain the desired wave tilt at the Hankel crossover distance. For example, Equation (86) can be rewritten as the phase delay applied to the charge terminal T₁ as a function of the compensation terminal height (h_{d}) to give

$${Φ}_{U} ( {h}_{d} ) = - β ( {h}_{p} + z ) - j ln ( \frac{{R}_{x} \times W - ( {h}_{d} + y ) {e}^{j ( β {h}_{d} + β y + {Φ}_{L} )}}{( {h}_{p} + z )} ) . \qquad ( 87 )$$

To determine the positioning of the compensation terminal T₂, the relationships discussed above can be utilized. First, the total effective height (h_{TE}) is the superposition of the complex effective height (h_{UE}) of the upper charge terminal T₁ and the complex effective height (h_{LE}) of the lower compensation terminal T₂ as expressed in Equation (86). Next, the tangent of the angle of incidence can be expressed geometrically as

$$tan {ψ}_{E} = \frac{{h}_{TE}}{{R}_{x}} , \qquad ( 88 )$$

which is equal to the definition of the wave tilt, W. Finally, given the desired Hankel crossover distance Rₓ, the h_{TE} can be adjusted to make the wave tilt of the incident ray match the complex Brewster angle at the Hankel crossover point 121. This can be accomplished by adjusting hₚ, Φ_{U}, and/or h_{d}.

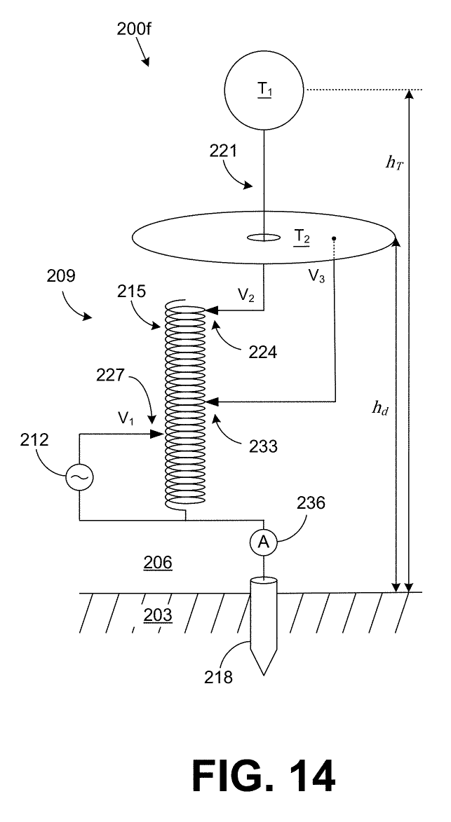

These concepts may be better understood when discussed in the context of an example of a guided surface waveguide probe. Referring to FIG. 14, shown is a graphical representation of an example of a guided surface waveguide probe 200f including an upper charge terminal T₁ (e.g., a sphere at height h_{T}) and a lower compensation terminal T₂ (e.g., a disk at height h_{d}) that are positioned along a vertical axis z that is substantially normal to the plane presented by the lossy conducting medium 203. During operation, charges Q₁ and Q₂ are imposed on the charge and compensation terminals T₁ and T₂, respectively, depending on the voltages applied to the terminals T₁ and T₂ at any given instant.

An AC source can act as the excitation source 212 for the charge terminal T₁, which is coupled to the guided surface waveguide probe 200f through a feed network 209 comprising a phasing coil 215 such as, e.g., a helical coil. The excitation source 212 can be connected across a lower portion of the coil 215 through a tap 227, as shown in FIG. 14, or can be inductively coupled to the coil 215 by way of a primary coil. The coil 215 can be coupled to a ground stake (or grounding system) 218 at a first end and the charge terminal T₁ at a second end. In some implementations, the connection to the charge terminal T₁ can be adjusted using a tap 224 at the second end of the coil 215. The compensation terminal T₂ is positioned above and substantially parallel with the lossy conducting medium 203 (e.g., the ground or Earth), and energized through a tap 233 coupled to the coil 215. An ammeter 236 located between the coil 215 and ground stake (or grounding system) 218 can be used to provide an indication of the magnitude of the current flow (I₀) at the base of the guided surface waveguide probe. Alternatively, a current clamp may be used around the conductor coupled to the ground stake (or grounding system) 218 to obtain an indication of the magnitude of the current flow (Iₒ).

In the example of FIG. 14, the coil 215 is coupled to a ground stake (or grounding system) 218 at a first end and the charge terminal T₁ at a second end via a vertical feed line conductor 221. In some implementations, the connection to the charge terminal T₁ can be adjusted using a tap 224 at the second end of the coil 215 as shown in FIG. 14. The coil 215 can be energized at an operating frequency by the excitation source 212 through a tap 227 at a lower portion of the coil 215. In other implementations, the excitation source 212 can be inductively coupled to the coil 215 through a primary coil. The compensation terminal T₂ is energized through a tap 233 coupled to the coil 215. An ammeter 236 located between the coil 215 and ground stake (or grounding system) 218 can be used to provide an indication of the magnitude of the current flow at the base of the guided surface waveguide probe 200f. Alternatively, a current clamp may be used around the conductor coupled to the ground stake (or grounding system) 218 to obtain an indication of the magnitude of the current flow. The compensation terminal T₂ is positioned above and substantially parallel with the lossy conducting medium 203 (e.g., the ground).

In the example of FIG. 14, the connection to the charge terminal T₁ is located on the coil 215 above the connection point of tap 233 for the compensation terminal T₂. Such an adjustment allows an increased voltage (and thus a higher charge Q₁) to be applied to the upper charge terminal T₁. In other embodiments, the connection points for the charge terminal T₁ and the compensation terminal T₂ can be reversed. It is possible to adjust the total effective height (h_{TE}) of the guided surface waveguide probe 200f to excite an electric field having a guided surface wave tilt at the Hankel crossover distance Rₓ. The Hankel crossover distance can also be found by equating the magnitudes of equations (20b) and (21) for −jγρ, and solving for Rₓ as illustrated by FIG. 4. The index of refraction (n), the complex Brewster angle (θ_{i,B} and ψ_{i,B}), the wave tilt (|W|e^{jΨ}) and the complex effective height (h_{eff}=hₚe^{jΦ}) can be determined as described with respect to Equations (41)-(44) above.

With the selected charge terminal T₁ configuration, a spherical diameter (or the effective spherical diameter) can be determined. For example, if the charge terminal T₁ is not configured as a sphere, then the terminal configuration may be modeled as a spherical capacitance having an effective spherical diameter. The size of the charge terminal T₁ can be chosen to provide a sufficiently large surface for the charge Q₁ imposed on the terminals. In general, it is desirable to make the charge terminal T₁ as large as practical. The size of the charge terminal T₁ should be large enough to avoid ionization of the surrounding air, which can result in electrical discharge or sparking around the charge terminal. To reduce the amount of bound charge on the charge terminal T₁, the desired elevation to provide free charge on the charge terminal T₁ for launching a guided surface wave should be at least 4-5 times the effective spherical diameter above the lossy conductive medium (e.g., the Earth). The compensation terminal T₂ can be used to adjust the total effective height (h_{TE}) of the guided surface waveguide probe 200f to excite an electric field having a guided surface wave tilt at Rₓ. The compensation terminal T₂ can be positioned below the charge terminal T₁ at h_{d}=h_{T}−hₚ, where h_{T} is the total physical height of the charge terminal T₁. With the position of the compensation terminal T₂ fixed and the phase delay Φ_{U} applied to the upper charge terminal T₁, the phase delay Φ_{L} applied to the lower compensation terminal T₂ can be determined using the relationships of Equation (86), such that:

$${Φ}_{U} ( {h}_{d} ) = - β ( {h}_{d} + y ) - j ln ( \frac{{R}_{x} \times W - ( {h}_{d} + z ) {e}^{j ( β {h}_{p} + β z + {Φ}_{L} )}}{( {h}_{d} + y )} ) . \qquad ( 89 )$$

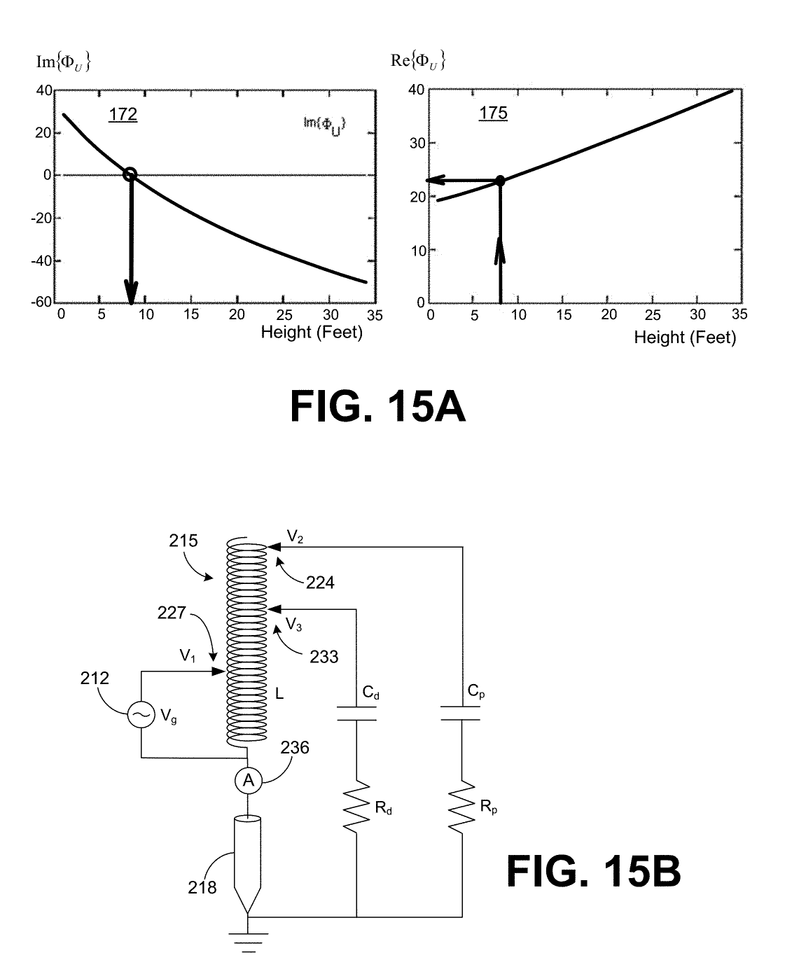

In alternative embodiments, the compensation terminal T₂ can be positioned at a height h_{d} where Im{Φ_{L}}=0. This is graphically illustrated in FIG. 15A, which shows plots 172 and 175 of the imaginary and real parts of Φ_{U}, respectively. The compensation terminal T₂ is positioned at a height h_{d} where Im{Φ_{U}}=0, as graphically illustrated in plot 172. At this fixed height, the coil phase Φ_{U} can be determined from Re{Φ_{U}}, as graphically illustrated in plot 175.

With the excitation source 212 coupled to the coil 215 (e.g., at the 50Ω point to maximize coupling), the position of tap 233 may be adjusted for parallel resonance of the compensation terminal T₂ with at least a portion of the coil at the frequency of operation. FIG. 15B shows a schematic diagram of the general electrical hookup of FIG. 14 in which V₁ is the voltage applied to the lower portion of the coil 215 from the excitation source 212 through tap 227, V₂ is the voltage at tap 224 that is supplied to the upper charge terminal T₁, and V₃ is the voltage applied to the lower compensation terminal T₂ through tap 233. The resistances Rₚ and R_{d} represent the ground return resistances of the charge terminal T₁ and compensation terminal T₂, respectively. The charge and compensation terminals T₁ and T₂ may be configured as spheres, cylinders, toroids, rings, hoods, or any other combination of capacitive structures. The size of the charge and compensation terminals T₁ and T₂ can be chosen to provide a sufficiently large surface for the charges Q₁ and Q₂ imposed on the terminals. In general, it is desirable to make the charge terminal T₁ as large as practical. The size of the charge terminal T₁ should be large enough to avoid ionization of the surrounding air, which can result in electrical discharge or sparking around the charge terminal. The self-capacitance Cₚ and C_{d} of the charge and compensation terminals T₁ and T₂ respectively, can be determined using, for example, Equation (24).

As can be seen in FIG. 15B, a resonant circuit is formed by at least a portion of the inductance of the coil 215, the self-capacitance C_{d} of the compensation terminal T₂, and the ground return resistance R_{d} associated with the compensation terminal T₂. The parallel resonance can be established by adjusting the voltage V₃ applied to the compensation terminal T₂ (e.g., by adjusting a tap 233 position on the coil 215) or by adjusting the height and/or size of the compensation terminal T₂ to adjust C_{d}. The position of the coil tap 233 can be adjusted for parallel resonance, which will result in the ground current through the ground stake (or grounding system) 218 and through the ammeter 236 reaching a maximum point. After parallel resonance of the compensation terminal T₂ has been established, the position of the tap 227 for the excitation source 212 can be adjusted to the 50Ω point on the coil 215.

Voltage V₂ from the coil 215 can be applied to the charge terminal T₁, and the position of tap 224 can be adjusted such that the phase delay (Φ) of the total effective height (h_{TE}) approximately equals the angle of the guided surface wave tilt (W_{Rx}) at the Hankel crossover distance (Rₓ). The position of the coil tap 224 can be adjusted until this operating point is reached, which results in the ground current through the ammeter 236 increasing to a maximum. At this point, the resultant fields excited by the guided surface waveguide probe 200f are substantially mode-matched to a guided surface waveguide mode on the surface of the lossy conducting medium 203, resulting in the launching of a guided surface wave along the surface of the lossy conducting medium 203. This can be verified by measuring field strength along a radial extending from the guided surface waveguide probe 200.

Resonance of the circuit including the compensation terminal T₂ may change with the attachment of the charge terminal T₁ and/or with adjustment of the voltage applied to the charge terminal T₁ through tap 224. While adjusting the compensation terminal circuit for resonance aids the subsequent adjustment of the charge terminal connection, it is not necessary to establish the guided surface wave tilt (W_{Rx}) at the Hankel crossover distance (Rₓ). The system may be further adjusted to improve coupling by iteratively adjusting the position of the tap 227 for the excitation source 212 to be at the 50Ω point on the coil 215 and adjusting the position of tap 233 to maximize the ground current through the ammeter 236. Resonance of the circuit including the compensation terminal T₂ may drift as the positions of taps 227 and 233 are adjusted, or when other components are attached to the coil 215.

In other implementations, the voltage V₂ from the coil 215 can be applied to the charge terminal T₁, and the position of tap 233 can be adjusted such that the phase delay)) of the total effective height (h_{TE}) approximately equals the angle (W) of the guided surface wave tilt at Rₓ. The position of the coil tap 224 can be adjusted until the operating point is reached, resulting in the ground current through the ammeter 236 substantially reaching a maximum. The resultant fields are substantially mode-matched to a guided surface waveguide mode on the surface of the lossy conducting medium 203, and a guided surface wave is launched along the surface of the lossy conducting medium 203. This can be verified by measuring field strength along a radial extending from the guided surface waveguide probe 200. The system may be further adjusted to improve coupling by iteratively adjusting the position of the tap 227 for the excitation source 212 to be at the 50Ω point on the coil 215 and adjusting the position of tap 224 and/or 233 to maximize the ground current through the ammeter 236.

Referring back to FIG. 12, operation of a guided surface waveguide probe 200 may be controlled to adjust for variations in operational conditions associated with the guided surface waveguide probe 200. For example, a probe control system 230 can be used to control the feed network 209 and/or positioning of the charge terminal T₁ and/or compensation terminal T₂ to control the operation of the guided surface waveguide probe 200. Operational conditions can include, but are not limited to, variations in the characteristics of the lossy conducting medium 203 (e.g., conductivity σ and relative permittivity εᵣ), variations in field strength and/or variations in loading of the guided surface waveguide probe 200. As can be seen from Equations (41)-(44), the index of refraction (n), the complex Brewster angle (θ_{i,B} and ψ_{i,B}), the wave tilt (|W|e^{jΨ}) and the complex effective height (h_{eff}=hₚe^{jΦ}) can be affected by changes in soil conductivity and permittivity resulting from, e.g., weather conditions.

Equipment such as, e.g., conductivity measurement probes, permittivity sensors, ground parameter meters, field meters, current monitors and/or load receivers can be used to monitor for changes in the operational conditions and provide information about current operational conditions to the probe control system 230. The probe control system 230 can then make one or more adjustments to the guided surface waveguide probe 200 to maintain specified operational conditions for the guided surface waveguide probe 200. For instance, as the moisture and temperature vary, the conductivity of the soil will also vary. Conductivity measurement probes and/or permittivity sensors may be located at multiple locations around the guided surface waveguide probe 200. Generally, it would be desirable to monitor the conductivity and/or permittivity at or about the Hankel crossover distance Rₓ for the operational frequency. Conductivity measurement probes and/or permittivity sensors may be located at multiple locations (e.g., in each quadrant) around the guided surface waveguide probe 200.

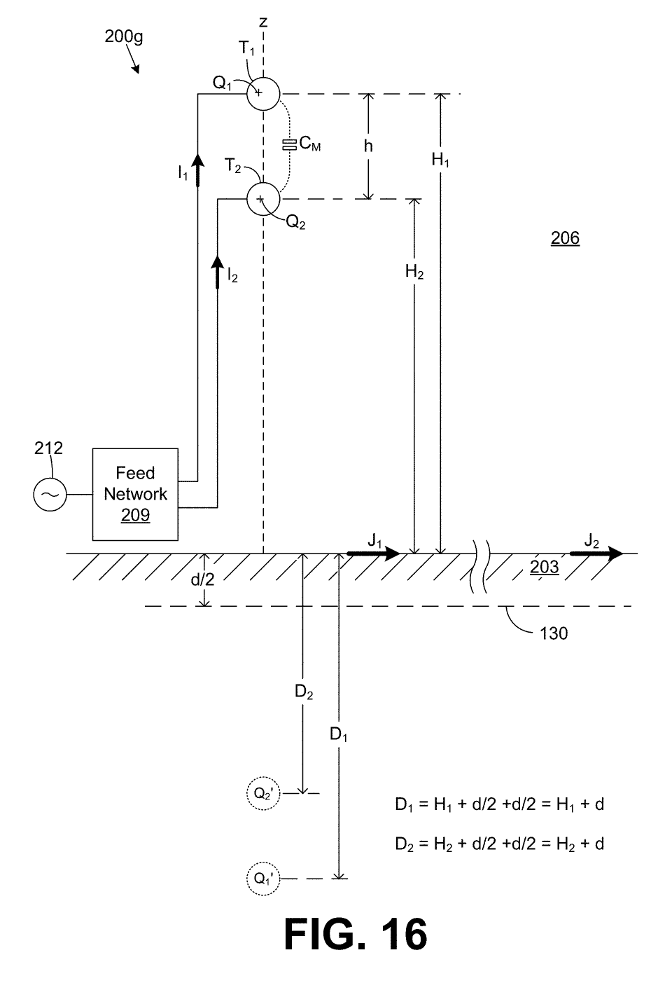

With reference then to FIG. 16, shown is an example of a guided surface waveguide probe 200g that includes a charge terminal T₁ and a charge terminal T₂ that are arranged along a vertical axis z. The guided surface waveguide probe 200g is disposed above a lossy conducting medium 203, which makes up Region 1. In addition, a second medium 206 shares a boundary interface with the lossy conducting medium 203 and makes up Region 2. The charge terminals T₁ and T₂ are positioned over the lossy conducting medium 203. The charge terminal T₁ is positioned at height H₁, and the charge terminal T₂ is positioned directly below T₁ along the vertical axis z at height H₂, where H₂ is less than H₁. The height h of the transmission structure presented by the guided surface waveguide probe 200g is h=H₁−H₂. The guided surface waveguide probe 200g includes a feed network 209 that couples an excitation source 212 such as an AC source, for example, to the charge terminals T₁ and T₂.

The charge terminals T₁ and/or T₂ include a conductive mass that can hold an electrical charge, which may be sized to hold as much charge as practically possible. The charge terminal T₁ has a self-capacitance C₁, and the charge terminal T₂ has a self-capacitance C₂, which can be determined using, for example, Equation (24). By virtue of the placement of the charge terminal T₁ directly above the charge terminal T₂, a mutual capacitance CM is created between the charge terminals T₁ and T₂. Note that the charge terminals T₁ and T₂ need not be identical, but each can have a separate size and shape, and can include different conducting materials. Ultimately, the field strength of a guided surface wave launched by a guided surface waveguide probe 200g is directly proportional to the quantity of charge on the terminal T₁. The charge Q₁ is, in turn, proportional to the self-capacitance C₁ associated with the charge terminal T₁ since Q₁=C₁V, where V is the voltage imposed on the charge terminal T₁.

When properly adjusted to operate at a predefined operating frequency, the guided surface waveguide probe 200g generates a guided surface wave along the surface of the lossy conducting medium 203. The excitation source 212 can generate electrical energy at the predefined frequency that is applied to the guided surface waveguide probe 200g to excite the structure. When the electromagnetic fields generated by the guided surface waveguide probe 200g are substantially mode-matched with the lossy conducting medium 203, the electromagnetic fields substantially synthesize a wave front incident at a complex Brewster angle that results in little or no reflection. Thus, the surface waveguide probe 200g does not produce a radiated wave, but launches a guided surface traveling wave along the surface of a lossy conducting medium 203. The energy from the excitation source 212 can be transmitted as Zenneck surface currents to one or more receivers that are located within an effective transmission range of the guided surface waveguide probe 200g.

One can determine asymptotes of the radial Zenneck surface current Jₚ(ρ) on the surface of the lossy conducting medium 203 to be J₁(ρ) close-in and J₂(ρ) far-out, where

$$\begin{matrix}Close \text{-} in ( ρ < λ \text{/} 8 ) \text{:} {J}_{ρ} ( ρ ) ∼ {J}_{1} = \frac{{I}_{1} + {I}_{2}}{2 π ρ} + \frac{{E}_{ρ}^{QS} ( {Q}_{1} ) + {E}_{ρ}^{QS} ( {Q}_{2} )}{{Z}_{ρ}} , and & ( 90 ) \\ Far \text{-} out ( ρ ≫ λ \text{/} 8 ) \text{:} {J}_{ρ} ( ρ ) ∼ {J}_{2} = \frac{j γ ω {Q}_{1}}{4} \times \sqrt{\frac{2 γ}{π}} \times \frac{{e}^{- ( α + j β ) ρ}}{\sqrt{ρ}} . & ( 91 )\end{matrix}$$

where I₁ is the conduction current feeding the charge Q₁ on the first charge terminal T₁ and I₂ is the conduction current feeding the charge Q₂ on the second charge terminal T₂. The charge Q₁ on the upper charge terminal T₁ is determined by Q₁=C₁V₁, where C₁ is the isolated capacitance of the charge terminal T₁. Note that there is a third component to J₁ set forth above given by (Eₚ^{Q}^{₁})/Z_{ρ}, which follows from the Leontovich boundary condition and is the radial current contribution in the lossy conducting medium 203 pumped by the quasi-static field of the elevated oscillating charge on the first charge terminal Q₁. The quantity Z_{ρ}=jωμₒ/γₑ is the radial impedance of the lossy conducting medium, where γₑ=(jωμ₁σ₁−ω²μ₁ε₁)^{1/2}.

The asymptotes representing the radial current close-in and far-out as set forth by equations (90) and (91) are complex quantities. According to various embodiments, a physical surface current J(ρ) is synthesized to match as close as possible the current asymptotes in magnitude and phase. That is to say close-in, |J(ρ)| is to be tangent to |J₁|, and far-out |J(ρ)| is to be tangent to |J₂|. Also, according to the various embodiments, the phase of J(ρ) should transition from the phase of J₁ close-in to the phase of J₂ far-out.

In order to match the guided surface wave mode at the site of transmission to launch a guided surface wave, the phase of the surface current |J₂| far-out should differ from the phase of the surface current |J₁| close-in by the propagation phase corresponding to e^{-jβ(ρ}^{₂}^{-ρ}^{₁}⁾ plus a constant of approximately 45 degrees or 225 degrees. This is because there are two roots for \sqrt{γ}, one near π/4 and one near 5π/4. The properly adjusted synthetic radial surface current is

$${J}_{ρ} ( ρ , φ , 0 ) = \frac{{I}_{0} γ}{4} {H}_{1}^{( 2 )} ( - j γ ρ ) . \qquad ( 92 )$$

Note that this is consistent with equation (17). By Maxwell's equations, such a J(ρ) surface current automatically creates fields that conform to

$$\begin{matrix}{H}_{φ} = \frac{- γ {I}_{0}}{4} {e}^{- {u}_{2} z} {H}_{1}^{( 2 )} ( - j γ ρ ) , & ( 93 ) \\ {E}_{ρ} = \frac{- γ {I}_{0}}{4} ( \frac{{u}_{2}}{j ω {ɛ}_{o}} ) {e}^{- {u}_{2} z} {H}_{1}^{( 2 )} ( - j γ ρ ) , and & ( 94 ) \\ {E}_{z} = \frac{- γ {I}_{0}}{4} ( \frac{- γ}{ω {ɛ}_{o}} ) {e}^{- {u}_{2} z} {H}_{0}^{( 2 )} ( - j γ ρ ) . & ( 95 )\end{matrix}$$

Thus, the difference in phase between the surface current |J₂| far-out and the surface current |J₁| close-in for the guided surface wave mode that is to be matched is due to the characteristics of the Hankel functions in equations (93)-(95), which are consistent with equations (1)-(3). It is of significance to recognize that the fields expressed by equations (1)-(6) and (17) and equations (92)-(95) have the nature of a transmission line mode bound to a lossy interface, not radiation fields that are associated with groundwave propagation.

In order to obtain the appropriate voltage magnitudes and phases for a given design of a guided surface waveguide probe 200g at a given location, an iterative approach may be used. Specifically, analysis may be performed of a given excitation and configuration of a guided surface waveguide probe 200g taking into account the feed currents to the terminals T₁ and T₂, the charges on the charge terminals T₁ and T₂, and their images in the lossy conducting medium 203 in order to determine the radial surface current density generated. This process may be performed iteratively until an optimal configuration and excitation for a given guided surface waveguide probe 200g is determined based on desired parameters. To aid in determining whether a given guided surface waveguide probe 200g is operating at an optimal level, a guided field strength curve 103 (FIG. 1) may be generated using equations (1)-(12) based on values for the conductivity of Region 1 (σ₁) and the permittivity of Region 1 (ε₁) at the location of the guided surface waveguide probe 200g. Such a guided field strength curve 103 can provide a benchmark for operation such that measured field strengths can be compared with the magnitudes indicated by the guided field strength curve 103 to determine if optimal transmission has been achieved.

In order to arrive at an optimized condition, various parameters associated with the guided surface waveguide probe 200g may be adjusted. One parameter that may be varied to adjust the guided surface waveguide probe 200g is the height of one or both of the charge terminals T₁ and/or T₂ relative to the surface of the lossy conducting medium 203. In addition, the distance or spacing between the charge terminals T₁ and T₂ may also be adjusted. In doing so, one may minimize or otherwise alter the mutual capacitance CM or any bound capacitances between the charge terminals T₁ and T₂ and the lossy conducting medium 203 as can be appreciated. The size of the respective charge terminals T₁ and/or T₂ can also be adjusted. By changing the size of the charge terminals T₁ and/or T₂, one will alter the respective self-capacitances C₁ and/or C₂, and the mutual capacitance CM as can be appreciated.

Still further, another parameter that can be adjusted is the feed network 209 associated with the guided surface waveguide probe 200g. This may be accomplished by adjusting the size of the inductive and/or capacitive reactances that make up the feed network 209. For example, where such inductive reactances comprise coils, the number of turns on such coils may be adjusted. Ultimately, the adjustments to the feed network 209 can be made to alter the electrical length of the feed network 209, thereby affecting the voltage magnitudes and phases on the charge terminals T₁ and T₂.

Note that the iterations of transmission performed by making the various adjustments may be implemented by using computer models or by adjusting physical structures as can be appreciated. By making the above adjustments, one can create corresponding “close-in” surface current J₁ and “far-out” surface current J₂ that approximate the same currents J(ρ) of the guided surface wave mode specified in Equations (90) and (91) set forth above. In doing so, the resulting electromagnetic fields would be substantially or approximately mode-matched to a guided surface wave mode on the surface of the lossy conducting medium 203.

While not shown in the example of FIG. 16, operation of the guided surface waveguide probe 200g may be controlled to adjust for variations in operational conditions associated with the guided surface waveguide probe 200. For example, a probe control system 230 shown in FIG. 12 can be used to control the feed network 209 and/or positioning and/or size of the charge terminals T₁ and/or T₂ to control the operation of the guided surface waveguide probe 200g. Operational conditions can include, but are not limited to, variations in the characteristics of the lossy conducting medium 203 (e.g., conductivity σ and relative permittivity εᵣ), variations in field strength and/or variations in loading of the guided surface waveguide probe 200g.

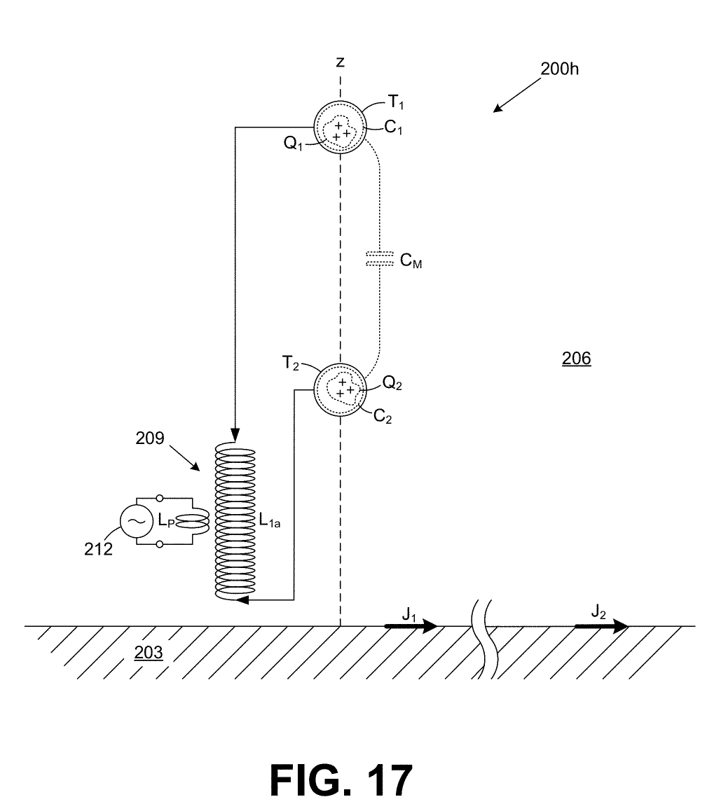

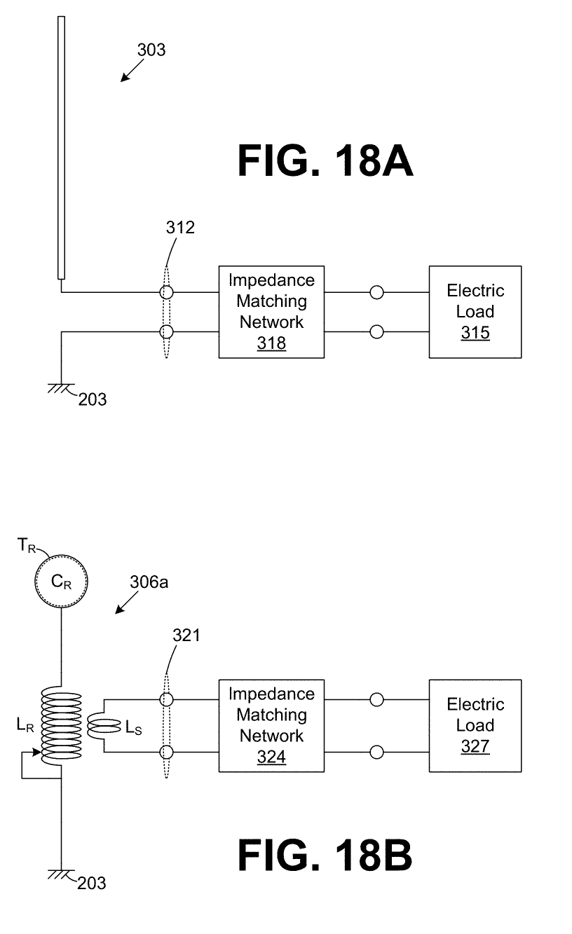

Referring now to FIG. 17, shown is an example of the guided surface waveguide probe 200g of FIG. 16, denoted herein as guided surface waveguide probe 200h. The guided surface waveguide probe 200h includes the charge terminals T₁ and T₂ that are positioned along a vertical axis z that is substantially normal to the plane presented by the lossy conducting medium 203 (e.g., the Earth). The second medium 206 is above the lossy conducting medium 203. The charge terminal T₁ has a self-capacitance C₁, and the charge terminal T₂ has a self-capacitance C₂. During operation, charges Q₁ and Q₂ are imposed on the charge terminals T₁ and T₂, respectively, depending on the voltages applied to the charge terminals T₁ and T₂ at any given instant. A mutual capacitance CM may exist between the charge terminals T₁ and T₂ depending on the distance therebetween. In addition, bound capacitances may exist between the respective charge terminals T₁ and T₂ and the lossy conducting medium 203 depending on the heights of the respective charge terminals T₁ and T₂ with respect to the lossy conducting medium 203.

The guided surface waveguide probe 200h includes a feed network 209 that comprises an inductive impedance comprising a coil L₁ₐ having a pair of leads that are coupled to respective ones of the charge terminals T₁ and T₂. In one embodiment, the coil L₁ₐ is specified to have an electrical length that is one-half (½) of the wavelength at the operating frequency of the guided surface waveguide probe 200h.

While the electrical length of the coil L₁ₐ is specified as approximately one-half (½) the wavelength at the operating frequency, it is understood that the coil L₁ₐ may be specified with an electrical length at other values. According to one embodiment, the fact that the coil L₁ₐ has an electrical length of approximately one-half (½) the wavelength at the operating frequency provides for an advantage in that a maximum voltage differential is created on the charge terminals T₁ and T₂. Nonetheless, the length or diameter of the coil L₁ₐ may be increased or decreased when adjusting the guided surface waveguide probe 200h to obtain optimal excitation of a guided surface wave mode. Adjustment of the coil length may be provided by taps located at one or both ends of the coil. In other embodiments, it may be the case that the inductive impedance is specified to have an electrical length that is significantly less than or greater than one-half (½) the wavelength at the operating frequency of the guided surface waveguide probe 200h.

The excitation source 212 can be coupled to the feed network 209 by way of magnetic coupling. Specifically, the excitation source 212 is coupled to a coil L_{P} that is inductively coupled to the coil L₁ₐ. This may be done by link coupling, a tapped coil, a variable reactance, or other coupling approach as can be appreciated. To this end, the coil L_{P} acts as a primary, and the coil L₁ₐ acts as a secondary as can be appreciated.

In order to adjust the guided surface waveguide probe 200h for the transmission of a desired guided surface wave, the heights of the respective charge terminals T₁ and T₂ may be altered with respect to the lossy conducting medium 203 and with respect to each other. Also, the sizes of the charge terminals T₁ and T₂ may be altered. In addition, the size of the coil L₁ₐ may be altered by adding or eliminating turns or by changing some other dimension of the coil L₁ₐ. The coil L₁ₐ can also include one or more taps for adjusting the electrical length as shown in FIG. 17. The position of a tap connected to either charge terminal T₁ or T₂ can also be adjusted.

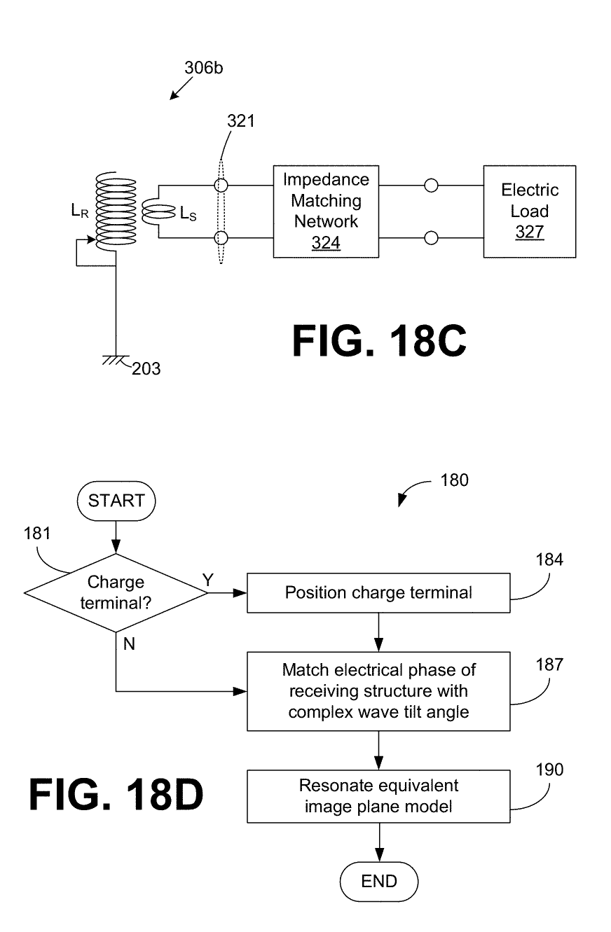

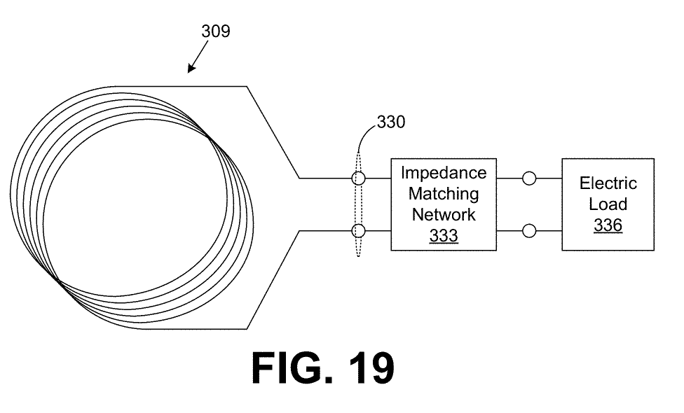

Referring next to FIGS. 18A, 18B, 18C and 19, shown are examples of generalized receive circuits for using the surface-guided waves in wireless power delivery systems. FIG. 18A depict a linear probe 303, and FIGS. 18B and 18C depict tuned resonators 306a and 306b, respectively. FIG. 19 is a magnetic coil 309 according to various embodiments of the present disclosure. According to various embodiments, each one of the linear probe 303, the tuned resonators 306a/b, and the magnetic coil 309 may be employed to receive power transmitted in the form of a guided surface wave on the surface of a lossy conducting medium 203 according to various embodiments. As mentioned above, in one embodiment the lossy conducting medium 203 comprises a terrestrial medium (or Earth).

With specific reference to FIG. 18A, the open-circuit terminal voltage at the output terminals 312 of the linear probe 303 depends upon the effective height of the linear probe 303. To this end, the terminal point voltage may be calculated as

V_{T}=∫₀^{h}^{ₑ}E_{inc}·dl, (96)

where E_{inc} is the strength of the incident electric field induced on the linear probe 303 in Volts per meter, dl is an element of integration along the direction of the linear probe 303, and hₑ is the effective height of the linear probe 303. An electrical load 315 is coupled to the output terminals 312 through an impedance matching network 318.

When the linear probe 303 is subjected to a guided surface wave as described above, a voltage is developed across the output terminals 312 that may be applied to the electrical load 315 through a conjugate impedance matching network 318 as the case may be. In order to facilitate the flow of power to the electrical load 315, the electrical load 315 should be substantially impedance matched to the linear probe 303 as will be described below.

Referring to FIG. 18B, a ground current excited coil L_{R} possessing a phase delay equal to the wave tilt of the guided surface wave includes a charge terminal T_{R} that is elevated (or suspended) above the lossy conducting medium 203. The charge terminal T_{R} has a self-capacitance C_{R}. In addition, there may also be a bound capacitance (not shown) between the charge terminal T_{R} and the lossy conducting medium 203 depending on the height of the charge terminal T_{R} above the lossy conducting medium 203. The bound capacitance should preferably be minimized as much as is practicable, although this may not be entirely necessary in every instance.

The tuned resonator 306a also includes a receiver network comprising a coil L_{R} having a phase delay Φ. One end of the coil L_{R} is coupled to the charge terminal T_{R}, and the other end of the coil L_{R} is coupled to the lossy conducting medium 203. The receiver network can include a vertical supply line conductor that couples the coil L_{R} to the charge terminal T_{R}. To this end, the coil L_{R} (which may also be referred to as tuned resonator L_{R}-C_{R}) comprises a series-adjusted resonator as the charge terminal C_{R} and the coil L_{R} are situated in series. The phase delay of the coil L_{R} can be adjusted by changing the size and/or height of the charge terminal T_{R}, and/or adjusting the size of the coil L_{R} so that the phase delay Φ of the structure is made substantially equal to the angle of the wave tilt Ψ. The phase delay of the vertical supply line can also be adjusted by, e.g., changing length of the conductor.

For example, the reactance presented by the self-capacitance C_{R} is calculated as 1/jωC_{R}. Note that the total capacitance of the tuned resonator 306a may also include capacitance between the charge terminal T_{R} and the lossy conducting medium 203, where the total capacitance of the tuned resonator 306a may be calculated from both the self-capacitance C_{R} and any bound capacitance as can be appreciated. According to one embodiment, the charge terminal T_{R} may be raised to a height so as to substantially reduce or eliminate any bound capacitance. The existence of a bound capacitance may be determined from capacitance measurements between the charge terminal T_{R} and the lossy conducting medium 203 as previously discussed.

The inductive reactance presented by a discrete-element coil L_{R} may be calculated as jωL, where L is the lumped-element inductance of the coil L_{R}. If the coil L_{R} is a distributed element, its equivalent terminal-point inductive reactance may be determined by conventional approaches. To tune the tuned resonator 306a, one would make adjustments so that the phase delay is equal to the wave tilt for the purpose of mode-matching to the surface waveguide at the frequency of operation. Under this condition, the receiving structure may be considered to be “mode-matched” with the surface waveguide. A transformer link around the structure and/or an impedance matching network 324 may be inserted between the probe and the electrical load 327 in order to couple power to the load. Inserting the impedance matching network 324 between the probe terminals 321 and the electrical load 327 can effect a conjugate-match condition for maximum power transfer to the electrical load 327.

When placed in the presence of surface currents at the operating frequencies power will be delivered from the surface guided wave to the electrical load 327. To this end, an electrical load 327 may be coupled to the tuned resonator 306a by way of magnetic coupling, capacitive coupling, or conductive (direct tap) coupling. The elements of the coupling network may be lumped components or distributed elements as can be appreciated.

In the embodiment shown in FIG. 18B, magnetic coupling is employed where a coil Ls is positioned as a secondary relative to the coil L_{R} that acts as a transformer primary. The coil Ls may be link-coupled to the coil L_{R} by geometrically winding it around the same core structure and adjusting the coupled magnetic flux as can be appreciated. In addition, while the tuned resonator 306a comprises a series-tuned resonator, a parallel-tuned resonator or even a distributed-element resonator of the appropriate phase delay may also be used.

While a receiving structure immersed in an electromagnetic field may couple energy from the field, it can be appreciated that polarization-matched structures work best by maximizing the coupling, and conventional rules for probe-coupling to waveguide modes should be observed. For example, a TE₂₀ (transverse electric mode) waveguide probe may be optimal for extracting energy from a conventional waveguide excited in the TE₂₀ mode. Similarly, in these cases, a mode-matched and phase-matched receiving structure can be optimized for coupling power from a surface-guided wave. The guided surface wave excited by a guided surface waveguide probe 200 on the surface of the lossy conducting medium 203 can be considered a waveguide mode of an open waveguide. Excluding waveguide losses, the source energy can be completely recovered. Useful receiving structures may be E-field coupled, H-field coupled, or surface-current excited.

The receiving structure can be adjusted to increase or maximize coupling with the guided surface wave based upon the local characteristics of the lossy conducting medium 203 in the vicinity of the receiving structure. To accomplish this, the phase delay (Φ) of the receiving structure can be adjusted to match the angle (Ψ) of the wave tilt of the surface traveling wave at the receiving structure. If configured appropriately, the receiving structure may then be tuned for resonance with respect to the perfectly conducting image ground plane at complex depth z=−d/2.

For example, consider a receiving structure comprising the tuned resonator 306a of FIG. 18B, including a coil L_{R} and a vertical supply line connected between the coil L_{R} and a charge terminal T_{R}. With the charge terminal T_{R} positioned at a defined height above the lossy conducting medium 203, the total phase delay Φ of the coil L_{R} and vertical supply line can be matched with the angle (Ψ) of the wave tilt at the location of the tuned resonator 306a. From Equation (22), it can be seen that the wave tilt asymptotically passes to

$$W = \vert W \vert {e}^{j Ψ} = \frac{{E}_{ρ}}{{E}_{z}} {\to }_{ρ \to ∞} \frac{1}{\sqrt{{ɛ}_{r} - j \frac{{σ}_{1}}{ω {ɛ}_{o}}}} , \qquad ( 97 )$$

where εᵣ comprises the relative permittivity and σ₁ is the conductivity of the lossy conducting medium 203 at the location of the receiving structure, εₒ is the permittivity of free space, and ω=2πf, where f is the frequency of excitation. Thus, the wave tilt angle (Ψ) can be determined from Equation (97).

The total phase delay (Φ=θ_{c}+θ_{y}) of the tuned resonator 306a includes both the phase delay (θ_{c}) through the coil L_{R} and the phase delay of the vertical supply line (θ_{y}). The spatial phase delay along the conductor length l_{w} of the vertical supply line can be given by θ_{y}=β_{w}l_{w}, where β_{w} is the propagation phase constant for the vertical supply line conductor. The phase delay due to the coil (or helical delay line) is θ_{c}=βₚl_{c}, with a physical length of l_{C} and a propagation factor of

$${β}_{p} = \frac{2 π}{{λ}_{p}} = \frac{2 π}{{V}_{f} {λ}_{0}} , \qquad ( 98 )$$

where V_{f} is the velocity factor on the structure, λ₀ is the wavelength at the supplied frequency, and λₚ is the propagation wavelength resulting from the velocity factor V_{f}. One or both of the phase delays (θ_{c}+θ_{y}) can be adjusted to match the phase delay Φ to the angle (Ψ) of the wave tilt. For example, a tap position may be adjusted on the coil L_{R} of FIG. 18B to adjust the coil phase delay (θ_{c}) to match the total phase delay to the wave tilt angle (Φ=Ψ). For example, a portion of the coil can be bypassed by the tap connection as illustrated in FIG. 18B. The vertical supply line conductor can also be connected to the coil L_{R} via a tap, whose position on the coil may be adjusted to match the total phase delay to the angle of the wave tilt.

Once the phase delay (Φ) of the tuned resonator 306a has been adjusted, the impedance of the charge terminal T_{R} can then be adjusted to tune to resonance with respect to the perfectly conducting image ground plane at complex depth z=−d/2. This can be accomplished by adjusting the capacitance of the charge terminal T₁ without changing the traveling wave phase delays of the coil L_{R} and vertical supply line. In some embodiments, a lumped element tuning circuit can be included between the lossy conducting medium 203 and the coil L_{R} to allow for resonant tuning of the tuned resonator 306a with respect to the complex image plane as discussed above with respect to the guided surface waveguide probe 200. The adjustments are similar to those described with respect to FIGS. 9A-9C.

The impedance seen “looking down” into the lossy conducting medium 203 to the complex image plane is given by:

Zᵢₙ=Rᵢₙ+jXᵢₙ=Zₒ tan h(jβₒ(d/2)), (99)

where βₒ=ω\sqrt{μₒεₒ}. For vertically polarized sources over the Earth, the depth of the complex image plane can be given by:

d/2≈1/\sqrt{jωμ₁σ₁−ω²μ₁ε₁}, (100)

where μ₁ is the permeability of the lossy conducting medium 203 and ε₁=εᵣεₒ.

At the base of the tuned resonator 306a, the impedance seen “looking up” into the receiving structure is Z_{↑}=Z_{base} as illustrated in FIG. 9A or Z_{↑}=Z_{tuning} as illustrated in FIG. 9C. With a terminal impedance of:

$${Z}_{R} = \frac{1}{j ω {C}_{R}} , \qquad ( 101 )$$

where C_{R} is the self-capacitance of the charge terminal T_{R}, the impedance seen “looking up” into the vertical supply line conductor of the tuned resonator 306a is given by:

$${Z}_{2} = {Z}_{W} \frac{{Z}_{R} + {Z}_{w} tan h ( j {β}_{w} {h}_{w} )}{{Z}_{w} + {Z}_{R} tan h ( j {β}_{w} {h}_{w} )} = {Z}_{W} \frac{{Z}_{R} + {Z}_{w} tan h ( j {θ}_{y} )}{{Z}_{w} + {Z}_{R} tan h ( j {θ}_{y} )} , \qquad ( 102 )$$

and the impedance seen “looking up” into the coil L_{R} of the tuned resonator 306a is given by:

$${Z}_{base} = {R}_{base} + {jX}_{base} = {Z}_{R} \frac{{Z}_{2} + {Z}_{R} tan h ( j {β}_{p} H )}{{Z}_{R} + {Z}_{2} tan h ( j {β}_{p} H )} = {Z}_{c} \frac{{Z}_{2} + {Z}_{R} tan h ( j {θ}_{c} )}{{Z}_{R} + {Z}_{2} tan h ( j {θ}_{c} )} . \qquad ( 103 )$$

By matching the reactive component (Xᵢₙ) seen “looking down” into the lossy conducting medium 203 with the reactive component (X_{base}) seen “looking up” into the tuned resonator 306a, the coupling into the guided surface waveguide mode may be maximized.

Where a lumped element tank circuit is included at the base of the tuned resonator 306a, the self-resonant frequency of the tank circuit can be tuned to add positive or negative impedance to bring the tuned resonator 306b into standing wave resonance by matching the reactive component (Xᵢₙ) seen “looking down” into the lossy conducting medium 203 with the reactive component (X_{tuning}) seen “looking up” into the lumped element tank circuit.

Referring next to FIG. 18C, shown is an example of a tuned resonator 306b that does not include a charge terminal T_{R} at the top of the receiving structure. In this embodiment, the tuned resonator 306b does not include a vertical supply line coupled between the coil L_{R} and the charge terminal T_{R}. Thus, the total phase delay (Φ) of the tuned resonator 306b includes only the phase delay (θ_{c}) through the coil L_{R}. As with the tuned resonator 306a of FIG. 18B, the coil phase delay θ_{c} can be adjusted to match the angle (Ψ) of the wave tilt determined from Equation (97), which results in Φ=Ψ. While power extraction is possible with the receiving structure coupled into the surface waveguide mode, it is difficult to adjust the receiving structure to maximize coupling with the guided surface wave without the variable reactive load provided by the charge terminal T_{R}. Including a lumped element tank circuit at the base of the tuned resonator 306b provides a convenient way to bring the tuned resonator 306b into standing wave resonance with respect to the complex image plane.

Referring to FIG. 18D, shown is a flow chart 180 illustrating an example of adjusting a receiving structure to substantially mode-match to a guided surface waveguide mode on the surface of the lossy conducting medium 203. Beginning with 181, if the receiving structure includes a charge terminal T_{R} (e.g., of the tuned resonator 306a of FIG. 18B), then the charge terminal T_{R} is positioned at a defined height above a lossy conducting medium 203 at 184. As the surface guided wave has been established by a guided surface waveguide probe 200, the physical height (hₚ) of the charge terminal T_{R} may be below that of the effective height. The physical height may be selected to reduce or minimize the bound charge on the charge terminal T_{R} (e.g., four times the spherical diameter of the charge terminal). If the receiving structure does not include a charge terminal T_{R} (e.g., of the tuned resonator 306b of FIG. 18C), then the flow proceeds to 187.

At 187, the electrical phase delay Φ of the receiving structure is matched to the complex wave tilt angle Ψ defined by the local characteristics of the lossy conducting medium 203. The phase delay (θᵣ) of the helical coil and/or the phase delay (θ_{y}) of the vertical supply line can be adjusted to make Φ equal to the angle (Ψ) of the wave tilt (W). The angle (Ψ) of the wave tilt can be determined from Equation (86). The electrical phase delay Φ can then be matched to the angle of the wave tilt. For example, the electrical phase delay Φ=θ_{c}+θ_{y} can be adjusted by varying the geometrical parameters of the coil L_{R} and/or the length (or height) of the vertical supply line conductor.

Next at 190, the resonator impedance can be tuned via the load impedance of the charge terminal T_{R} and/or the impedance of a lumped element tank circuit to resonate the equivalent image plane model of the tuned resonator 306a. The depth (d/2) of the conducting image ground plane 139 (FIGS. 9A-9C) below the receiving structure can be determined using Equation (100) and the values of the lossy conducting medium 203 (e.g., the Earth) at the receiving structure, which can be locally measured. Using that complex depth, the phase shift (θ_{d}) between the image ground plane 139 and the physical boundary 136 (FIGS. 9A-9C) of the lossy conducting medium 203 can be determined using θ_{d}=βₒ d/2. The impedance (Zᵢₙ) as seen “looking down” into the lossy conducting medium 203 can then be determined using Equation (99). This resonance relationship can be considered to maximize coupling with the guided surface waves.

Based upon the adjusted parameters of the coil L_{R} and the length of the vertical supply line conductor, the velocity factor, phase delay, and impedance of the coil L_{R} and vertical supply line can be determined. In addition, the self-capacitance (C_{R}) of the charge terminal T_{R} can be determined using, e.g., Equation (24). The propagation factor (βₚ) of the coil L_{R} can be determined using Equation (98), and the propagation phase constant (β_{w}) for the vertical supply line can be determined using Equation (49). Using the self-capacitance and the determined values of the coil L_{R} and vertical supply line, the impedance (Z_{base}) of the tuned resonator 306 as seen “looking up” into the coil L_{R} can be determined using Equations (101), (102), and (103).

The equivalent image plane model of FIGS. 9A-9C also apply to the tuned resonator 306a of FIG. 18B. The tuned resonator 306a can be tuned to resonance with respect to the complex image plane by adjusting the load impedance Z_{R} of the charge terminal T_{R} such that the reactance component X_{base} of Z_{base} cancels out the reactance component of Xᵢₙ of Zᵢₙ, or X_{base}+Xᵢₙ=0. Where the tuned resonator 306 of FIGS. 18B and 18C includes a lumped element tank circuit, the self-resonant frequency of the parallel circuit can be adjusted such that the reactance component X_{tuning} of Z_{tuning} cancels out the reactance component of Xᵢₙ of Zᵢₙ, or X_{tuning}+Xᵢₙ=0. Thus, the impedance at the physical boundary 136 (FIG. 9A) “looking up” into the coil of the tuned resonator 306 is the conjugate of the impedance at the physical boundary 136 “looking down” into the lossy conducting medium 203. The load impedance Z_{R} can be adjusted by varying the capacitance (C_{R}) of the charge terminal T_{R} without changing the electrical phase delay Φ=θ_{c}+θ_{y} seen by the charge terminal T_{R}. The impedance of the lumped element tank circuit can be adjusted by varying the self-resonant frequency (fₚ) as described with respect to FIG. 9D. An iterative approach may be taken to tune the resonator impedance for resonance of the equivalent image plane model with respect to the conducting image ground plane 139. In this way, the coupling of the electric field to a guided surface waveguide mode along the surface of the lossy conducting medium 203 (e.g., Earth) can be improved and/or maximized.

Referring to FIG. 19, the magnetic coil 309 comprises a receive circuit that is coupled through an impedance matching network 333 to an electrical load 336. In order to facilitate reception and/or extraction of electrical power from a guided surface wave, the magnetic coil 309 may be positioned so that the magnetic flux of the guided surface wave, H_{φ}, passes through the magnetic coil 309, thereby inducing a current in the magnetic coil 309 and producing a terminal point voltage at its output terminals 330. The magnetic flux of the guided surface wave coupled to a single turn coil is expressed by

[symbol]

=∫∫_{A}_{_{CS}}μᵣμₒ [symbol] ·\hat{n}dA, (104)

where [symbol] is the coupled magnetic flux, μᵣ is the effective relative permeability of the core of the magnetic coil 309, μₒ is the permeability of free space, [symbol] is the incident magnetic field strength vector, \hat{n} is a unit vector normal to the cross-sectional area of the turns, and A_{CS} is the area enclosed by each loop. For an N-turn magnetic coil 309 oriented for maximum coupling to an incident magnetic field that is uniform over the cross-sectional area of the magnetic coil 309, the open-circuit induced voltage appearing at the output terminals 330 of the magnetic coil 309 is

$$V = - N \frac{d ℱ}{dt} \approx - j ω {μ}_{r} {μ}_{0} {NHA}_{CS} , \qquad ( 105 )$$

where the variables are defined above. The magnetic coil 309 may be tuned to the guided surface wave frequency either as a distributed resonator or with an external capacitor across its output terminals 330, as the case may be, and then impedance-matched to an external electrical load 336 through a conjugate impedance matching network 333.

Assuming that the resulting circuit presented by the magnetic coil 309 and the electrical load 336 are properly adjusted and conjugate impedance matched, via impedance matching network 333, then the current induced in the magnetic coil 309 may be employed to optimally power the electrical load 336. The receive circuit presented by the magnetic coil 309 provides an advantage in that it does not have to be physically connected to the ground.

With reference to FIGS. 18A, 18B, 18C and 19, the receive circuits presented by the linear probe 303, the tuned resonator 306, and the magnetic coil 309 each facilitate receiving electrical power transmitted from any one of the embodiments of guided surface waveguide probes 200 described above. To this end, the energy received may be used to supply power to an electrical load 315/327/336 via a conjugate matching network as can be appreciated. This contrasts with the signals that may be received in a receiver that were transmitted in the form of a radiated electromagnetic field. Such signals have very low available power, and receivers of such signals do not load the transmitters.

It is also characteristic of the present guided surface waves generated using the guided surface waveguide probes 200 described above that the receive circuits presented by the linear probe 303, the tuned resonator 306, and the magnetic coil 309 will load the excitation source 212 (e.g., FIGS. 3, 12 and 16) that is applied to the guided surface waveguide probe 200, thereby generating the guided surface wave to which such receive circuits are subjected. This reflects the fact that the guided surface wave generated by a given guided surface waveguide probe 200 described above comprises a transmission line mode. By way of contrast, a power source that drives a radiating antenna that generates a radiated electromagnetic wave is not loaded by the receivers, regardless of the number of receivers employed.

Thus, together one or more guided surface waveguide probes 200 and one or more receive circuits in the form of the linear probe 303, the tuned resonator 306a/b, and/or the magnetic coil 309 can make up a wireless distribution system. Given that the distance of transmission of a guided surface wave using a guided surface waveguide probe 200 as set forth above depends upon the frequency, it is possible that wireless power distribution can be achieved across wide areas and even globally.

The conventional wireless-power transmission/distribution systems extensively investigated today include “energy harvesting” from radiation fields and also sensor coupling to inductive or reactive near-fields. In contrast, the present wireless-power system does not waste power in the form of radiation which, if not intercepted, is lost forever. Nor is the presently disclosed wireless-power system limited to extremely short ranges as with conventional mutual-reactance coupled near-field systems. The wireless-power system disclosed herein probe-couples to the novel surface-guided transmission line mode, which is equivalent to delivering power to a load by a waveguide or a load directly wired to the distant power generator. Not counting the power required to maintain transmission field strength plus that dissipated in the surface waveguide, which at extremely low frequencies is insignificant relative to the transmission losses in conventional high-tension power lines at 60 Hz, all of the generator power goes only to the desired electrical load. When the electrical load demand is terminated, the source power generation is relatively idle.

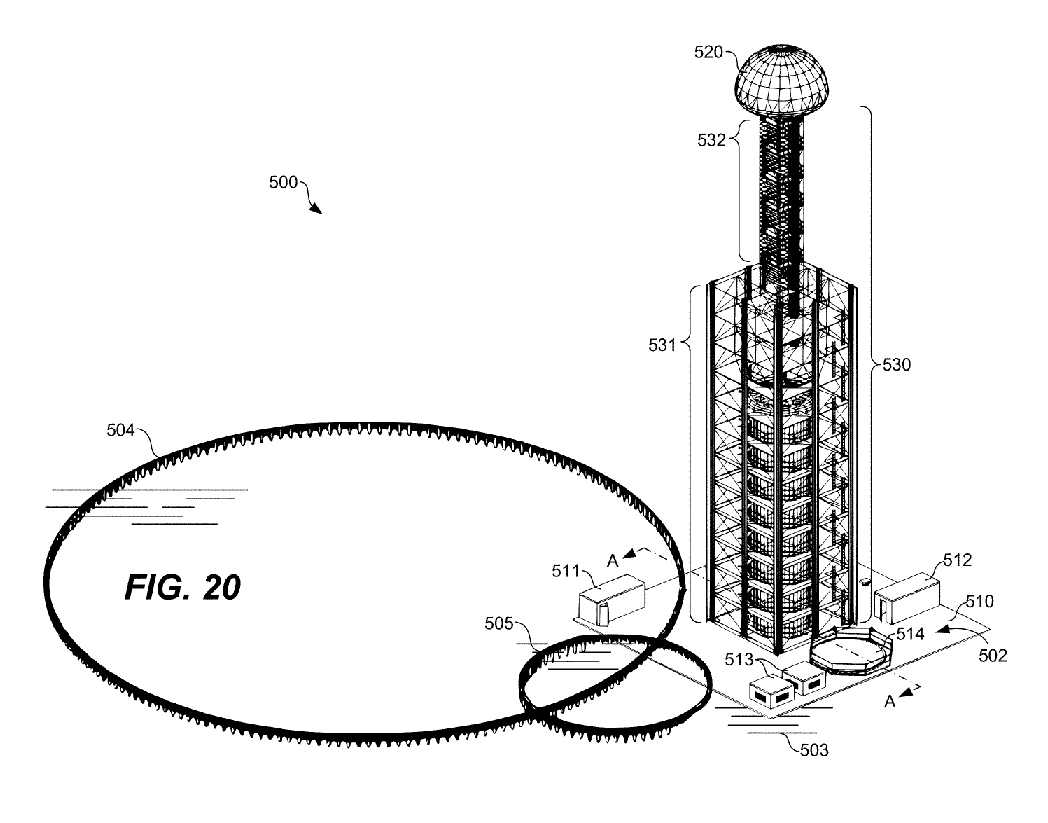

Referring next to FIG. 20, an example of a guided surface waveguide probe 500 is illustrated according to various embodiments of the present disclosure. The guided surface waveguide probe 500 is situated on a probe site. The guided surface waveguide probe 500 is provided as an example of the types of structures that can be used to launch guided surface waves on a lossy conducting media, but is not intended to be limiting or exhaustive as to those structures. Not all the structures that make up the guided surface waveguide probe 500 shown in FIG. 20 are necessary in all cases, and various structures can be omitted. Similarly, the guided surface waveguide probe 500 can include other structures not illustrated in FIG. 20.

Among other parts, components, or structures, the guided surface waveguide probe 500 is constructed with a substructure 502 constructed in a lossy conducting medium 503, such as the Earth. The substructure 502 forms a substructure of the guided surface waveguide probe 500 and may be used to house various equipment as will be described. In one embodiment, the guided surface waveguide probe 500 includes one or more external phasing coils 504 and 505. The external phasing coils 504 and 505 can provide both phase delay and phase shift as described below. In various embodiments, the external phasing coils 504 and 505 may not be used and can be omitted depending on design considerations such as the frequency of operation and other considerations as described above.

The guided surface waveguide probe 500 can be constructed at any suitable geographic location on the Earth. In some cases, a portion of the lossy conducting medium 503 around the guided surface waveguide probe 500 can be conditioned to adjust its permittivity, conductivity, or related characteristics. The external phasing coils 504 and 505 can be constructed at any suitable locations, including around (e.g., encircling) the guided surface waveguide probe 500 as will be further described below.

The substructure 502 includes a covering support slab 510 at a ground surface elevation of the lossy conducting medium 503. To provide entry and exit points to the guided surface waveguide probe 500 for individuals, the substructure 502 includes entryways 511 and 512, leading to staircases, for example, leading down into the substructure 502. The substructure 502 also includes a number of vents 513 to exhaust forced air, for example, from heating, ventilation, and air conditioning (HVAC) systems in the substructure 502 and for potentially other purposes. Also, the vents 513 may be used for air intake as needed. Additionally, the substructure 502 includes an access opening 514 which can be used to lower various types of equipment down into the substructure 502.

The guided surface waveguide probe 500 includes a charge reservoir or terminal 520 (“charge terminal 520”) elevated to a height above the lossy conducting medium 503 over the substructure 502. The guided surface waveguide probe 500 also includes a support structure 530. The support structure 530 includes a truss frame 531 and a charge terminal truss extension 532 (“the truss extension 532”). The truss frame 531 is secured to and supported by the covering support slab 510 and substructure elements in the substructure 502 such as pillars and beams as will be described.

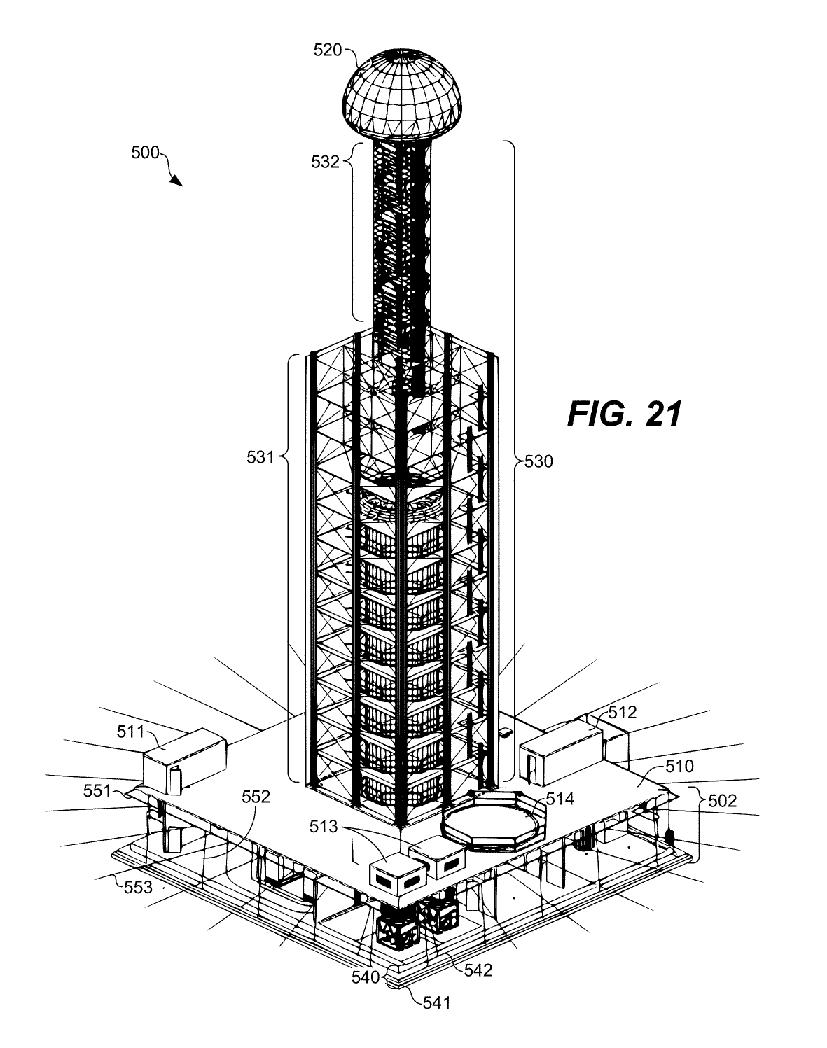

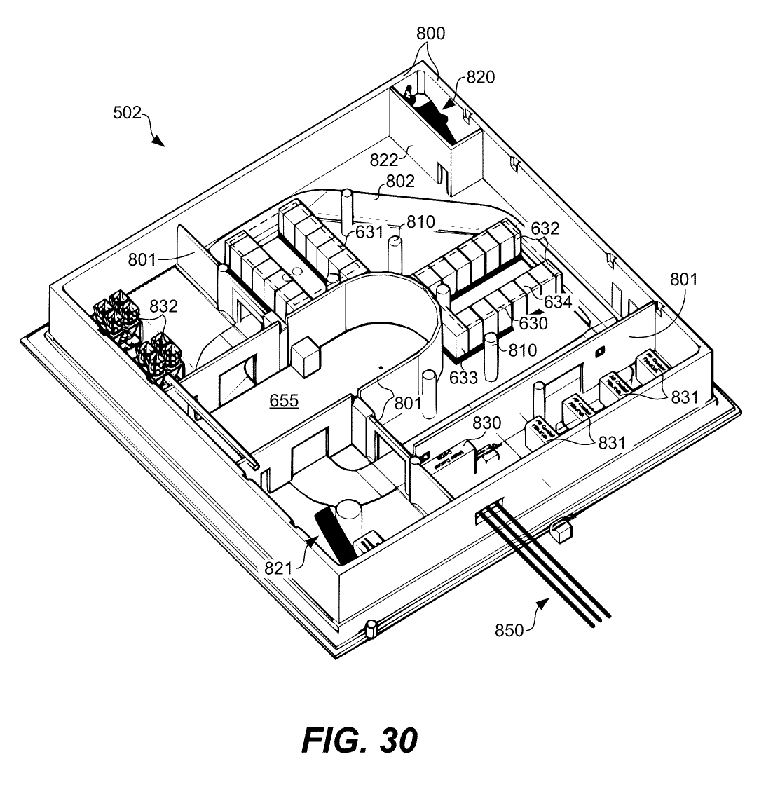

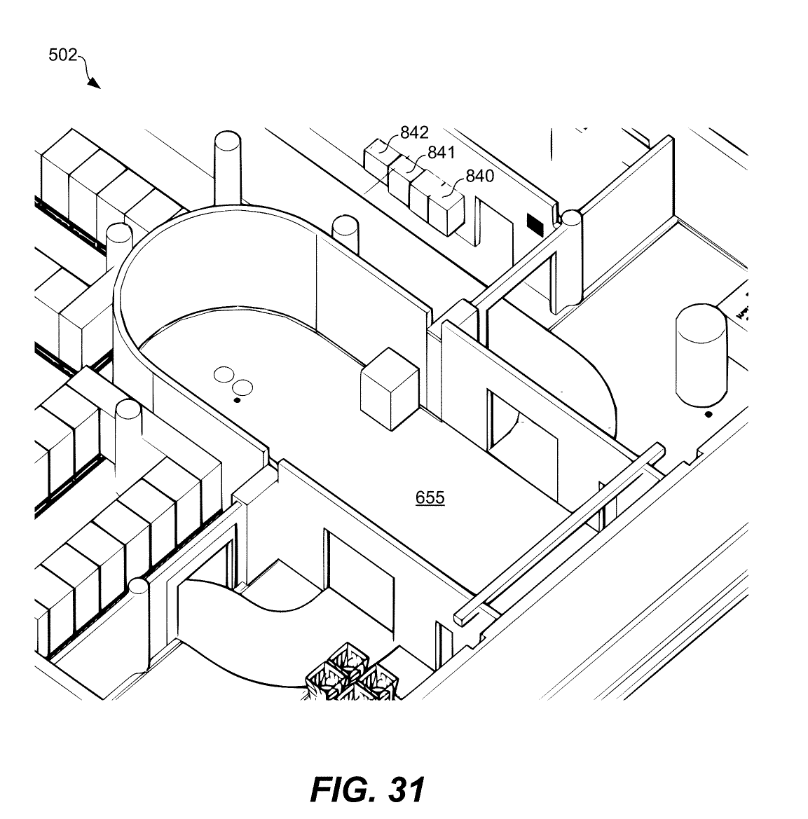

With reference to FIG. 21, shown is a further view of the guided surface waveguide probe 500 according to various embodiments of the present disclosure. As shown, the substructure 502 is constructed to a large extent within the lossy conducting medium 503. The substructure 502 provides a supporting, foundational substructure for the guided surface waveguide probe 500, similar to the way a basement or cellar provides a below-ground foundation for a building. In one example case, the substructure 502 can be constructed to include one floor or level at a depth of about 18 feet deep from the ground surface of the lossy conducting medium 503. In other embodiments, the substructure 502 can include additional underground floors and be constructed to other depths. Additional aspects of the substructure 502 are described below with reference to FIGS. 30 and 31.

The truss frame 531 includes a number of platforms supported, respectively, at elevated heights above the covering support slab 510. Among other components of the guided surface waveguide probe 500, a number of internal phasing coil sections of the guided surface waveguide probe 500 can be supported at one or more of the platforms as discussed in further detail below. The truss extension 532 is supported at one end by a transitional truss support region of the truss frame 531. The truss extension 532 also supports, at another end, the charge terminal 520 above the lossy conducting medium 503.

To provide an example frame of reference for the size of the guided surface waveguide probe 500, the substructure 502 can be constructed at a size of about 92 feet in width and length, although it can be constructed to any other suitable size. The guided surface waveguide probe 500 can be constructed to a height of over 200 feet in one embodiment. In that case, the charge terminal 520 can be elevated to a height of approximately 190 feet above the lossy conducting medium 503. However, it is understood that the height of the charge terminal 520 depends upon the design considerations described above, where the guided surface waveguide probe 500 is designed to position the charge terminal 520 at a predetermined height depending on various parameters of the lossy conducting medium 503 at the site of transmission and other operating factors. In one example, the base of the truss frame 531 can be constructed as a square with sides about 32 feet in length and width. It is understood that the truss frame 531 can be constructed to other shapes and dimensions. To this end, the guided surface waveguide probe 500 is not limited to any particular size or dimensions and can be constructed to any suitable size among the embodiments based on various factors and design considerations set forth above.

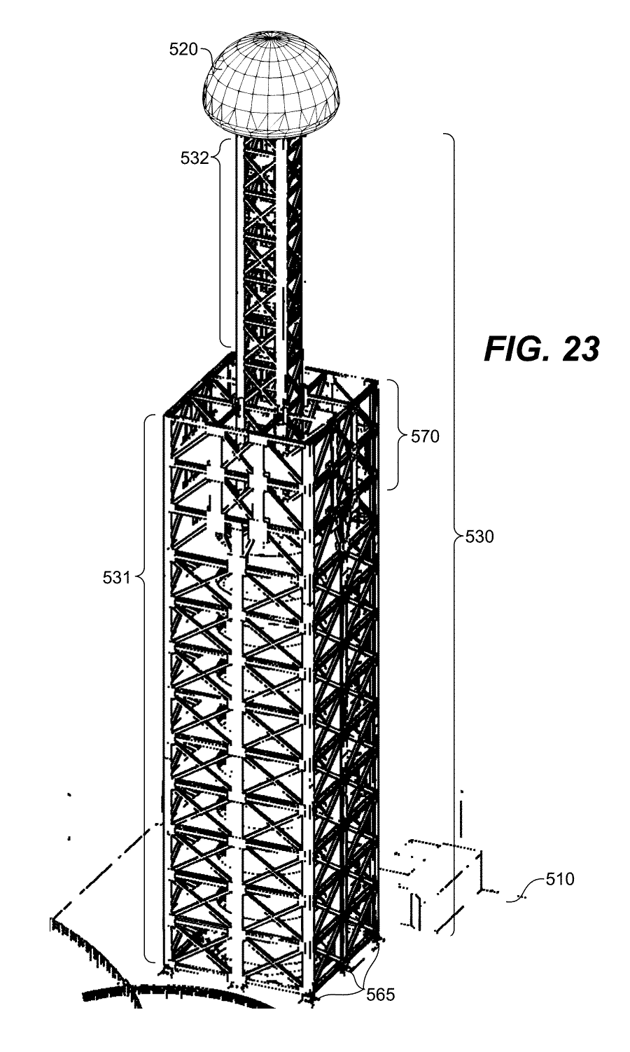

For simplicity, the truss frame 531 and the truss extension 532 of the guided surface waveguide probe 500 are drawn representatively in FIG. 20. Particularly, a number of vertical, horizontal, and cross beam support bars of the truss frame 531 and the truss extension 532 are omitted from view in FIG. 20. Additionally, a number of gusset plates of the truss frame 531 and the truss extension 532 are omitted from view. The vertical, horizontal, and cross beam support bars, gusset plates, connecting hardware, and other parts of the guided surface waveguide probe 500 are formed from non-conductive materials so as not to adversely affect the operation of the guided surface waveguide probe 500. The parts of the truss frame 531 and the truss extension 532 of the guided surface waveguide probe 500 are shown in FIG. 23 and described in further detail below.

FIG. 21 illustrates an example of the substructure 502 associated with the guided surface waveguide probe 500 shown in FIG. 20. The lossy conducting medium 503 and sidewalls of the substructure 502 are omitted from view in FIG. 20. As further described below, the substructure 502 includes a number of rooms or areas to store equipment, such as power transformers, variable power and frequency power transmitters, supervisory control and data acquisition (SCADA) systems, human-machine interface systems, electrical systems, power transmission system monitoring and control systems, heating, ventilation, and air conditioning (HVAC) systems, building monitoring and security systems, fire protection systems, water and air cooling systems, and other systems. Examples of the equipment in the substructure 502 is described in further detail below with reference to FIGS. 30 and 31.

Among a number of internal and external walls described below, the substructure 502 includes a foundation base 540 including a seal slab 541 and a base slab 542. The seal slab 541 can be formed from poured concrete. According to one embodiment, the base slab 542 is also formed from poured concrete and is reinforced with fiberglass bars as will be described.

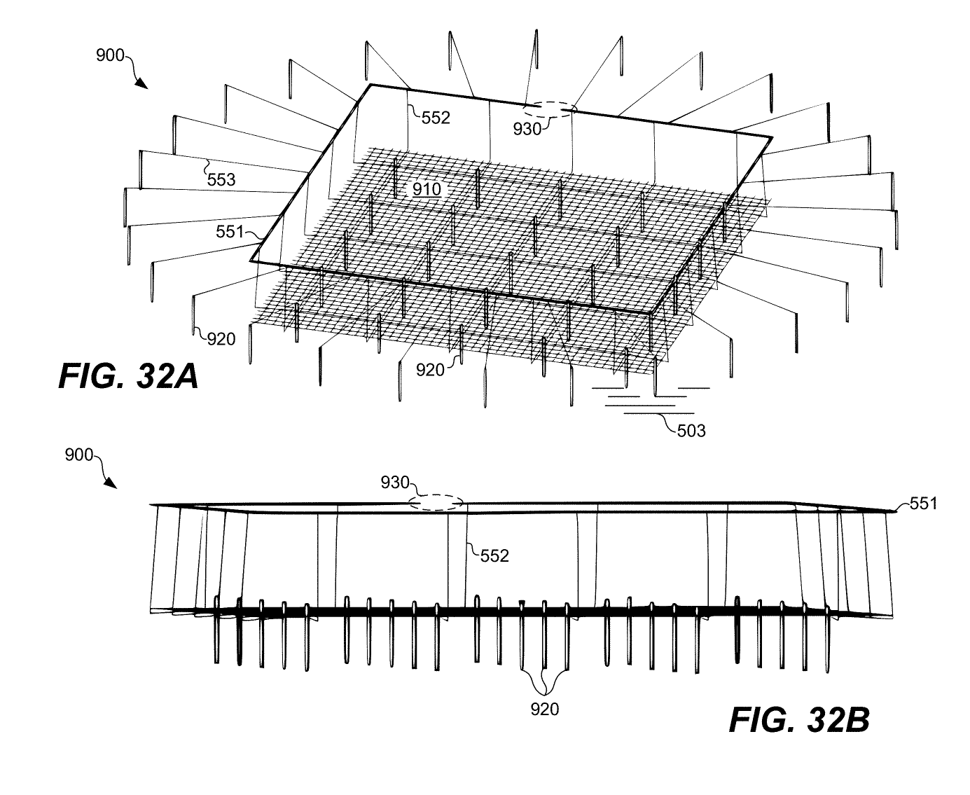

A grounding system, which is described in further detail below with reference to FIGS. 32A and 32B, is formed and sealed in the seal slab 541 of the foundation base 540. The grounding system also includes a grounding grid (not shown) in the seal slab 541, a grounding ring 551, connecting conductors 552, grounding radials 553, and other components not individually referenced in FIG. 21. As described below, each of the grounding radials 553 is electrically connected or coupled at one end to the grounding ring 551. The other end of each of the grounding radials 553 extends out from the grounding ring 551 radially away from the guided surface waveguide probe 500 to a staked location in the lossy conducting medium 503.

In one example case, the grounding radials 553 extend out about 100 feet from the guided surface waveguide probe 500, although other lengths of grounding radials 553 can be used. Further, the grounding radials 553 extend out from the grounding ring 551 at a depth below the ground surface of the lossy conducting medium 503. For example, in one embodiment, the grounding radials 553 extend radially away from the grounding ring 551 and the guided surface waveguide probe 500 at a depth of about 12 to 24 inches below the ground surface of the lossy conducting medium 503, although they can be buried at other depths. The grounding grid (not shown) in the seal slab 541, the grounding ring 551, and the grounding radials 553 provide electrical contact with the lossy conducting medium 503 for the guided surface waveguide probe 500 and various equipment in the substructure 502.

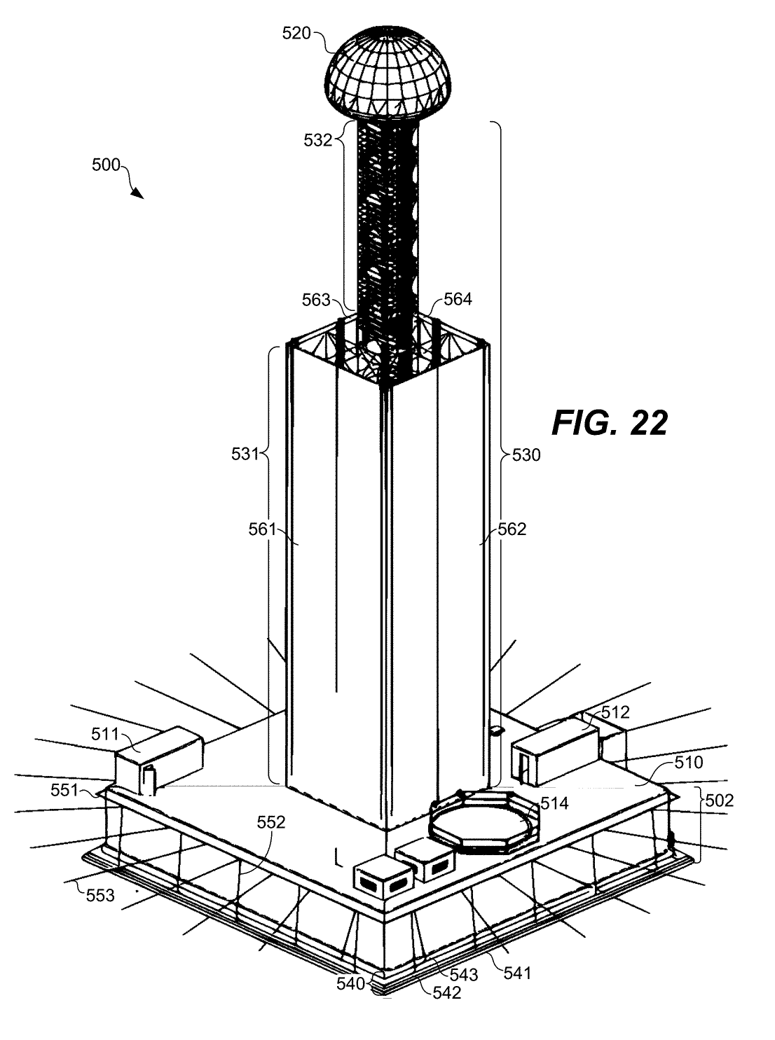

FIG. 22 illustrates the guided surface waveguide probe 500 shown in FIG. 20 with exterior coverings 561-564 according to various embodiments of the present disclosure. The exterior coverings 561-564, among others, can be installed around one or both of the truss frame 531, as shown in FIG. 22, and the truss extension 532. The exterior coverings 561-564 can be installed to insulate and protect the truss frame 531 and the truss extension 532 from the sun and various meteorological processes and events. The exterior coverings 561-564 can also be installed to facilitate forced-air heating and cooling of the guided surface waveguide probe 500 using HVAC systems, for example, installed in the substructure 502 or other location. Similar to the other parts of the truss frame 531 and the truss extension 532, the exterior coverings 561-564 of the guided surface waveguide probe 500 are formed from non-conductive materials so as not to interfere electrically with the operation of the guided surface waveguide probe 500.

FIG. 23 illustrates an example of the support structure 530 of the guided surface waveguide probe 500. As shown in FIG. 23, the support structure 530 of the guided surface waveguide probe 500 can be formed as a truss, including a number of vertical, horizontal, and cross beam support bar members joined together using gusset plates and fasteners at a number of nodes. Cross beam support bar members, the gusset plates, and the fasteners are all nonconductive having been made from nonconductive materials such as pultruded fiber reinforced polymer (FRP) composite structural products.

External forces on the support structure 530 primarily act at the nodes (e.g., gusset plates, fasteners) of the support structure 530 and result in support bar member forces that are either tensile or compressive that exert sheer forces on the gusset plates and fasteners. The support structure 530 is constructed so as not to exert moment forces on the gusset plates and the fasteners that form the junctions in the support structure 530. This accommodates the fact that the fasteners are constructed from nonconductive materials that might have difficulty withstanding such forces without failure. The support structure 530 is secured to the covering support slab 510 using a number of base brackets 565, which can be formed from metal or other appropriate material. In one embodiment, the base brackets 565 are formed from stainless steel to reduce the possibility that the base brackets 565 would become magnetized.

As shown in FIG. 23, the support structure 530 includes a transitional truss region 570 between the truss frame 531 and the terminal truss extension 532. The transitional truss region 570 includes a number of additional cross beam support bars that extend and are secured between nodes in the truss frame 531 and nodes in the terminal truss extension 532. The additional cross beams in the transitional truss region 570 secure the terminal truss extension 532 to the truss frame 531.

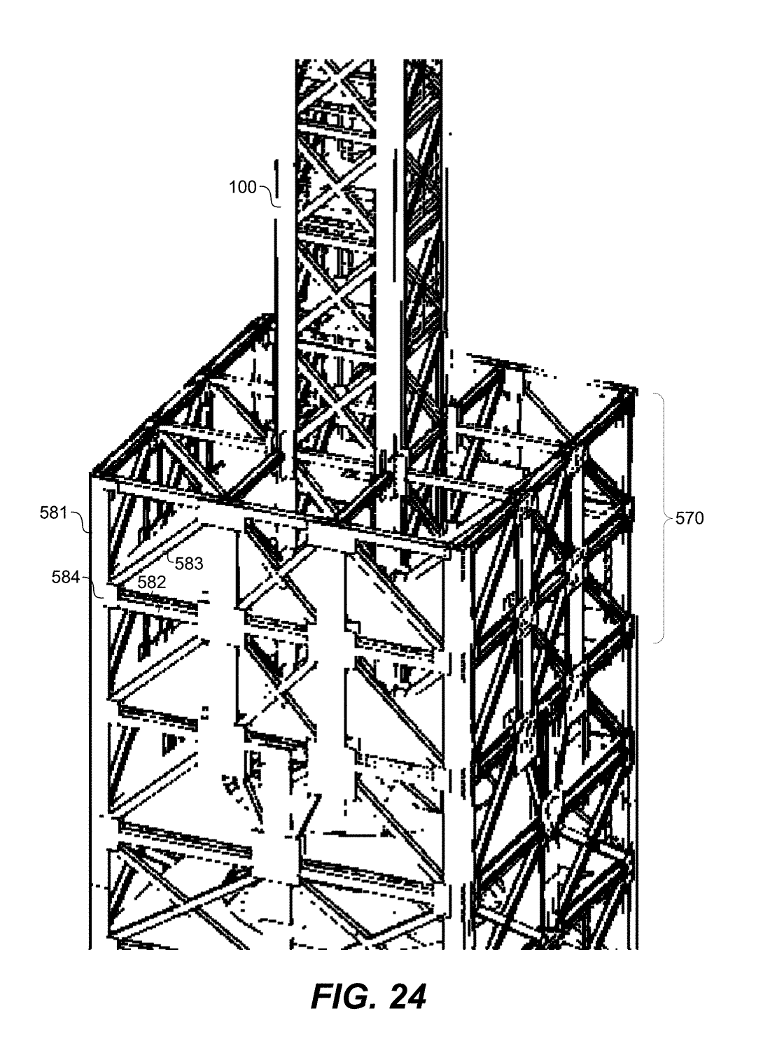

FIG. 24 illustrates a closer view of the transitional truss region 570 of the guided surface waveguide probe 500, in which examples of the vertical support bars 581, the horizontal support bars 582, the cross beam support bars 583 (collectively, “the bars 581-583), and the gusset plates 584 can be more clearly seen. As shown in FIG. 24, the truss frame 531 and the terminal truss extension 532 can be constructed using a number of vertical support bars 581, horizontal support bars 582, cross beam support bars 583, and gusset plates 584 of various shapes and sizes. For example, the bars 581-583 can be formed as L beams, I or H beams, T beams, etc. at various lengths and cross-sectioned sizes. In that context, the bars 581-583 can be designed to translate loads to the gusset plates 584.

The gusset plates 584 can be formed as relatively thick plates of material and are used to connect a number of the bars 581-583 together at various nodes in the support structure 530. Each of the gusset plates 584 can be fastened to a number of the bars 581-583 using nonconductive bolts or other nonconductive fastening means, or a combination of fastening means. As noted above, external forces on the support structure 530 primarily act at the nodes gusset plates 584.

As previously mentioned, the vertical support bars 581, horizontal support bars 582, cross beam support bars 583, gusset plates 584, fasteners, and/or other connecting hardware, and other parts of the truss frame 531 and the truss extension 532 can be formed (entirely or substantially) from non-conductive materials. For example, such support bars 582, cross beam support bars 583, gusset plates 584, fasteners, and other connecting hardware may be constructed of pultruded fiber reinforced polymer (FRP) composite structural products. Alternatively, the same may be made out of wood or resin impregnated wood structural products. In addition, other non-conductive materials may be used.

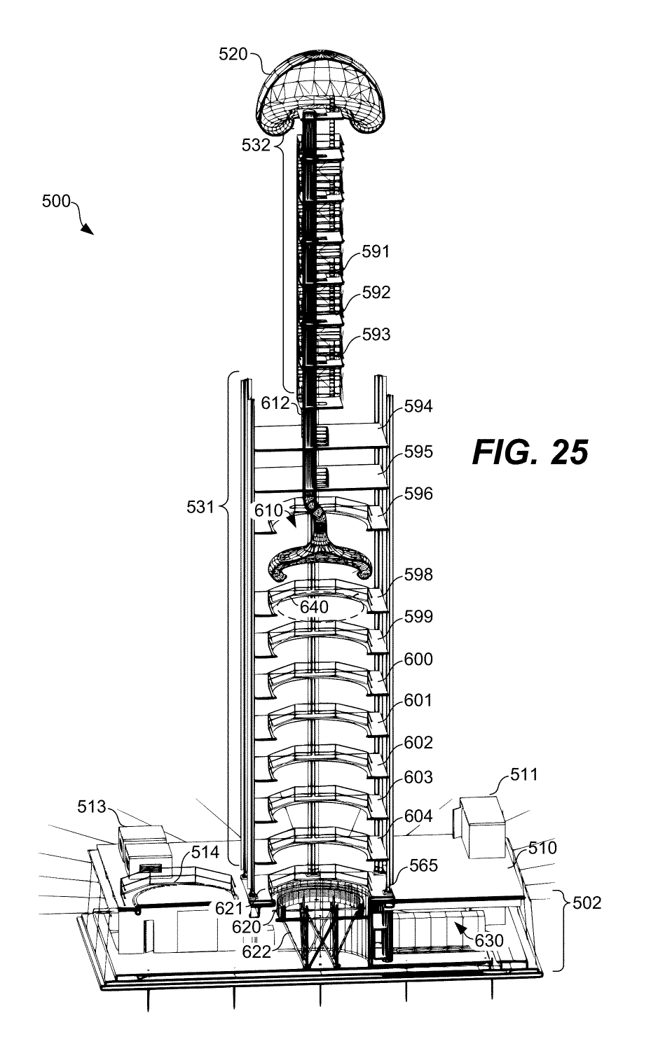

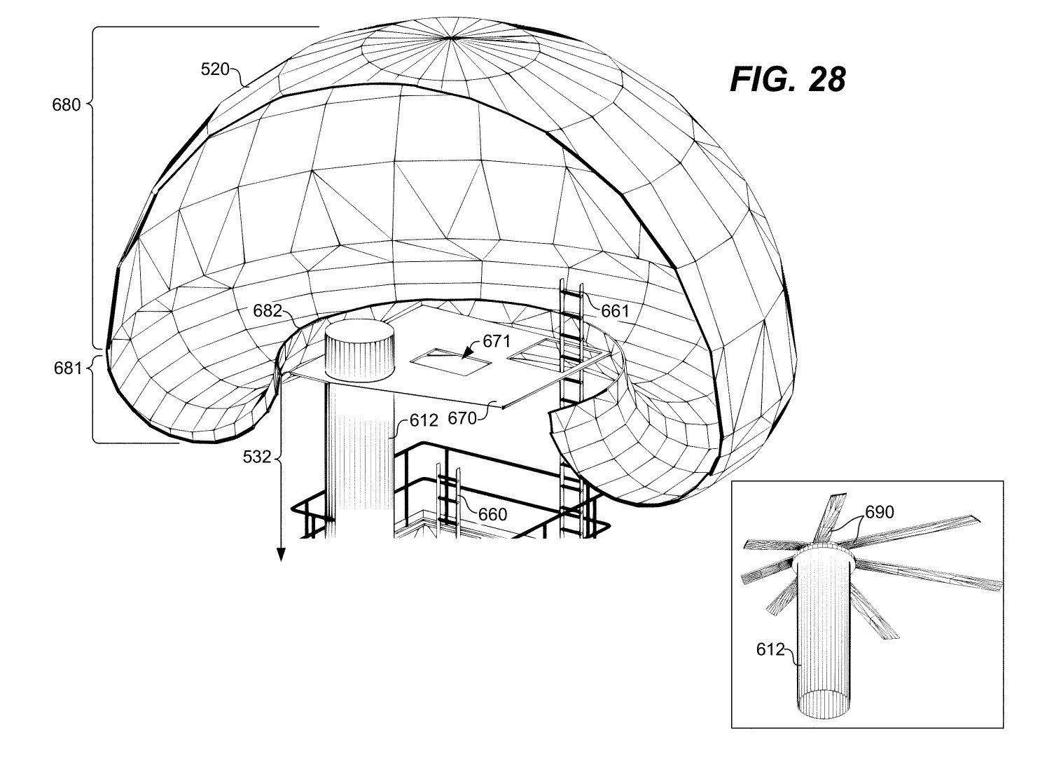

FIG. 25 is the cross-sectional view A-A of the guided surface waveguide probe 500 designated in FIG. 20. In FIG. 25, the bars 581-583 and the gusset plates 584 of the truss frame 531 and the terminal truss extension 532 are omitted from view. Thus, among others, a number of platforms 591-604 of the guided surface waveguide probe 500 are shown. The platform 597 (FIG. 28) is omitted from view in FIG. 25 so as not to obscure other components of the guided surface waveguide probe 500. The platforms 591-593 are supported by the truss extension 532, and platforms 594-604 are supported by the truss frame 531. In various embodiments, individuals can access the platforms 591-604, among others, using ladders, staircases, elevators, etc. between them, as also shown in FIG. 21.

A number of additional components of the guided surface waveguide probe 500 are shown in FIG. 25, including a corona hood 610 and a coil 620 that, in one embodiment, can be used to inductively couple power to other electrical components of the guided surface waveguide probe 500 as will be described. The coil 620 is supported by a coil support stand 622. A power transmitter bank 630 is housed in the substructure 502.

The corona hood 610 comprises an annular canopy that tapers into a tube 612. The tube 612 extends along (and through the platforms 591-596 of) a portion of the truss frame 531 and the truss extension 532 into a bottom opening of the charge terminal 520. The corona hood 610 is positioned within an opening in the platform 597 (FIG. 28), similar to the opening 640 in the platform 598 and the other platforms 599-604. In various embodiments, the corona hood 610 can be formed from one or more conductive materials such as copper, aluminum, or other metal.

In one embodiment, the covering support slab 510 includes a square opening close to its center, and the truss frame 531 is secured to the covering support slab 510 at the base brackets 565 positioned along the periphery of this square opening. Further, a base plate 621 can be secured over the square opening in the covering support slab 510 between the covering support slab 510 and the truss frame 531. As shown, the base plate 621 can include a circular opening in its center. The coil 620 can be supported by the coil support stand 622 below, within, or above the circular opening through the base plate 621. According to one embodiment, the base plate 621 may be constructed of nonconductive materials such as pultruded fiber reinforced polymer (FRP) composite structural material and/or other nonconductive materials according to one embodiment.

In one embodiment, the external phasing coils 504 and 505 (FIG. 20) are positioned such that at least one edge of the external phasing coils 504 and/or 505 is relatively close or adjacent to the square opening in the covering support slab 510 and the truss frame 531. In that configuration, it is possible to minimize the lengths of conductors extending between power sources in the substructure 502 and the external phasing coils 504 and/or 505, and/or between the external phasing coils 504 and/or 505 and other electrical components, such as internal phasing coils in the tower structure of the guided surface waveguide probe 500. In addition, other openings may be created in the covering support slab 510 to accommodate conductors that extend from a power source in the substructure 502 to one or both of the external phasing coils 504 and/or 505. In one embodiment, a distance between an edge of one or both of the external phasing coils 504 and/or 505 and an internal phasing coil positioned in the interior of the tower structure of the guided surface waveguide probe 500 is less than ⅛th of the periphery of the respective coils 504 and/or 505.

The coil 620 can be embodied as a length of conductor, such as wire or pipe, for example, wrapped and supported around a coil support structure. The coil support structure may comprise a cylindrical body or other support structure to which the wire or pipe is attached in the form of a coil. In one example case, the coil 620 can be embodied as a number of turns of a conductor wrapped around a support structure such as a cylindrical housing at about 19 feet in diameter, although the coil 620 can be formed to other sizes.

The power transmitter bank 630, which acts as a power source for the guided surface waveguide probe 500, is configured to convert bulk power to a range of output power over a range of sinusoidal output frequencies, such as up to a megawatt of power, for example, over a range of frequencies from about 6 kHz-100 kHz, or other frequencies or frequency ranges. As described in further detail below with reference to FIG. 30, the guided surface waveguide probe 500 can include a number of power transmitter cabinets, controllers, combiners, etc., such as the power transmitter bank 630 and others. The power transmitter bank 630 is not limited to any particular range of output power or output frequencies, however, as the guided surface waveguide probe 500 can be operated at various power levels and frequencies. In one example embodiment, the power transmitter bank 630 comprises various components including amplifier cabinets, control cabinet, and a combiner cabinet. The amplifier cabinets may be, for example, model D120R Amplifiers manufactured by Continental Electronics of Dallas, Tex. Likewise the control cabinet and combiner cabinet are also manufactured by Continental Electronics of Dallas Tex. It is understood, however, that power transmitter equipment manufactured by others may be used. In addition, it is understood that types of power sources other than power transmitter equipment may be used including, for example, generators or other sources.

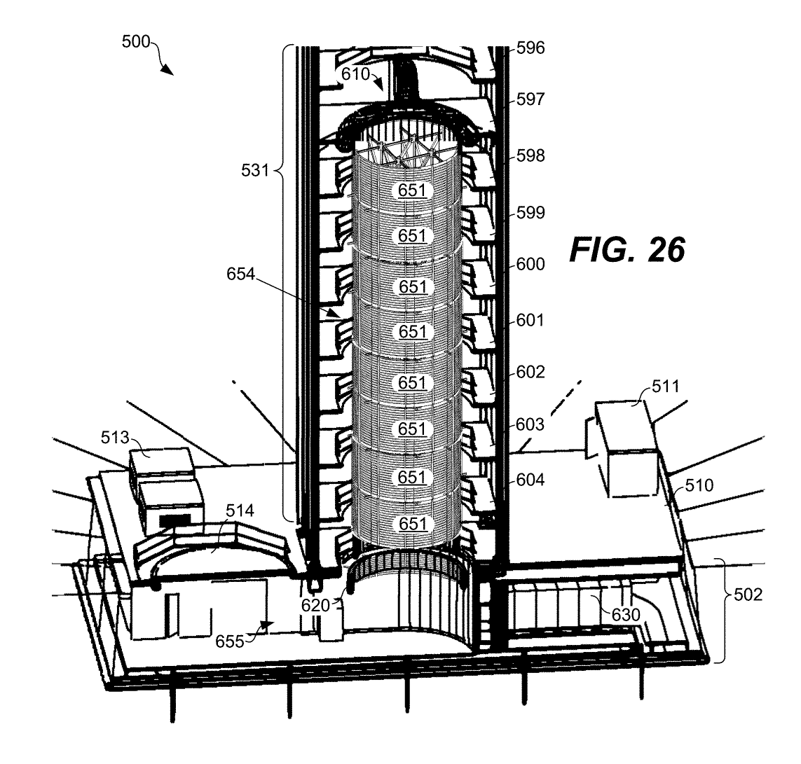

Depending upon the operating configuration of the guided surface waveguide probe 500, the output of the power transmitter bank 630 (and other power transmitter banks) can be electrically coupled to the coil 620. In turn, power can be inductively coupled from the power transmitter bank 630 to other electrical components of the guided surface waveguide probe 500 using the coil 620. For example, power can be inductively coupled from the coil 620 to the internal phasing coils 651 shown in FIG. 26. Alternatively, one or more other coils positioned relative (or adjacent) to the external phasing coils 504 and/or 505 can be used to inductively couple power from the power transmitter bank 630 to one or both of the external phasing coils 504 and/or 505. For example, such coils can be wrapped around (and supported by) the same support structure around which the external phasing coils 504 or 505 are supported. In one embodiment, such coils might be placed on the ground adjacent to or below one or both of the external phasing coils 504 and/or 505.

Generally, depending upon the operating frequency of the guided surface waveguide probe 500 (e.g., 400 Hz, 8 kHz, or 20 kHz operation), the output of the power transmitter bank 630 can be electrically coupled to one or more coils similar to the coil 620 for inductive coupling to one or more internal or external phasing coils of the guided surface waveguide probe 500 as described herein. Additionally or alternatively, the output of the power transmitter bank 630 can be electrically coupled to one or more coils similar to the coil 620 for inductive coupling to one or more tank (inductive) coils of the guided surface waveguide probe 500 as described herein.

FIG. 26 is the cross-sectional view A-A designated in FIG. 20 and illustrates a number of internal phasing coils 651 of the guided surface waveguide probe 500 according to various embodiments of the present disclosure. The internal phasing coils 651 are termed “internal” given that they are supported within the truss frame 531, although similar coils can be positioned outside of the truss frame 531. Similarly, the external phasing coils 504 and 505 are termed “external” given that they are placed outside of the truss frame 531.

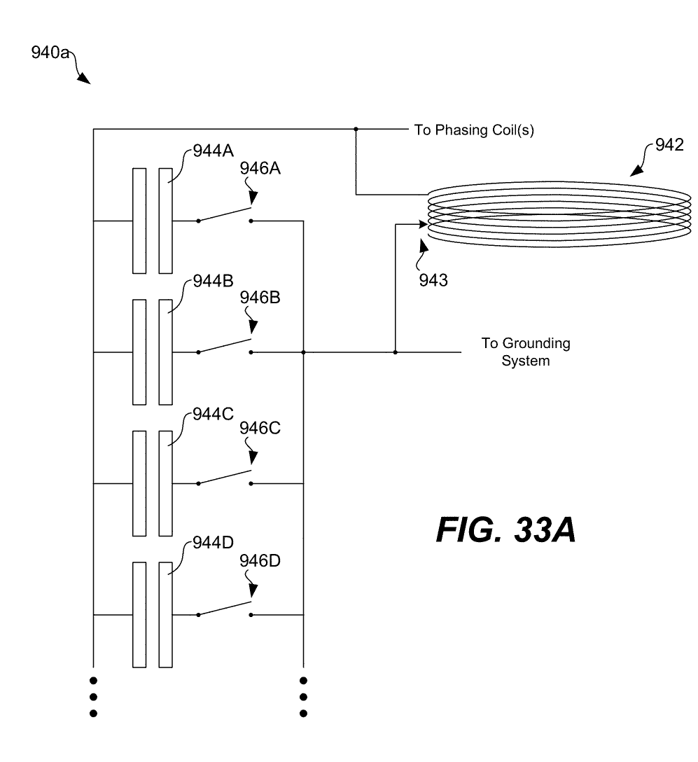

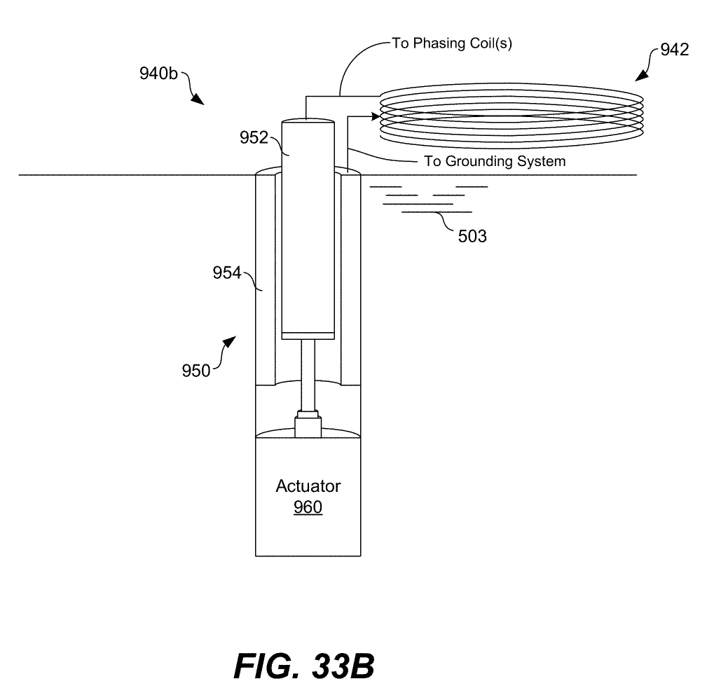

It should be noted that the internal phasing coils 651 shown in FIG. 26 are analogous to the phasing coil 215 shown in FIGS. 7A and 7B. The internal phasing coils 651 are also analogous to the phasing coil 215a shown in FIG. 7C. Additionally, the external phasing coils 504 and 505 are analogous to the phasing coil 215b shown in FIG. 7C. Further, the guided surface waveguide probe 500 can include a tank circuit as described below with reference to FIGS. 33A and 33B below, and the components in that tank circuit are analogous to the components of the tank circuit 260 shown in FIGS. 7B and 7C.

In one embodiment, the internal phasing coils 651 are positioned adjacent to each other to create one large single internal phasing coil 654. To this end, the internal phasing coils 651 may be positioned such that any discontinuity in the turn by turn spacing of the internal phasing coils 651 at the junction between two respective internal phasing coils 651 is minimized or eliminated, assuming that the turn by turn spacing of each of the internal phasing coils 651 is the same. In other embodiments, the turn by turn spacing of the internal phasing coils 651 may differ from one internal phasing coil 651 to the next. In one embodiment, the internal phasing coils 651 may be in one or more groups, where each group has a given turn by turn spacing. Alternatively, in another embodiment, each internal phasing coil 651 may have a turn by turn spacing that is unique with respect to all others depending on the ultimate design of the guided surface waveguide probe 500. In addition, the diameters of respective ones of the internal phasing coils 651 may vary as well.

Each of the internal phasing coils 651 can be embodied as a length of conductor, such as wire or pipe, for example, wrapped and supported around a support structure. In one embodiment, the support structure may comprise a cylindrical housing or some other structural arrangement. As one example, the internal phasing coils 651 can be about 19 feet in diameter, although other sizes can be used depending on design parameters.

The internal phasing coils 651 can be supported at one or more of the platforms 598-604 and/or the covering support slab 510. The guided surface waveguide probe 500 is not limited to the use of any particular number of the internal phasing coils 651 or, for that matter, any particular number of turns of conductors in the internal phasing coils 651. Instead, based on the design of the guided surface waveguide probe 500, which can vary based on various operating and design factors, any suitable number of internal phasing coils 651 can be used, where the turn by turn spacing and diameter of such internal phasing coils 651 can vary as described above.

To configure the guided surface waveguide probe 500 for use, the internal phasing coils 651 can be individually lowered through the access opening 514 in the covering support slab 510, lowered into the passageway 655, and moved through the passageway 655 to a position below the truss frame 531. From below the truss frame 531, the internal phasing coils 651 can be raised up into position within the openings in the platforms 598-604 and supported at one or more of the platforms 598-604. In one embodiment, each of the internal phasing coils 651 may be hung from the structural members of a respective platform 598-604. Alternatively, each of the internal phasing coils 651 may rest on structural members associated with a respective platform 598-604.

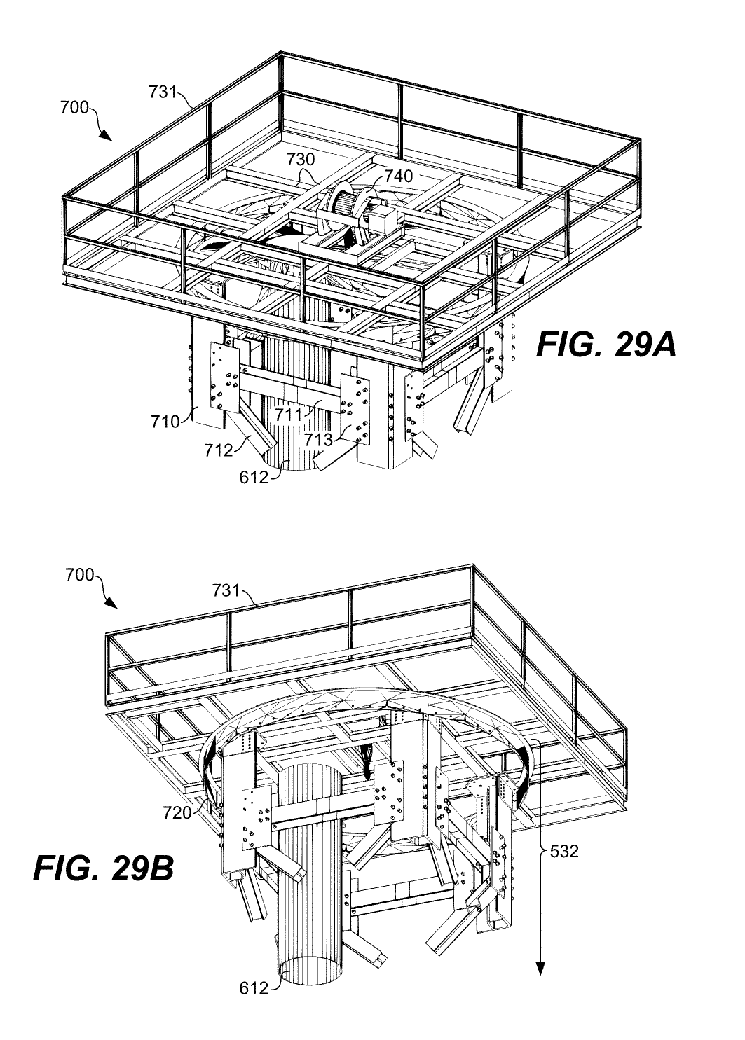

To raise one of the internal phasing coils 651, it can be secured to a winch line and lifted using a winch. The winch can be positioned in the truss frame 531, the truss extension 532, and/or the charge terminal 520. An example winch is shown and described below with reference to FIG. 29A. In the event that a winch is positioned in the truss frame 531 or the truss extension 532, it may be attached in a temporary manner so that the winch may be removed when necessary. In this manner, such a winch would be removeably attached to the truss frame 531 or the truss extension 532 given that such a winch would be made of conductive materials that are likely to interfere with the operation of the guided surface waveguide probe 500.

In one embodiment, a conductor that extends from the bottom end of the bottom most internal phasing coil 651 is coupled to the grounding grid described below with reference to FIGS. 32A and 32B. Alternatively, the conductor that extends from the bottom end of the bottom most internal phasing coil 651 can be coupled to an external phasing coil, such as one of the external phasing coils 504 and/or 505. Intermediate ones of the internal phasing coils 651 are electrically coupled to adjacent ones of the internal phasing coils 651. A conductor that extends from the top end of the top most internal phasing coil 651 that is part of the single internal phasing coil 654 is electrically coupled to the corona hood 610 and/or the charge terminal 520. If coupled to the corona hood 610, the top most internal phasing coil 651 is coupled to the corona hood 610 at a point that is recessed up into the underside of the corona hood 610 to avoid the creation of corona as will be described.

When power is provided from the power transmitter bank 630 to the coil 620 at a certain voltage and sinusoidal frequency, electrical energy is transferred from the coil 620 to the internal phasing coils 651 by magnetic induction. To this end, the coil 620 acts as a type of primary coil for inductive power transfer and the single internal phasing coil 654 acts as a type of secondary coil. To the extent that the internal phasing coils 651 together are considered a single internal phasing coil 654, then the single internal phasing coil 654 acts as the secondary. To facilitate magnetic induction between them, the coil 620 can be positioned and supported by the coil support stand 622 (FIG. 25) or another suitable structure below, within, or above the circular opening through the base plate 621. Further, in various cases, the coil 620 can be positioned below, within, wholly overlapping outside, or partially overlapping outside one of the internal phasing coils 651. If the coil 620 is outside of the internal phasing coils 651, then the coil 620 may wholly or partially overlap a respective one of the internal phasing coils 651. According to one embodiment, the coil 620 is positioned below, within, or outside a bottom most one of the internal phasing coils 651 to facilitate a maximum charge on the charge terminal 520 as described above.

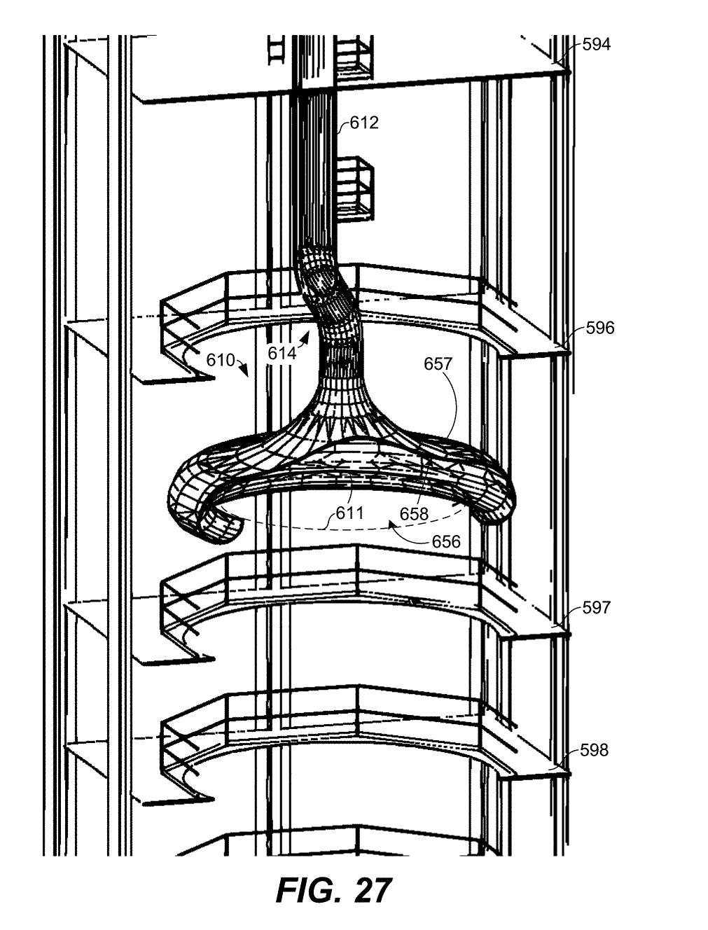

To more clearly illustrate the corona hood 610, FIG. 27 is an enlarged portion of the cross-sectional view A-A designated in FIG. 20. The shape and size of the corona hood 610 is provided as an example in FIG. 27, as other shapes and sizes are within the scope of the embodiments. As described in further detail below with reference to FIG. 27, the corona hood 610 can be positioned above and to cover at least a portion of the top most internal phasing coil 651 (FIG. 26) in the guided surface waveguide probe 500. One could also say that the corona hood 610 is positioned above and covers at least an end or top winding of the single internal phasing coil 654 (FIG. 26). Depending upon the number and position of internal phasing coils 651 installed in the guided surface waveguide probe 500, the position of the corona hood 610 may be adjusted. Generally, the corona hood 610 can be positioned and secured at any of the platforms 594-604 of the truss frame 531. However, the position of the corona hood 610 generally needs to be at a sufficient height so as not to create an unacceptable amount of bound capacitance in accordance with the discussion above. If necessary, sections of the tube 612 can be installed (or removed) to adjust the position of the corona hood 610 to one of the platforms 594-604.

The corona hood 610 is designed to minimize or reduce atmospheric discharge around the conductors of the end windings of the top-most internal phasing coil 651. To this end, atmospheric discharge may occur as Trichel pulses, corona, and/or a Townsend discharge. The Townsend discharge may also be called avalanche discharge. All of these different types of atmospheric discharges represent wasted energy in that electrical energy flows into the atmosphere around the electrical component causing the discharge to no effect. As the voltage on a conductor is continually raised from low voltage potential to high voltage potential, atmospheric discharge may manifest itself first as Trichel pulses, then as corona, and finally as a Townsend discharge. Corona discharge in particular essentially occurs when current flows from a conductor node at high potential, into a neutral fluid such as air, ionizing the fluid and creating a region of plasma. Corona discharge and Townsend discharges often form at sharp corners, points, and edges of metal surfaces. Thus, to reduce the formation of atmospheric discharges from the corona hood 610, the corona hood 610 is designed to be relatively free from sharp corners, points, edges, etc.

To this end, the corona hood 610 terminates along an edge 611 that curves around in a smooth arc and ultimately is pointed toward the underside of the corona hood 610. The corona hood 610 is an inverted bowl-like structure having a recessed interior that forms a hollow 656 in the underside of the corona hood 610. An outer surface 657 of the bowl-like structure curves around in the smooth arc mentioned above such that the edge of the bowl-like structure is pointed toward the recessed interior surface 658 of the hollow 656.

During operation of the guided surface waveguide probe 500, the charge density on the outer surface 657 of the corona hood 610 is relatively high as compared to the charge density on the recessed interior surface 658 of the corona hood 610. As a consequence, the electric field experienced within the hollow 656 bounded by the recessed interior surface 658 of the corona hood 610 will be relatively small as compared to the electric field experienced near the outer surface 657 of the corona hood 610. According to the various embodiments, the end most windings of the top-most internal phasing coil 651 are recessed into the hollow 656 bounded by the recessed interior surface 658 of the corona hood 610. Given that the electric fields in the hollow 656 are relatively low, atmospheric discharge is prevented or at least minimized from conductors recessed into the hollow 656. Specifically, in this arrangement, atmospheric discharge is prevented or minimized from the end most windings of the top-most internal phasing coil 651 that are recessed into the hollow 656. Also, atmospheric discharge is prevented from forming or minimized from the lead that extends from the end most winding of the top-most internal phasing coil 651 to an attachment point on the recessed interior surface 658 of the corona hood 610. Thus, by positioning the corona hood 610 such that the top winding(s) of the highest most internal phasing coil 651 is recessed into the hollow 656 having lower electric fields, atmospheric discharge is prevented from forming or is minimized around the top winding and the lead extending from the top winding which experience the highest electrical potential of the entire system.

The corona hood 610 terminates by tapering into a tube 612 that extends from the corona hood 610 to the charge terminal 520. The tube 612 acts as a conductor between the corona hood 610 and the charge terminal 520 and includes one or more bends or turns 614 from the corona hood 610 to the charge terminal 520. In the case of the guided surface waveguide probe 500, the turn 614 is relied upon to shift the tube 612 to an off-center position within the platforms 591-593, among others, in the truss extension 532. In that way, space can be reserved on the platforms 591-593 for individuals to stand and service the guided surface waveguide probe 500. The tube 612 may include a pivot junction above the turn 614 that would allow the tube 612 to be swung out of position over the corona hood 610 to leave an open hole in the tube 612 or the tapered portion of the corona hood 610 just above the corona hood 610. This is done to allow a cable to pass through the center of the corona hood 610 to facilitate lifting coil sections into place as described herein. Alternatively, a portion of the tube 612 may be removable at the first bend of the turn 614 to allow a cable to pass through the center of the corona hood 619.

Given that the corona hood 610 and the tube 612 are formed from a conductive material, the highest-installed internal coil 651 can be electrically coupled to the corona hood 610 by connecting the top most winding to the corona hood 610 at a point on the recessed interior surface 658 of the corona hood 610 to prevent atmospheric discharge from occurring around the connection point as well as the lead extending from the top most winding to the connection point on the recessed interior surface 658 of the corona hood 610. Alternatively, if such atmospheric discharge is not prevented entirely, then it is at least minimized in order to minimize unwanted losses. In that case, the conductor can be electrically coupled to the recessed interior surface 658 of the corona hood 610 at a point where the corona hood 610 tapers into the tube 612, for example, or at any other suitable location.

FIG. 28 is a cross-sectional view of the charge terminal 520 of the guided surface waveguide probe 500 shown in FIG. 20. The charge terminal 520 is positioned at the top of the guided surface waveguide probe 500 above the truss extension 532. Individuals can access the interior space within the charge terminal 520 using ladders 660 and 661, among others, to reach the top platform 670 of the truss extension 532. The top platform 670 includes an opening 671 through which a winch line can pass. As described in further detail below with reference to FIGS. 29A and 29B, a winch can be used to raise one or more of the internal phasing coils 651 into place, so that they can be secured at one or more of the platforms 598-604 (FIG. 25).

The charge terminal 520 can be formed from any suitable conductive metal or metals, or other conductive materials, to serve as a charge reservoir for the guided surface waveguide probe 500. As shown, the charge terminal 520 includes a hollow hemisphere portion 680 at the top that transitions into a hollow toroid portion 681 at the bottom. The hollow toroid portion 681 turns to the inside of the charge terminal 520 and ends at an annular ring lip 682.

For an electrical connection to the internal phasing coils 651, the tube 612 can extend further up toward the top of the charge terminal 520. As shown in the inset in FIG. 28, one or more coupling conductors 690, formed from a conductive material, can extend radially away from the top of the tube 612. The coupling conductors 690 can be mechanically and electrically coupled to any point on the inner surface of the charge terminal 520. For example, the coupling conductors 690 can be electrically and mechanically connected to points around the annular ring lip 682. Alternatively, the coupling conductors 690 can be mechanically and electrically coupled to points on the inside surface of the hollow toroid portion 681 or the hollow hemisphere portion 680. The charge terminal 520 is generally attached to and supported by the truss extension 532 as described below with reference to FIGS. 29A and 29B.

FIGS. 29A and 29B illustrate top and bottom perspective views, respectively, of a top support platform 700 of the guided surface waveguide probe 500 shown in FIG. 20 according to various embodiments of the present disclosure. In the example of the guided surface waveguide probe 500 described and illustrated herein, the charge terminal 520 shown in FIG. 28 can surround the top support platform 700.

The top support platform 700 is supported at the top of the truss extension 532 of the guided surface waveguide probe 500. Similar to the bars 581-583 referenced in FIG. 24, the truss extension 532 includes a number of vertical support bars 710, horizontal support bars 711, and cross beam support bars 712. The truss extension 532 also includes a number of gusset plates 713 to secure the vertical support bars 710, horizontal support bars 711, and cross beam support bars 712 together.

Secured at the top of the truss extension 532, the top support platform 700 includes a mounting ring 720 as shown in FIG. 29B. In one embodiment, the annular ring lip 682 of the charge terminal 520 can be secured to the mounting ring 720 using bolts or other suitable hardware. In that way, the charge terminal 520 can be mounted to the top support platform 700, which is secured to the truss extension 532.

The top support platform 700 includes an arrangement of platform joists 730 and a railing 731. The top platform 670 (FIG. 28) can be seated upon and secured to the platform joists 730. The top support platform 700 also includes a winch 740. The winch 740 can be used to install, reconfigure, and maintain various components of the guided surface waveguide probe 500. For example, a winch line of the winch 740 can be routed through the top support platform 700, through the opening 671 (FIG. 28) in the top platform 670, and down into the truss extension 532 and the truss frame 531. The winch line can be lowered down toward and into the passageway 655 (FIG. 26) in the substructure 502 (FIG. 26). From there, the winch line can be secured to one of the internal phasing coils 651 (FIG. 27), and the internal phasing coil 651 can be lifted up into the truss frame 531 and secured. Given that the winch 740 is located inside the charge terminal 520, the winch 740 is located in the region of uniform electric potential and is safe from discharge, eddy currents, or interference. In order to power the winch 740, an electrical cord may be brought up to the winch 740 from a power source such as utility power when the guided surface waveguide probe 500 is not operational. During operation, however, such an electrical cord would be removed.

The components of the top support platform 700, including the vertical support bars 710, horizontal support bars 711, cross beam support bars 712, gusset plates 713, platform joists 730, railing 731, etc. may be formed (entirely or substantially) from non-conductive materials. Alternatively, the same may be formed from conductive materials since they are located in a region of uniform electrical potential. In any event, such components may be constructed from lightweight materials such as aluminum or titanium so as to reduce the physical load on the entire structure of the guided surface waveguide probe 500.

FIGS. 30 and 31 illustrate various components inside the substructure 502 of the guided surface waveguide probe 500 shown in FIG. 20 according to various embodiments of the present disclosure. The arrangement of the rooms, compartments, sections, stairwells, etc., in the substructure 502 is provided as a representative example in FIGS. 30 and 31. In other embodiments, the space within the substructure 502 can be configured for use in any suitable way, and the equipment described below can be installed in various locations.

The substructure 502 includes external walls 800 and internal walls 801. According to one embodiment, the external walls 800 and internal walls 801 are formed from poured concrete and, in some cases, reinforced with fiberglass rebar as will be described. For safety, the internal walls 801 can be designed at a suitable thickness and/or structural integrity to withstand or retard the spread of fire, coronal discharge, etc. Various entryways and passages through the internal walls 801 permit individuals and equipment to move throughout the substructure 502. The entryways and passages can be sealed using any suitable types of doors, including standard doors, sliding doors, overhead doors, etc. As also shown, a pathway 802 is reserved through various areas in the substructure 502 for individuals to walk around and install, service, and move the equipment in the substructure 502, as necessary.

A number of the pillars 810, not all of which are individually referenced in FIG. 30, support the covering support slab 510 (FIG. 20) of the guided surface waveguide probe 500. The pillars 810 can be formed from reinforced concrete or other suitable materials as will be described. A central group of the pillars 810 are positioned under each of the base brackets 565 to support the truss frame 531 and the rest of the structure.

Stairwells 820 and 821 are provided at opposite corners of the substructure 502. The stairwells 820 and 821 lead up to the entryways 511 and 512 (FIG. 20). The stairwell 820 is surrounded by a stairwell enclosure 822, but stairwell enclosures are not necessary in every case. For example, the stairwell 821 is not shown as being enclosed in FIG. 30. The enclosure around each stairwell 820 and 821 provides for safety in case of fire or other calamity. Also, the stairwell enclosure 822 prevents or retards the entry of water into the substructure 502.

The substructure 502 includes a number of different rooms, compartments, or sections separated by the internal walls 801. Various types of equipment is installed in the rooms or compartments of the substructure 502. Among other types of equipment and systems, a power transmitter banks 630 and 631, a motor controller 830, a number of transformers 831, and an HVAC system 832 can be installed in the substructure 502 as shown in FIG. 30. Further, as shown in FIG. 31, a supervisory control and data acquisition (SCADA) system 840, an arc flash detection system 841, and a fire protection system 842 can be installed in the substructure 502. Additionally, although not referenced in FIGS. 30 and 31, an electrical switching gear can be installed in the substructure 502 to receive power over one or more power transmission cables 850 and connect the power to the transformers 831 and, in turn, other equipment in the substructure 502.

In one embodiment, the power transmitter bank 630 can be embodied as a number of variable power, variable frequency, power transmitters capable of outputting power over a range of sinusoidal output frequencies, such as up to a megawatt of power, for example, over a range of frequencies from about 6 kHz-100 kHz. However, the power transmitter bank 630 can provide output power at lower and higher wattages and at lower and higher frequencies in various embodiments. The power transmitter banks 630 and 631 are examples of various power sources that may be used such as, for example, generators and other power sources. The power transmitter bank 630 includes a control cabinet 632, a combiner 633, and a number of power transmitters 634. Each of the power transmitters 634 can include a number of power amplifier boards, and the outputs of the power transmitters 634 can be tied or combined together in the combiner 633 before being fed to the coil 620 (FIG. 25) of the guided surface waveguide probe 500, for example. The second power transmitter bank 631 is similar in form and function as the power transmitter bank 630.

Depending upon the operating configuration of the guided surface waveguide probe 500, the output of the power transmitter banks 630 and 631 can be electrically coupled to the coil 620 within the substructure 502, where the coil 620 acts as a primary coil to inductively couple electrical energy into the internal phasing coils 651. Alternatively, the output of the power transmitter banks 630 and 631 may be coupled to coils acting as primaries that are positioned around the external phasing coils 504 and 505, or the inductive coil 263/942 (FIG. 7C/FIGS. 33A and B) as described herein. Thus, electrical energy may be applied to the guided surface waveguide probe 500 by way of inductive coupling from a coil acting as a primary to any one of the internal phasing coils 651, the external phasing coils 504/505, or inductive coils 263/942.

In one embodiment, power can be fed from the power transmission cables 850 at a voltage level for power transmission at 138 kV (or higher), at the voltage level for sub-transmission at 26 kV or 69 kV, at the voltage level for primary customers at 13 kV or 4 kV, at the voltage level for internal customers at 120V, 240V, or 480V, or at another suitable voltage level.

The power can be fed through electrical switch gear and to the transformers 831. The electrical switch gear can include a number of relays, breakers, switchgears, etc., to control (e.g., connect and disconnect) the connection of power from the cables 850 to the equipment inside the substructure 502. The power can be fed from the transformers 831, at a stepped-up or stepped-down voltage, to the power transmitter banks 630 and 631. Alternatively, the power transmitter banks 630 and 631 can be supplied directly with power at a suitable voltage, such as 480V or 4160V, for example, from the cables 850.

The motor controller 830 can control a number of forced air and water heating and/or cooling subsystems in the substructure 502, among other subsystems. To this end, various ducts and piping are employed to route cooling air and water to various locations and components of the guided surface waveguide probe 500 to prevent damage to the system and structure due to heat. The SCADA system 840 can be relied upon to monitor and control equipment in the guided surface waveguide probe 500, such as the power transmitter banks 630 and 631, motor controller 830, transformers 831, HVAC system 832, arc flash detection system 841, and fire protection system 842, among others.

In one embodiment, the entire substructure 502 including the foundation base 540, seal slab 541, external walls 800, internal walls 801, pillars 810, and the covering support slab 510 (FIG. 20) is formed using poured concrete reinforced with Glass Fiber Reinforced Polymer (GFRP) rebar. The concrete used may include an additive that reduces the amount of moisture in the cement to reduce the conductivity of the cement to prevent eddy currents and the like in the cement itself. In one embodiment, such an additive may comprise XYPEX™ manufactured by Xypex Chemical Corporation of Richmond, British Columbia, Canada, or other appropriate additive. The GFRP rebar ensures that there are no conductive pathways in the cement upon which eddy currents might be produced.

FIGS. 32A and 32B illustrate the grounding system 900 of the guided surface waveguide probe 500 shown in FIG. 20. The grounding system 900 includes a grounding grid 910, the grounding ring 551, connecting conductors 552, a number of grounding radials 553, and a number of ground stakes 920. The grounding system 900 is shown as a representative example in FIGS. 32A and 32B and can differ in size, shape, and configuration in other embodiments. The grounding system 900 can be formed from conductive materials and provides an electrical connection to the lossy conducting medium 503 (e.g., the Earth) for the guided surface waveguide probe 500 and the equipment in the substructure 502.

In one embodiment, the grounding grid 910 is surrounded in the seal slab 541 of the foundation base 540 (FIG. 21). The grounding system 900 also includes a number of grounding stakes 920 driven into the lossy conducting medium 503 below the grounding grid 910 and electrically coupled to the grounding grid 910.

The connecting conductors 552 extend from the grounding grid 910 to the grounding ring 551. The grounding radials 553 are electrically coupled at one end to the grounding ring 551 and extend out from the grounding ring 551 radially away from the guided surface waveguide probe 500 to a number of grounding stakes 920 driven into the lossy conducting medium 503. The grounding ring 551 includes an opening or break 930 to prevent circulating current in the grounding ring 551 itself. Together all of the grounding components of the grounding system 900 provide a pathway for current generated by the guided surface waveguide probe 500 to the lossy conducting medium 503 around the guided surface waveguide probe 500.

FIG. 33A illustrates an example tank circuit 940a of the guided surface waveguide probe 500 according to various embodiments of the present disclosure. The tank circuit 940a includes an inductive coil 942, a number of parallel capacitors 944A-944D, and a number of switches 946A-946D corresponding to the parallel capacitors 944A-944D. With reference to the tank circuit 260 shown in FIGS. 7B and 7C, the inductive coil 942 is analogous to the inductive coil 263 and the parallel capacitors 944A-944D are analogous to the capacitor 266. Note that although only a limited number of capacitors are shown, it is understood that any number of capacitors may be employed and switched into the tank circuit 940a as conditions demand.

The tank circuit 940a can be electrically coupled at one end as shown in FIG. 33A to one or more phasing coils, such as the single internal phasing coil 654, the external phasing coils 504 and/or 505, and/or other phasing coils. The tank circuit 940a can be electrically coupled at another end as shown in FIG. 33A to a grounding system, such as the grounding system 900 shown in FIGS. 32A and 32B.

The capacitors 944A-944D can be embodied as any suitable type of capacitor and each can store the same or different amounts of charge in various embodiments, for flexibility. Any of the capacitors 944A-944D can be electrically coupled into the tank circuit 940a by closing corresponding ones of the switches 946A-946D. Similarly, any of the capacitors 944A-944D can be electrically isolated from the tank circuit 940a by opening corresponding ones of the switches 946A-946D. Thus, the capacitors 944A-944D and the switches 946A-946D can be considered a type of variable capacitor with a variable capacitance depending upon which of the switches 946A-946D are open (and closed). Thus, the equivalent parallel capacitance of the parallel capacitors 944A-944D will depend upon the state of the switches 946A-946D, thereby effectively forming a variable capacitor.

The inductive coil 942 can be embodied as a length of conductor, such as wire or pipe, for example, wrapped and supported around a coil support structure. The coil support structure may comprise a cylindrical body or other support structure to which the wire or pipe is attached in the form of a coil. In some cases, the connection from the inductive coil 942 to the grounding system 900 can be adjusted using one or more taps 943 of the inductive coil 942 as shown in FIG. 7A. Such a tap 943 may comprise, for example, a roller or other structure to facilitate easy adjustment. Alternatively, multiple taps 943 may be employed to vary the size of the inductive coil 942, where one of the taps 943 is connected to the capacitors 944.

As described herein, a phasing coil such as the single internal phasing coil 654 and the external phasing coils 504 and 505 can provide both phase delay and phase shift. Further, the tank circuit 940a that includes the inductive coil 942 can provide a phase shift without a phase delay. In this sense, the inductive coil 942 comprises a lumped element assumed to have a uniformly distributed current throughout. In this respect, the inductive coil 942 is electrically small enough relative to the wavelength of transmission of the guided surface waveguide probe 500 such that any delay it introduces is relatively negligible. That is to say, the inductive coil 942 acts as a lumped element as part of the tank circuit 940a that provides an appreciable phase shift, without a phase delay.

FIG. 33B illustrates another example tank circuit 940b of the guided surface waveguide probe 500 according to various embodiments of the present disclosure. As compared to the tank circuit 940a shown in FIG. 33A, the tank circuit 940b includes a variable capacitor 950 in place of the capacitors 944A-944D and switches 946A-946D. With reference to the tank circuit 260 shown in FIGS. 7B and 7C, the inductive coil 942 is analogous to the inductive coil 263 and the variable capacitor 950 is analogous to the capacitor 266.

As shown, the variable capacitor 950 can be buried or embedded into the lossy conducting medium 503, such as the Earth. The variable capacitor 950 includes a pair of cylindrical, parallel charge conductors 952, 954 and an actuator 960. The actuator 960, which can be embodied as a hydraulic actuator that actuates a hydraulic piston. Alternatively, the actuator 960 may be embodied as an electric actuator that employs a motor or other electrical component that drives a screw shaft or other mechanical lifting structure. Further, the actuator 960 may be embodied as a pneumatic actuator that is employed to raise or lower a pneumatic cylinder. Still other types of actuators may be employed to move the inner charge conductor 952 relative to the outer charge conductor 954, or vice versa, or both. Also, some other type of actuator may be employed beyond those described herein.

The actuator 960 is configured to raise and lower the inner charge conductor 952 within, or relative to, the outer charge conductor 954. By raising and lowering the inner charge plate 952 with respect to the outer charge plate 954, the capacitance of the variable capacitor 950 can be modified and, thus, the electrical characteristics of the tank circuit 940b adjusted.

While the variable capacitor 950 is shown as being buried in the lossy conducting medium 503, it is understood that the variable capacitor 950 may also reside in a building or a substructure such as the substructure 502. Also, while the variable capacitor 950 is depicted as being cylindrical in shape, it is possible to use any shape such as rectangular, polygonal, or other shape.

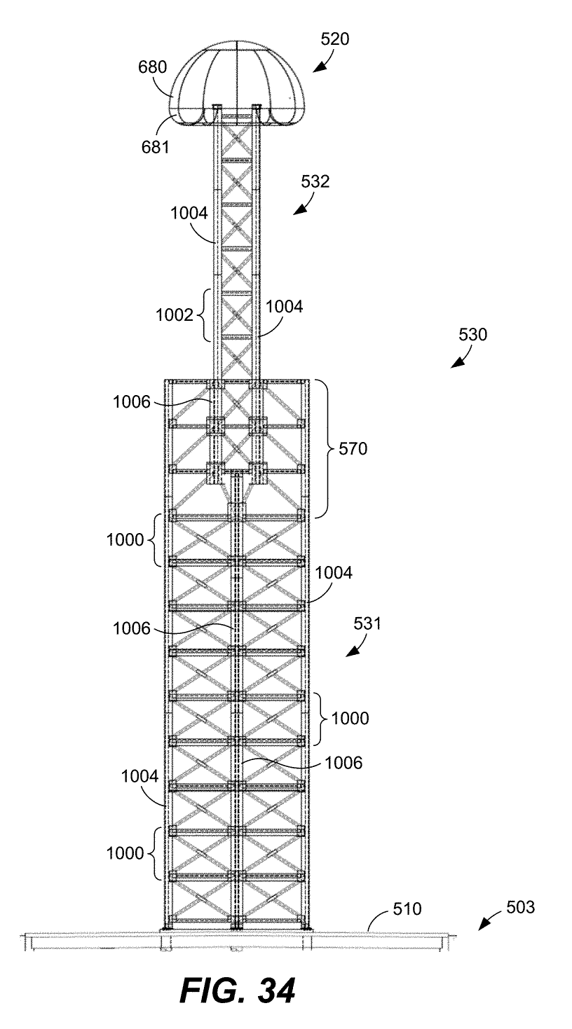

As described above, the charge terminal 520 of the guided surface waveguide probe 500 is supported above a lossy conducting medium, such as the earth, by a support structure 530. An example embodiment of this support structure 530 is illustrated in FIGS. 34-52, which are described below. In these figures, the support structure 530 is shown by itself without the various other components of the guided surface waveguide probe 500 being illustrated.

Beginning with FIG. 34, the support structure 530 is shown in side view extending upward from a support slab 510 formed on a lossy conducting medium 503, such as the earth. As identified above, the support structure 530 generally comprises a truss frame 531, a charge terminal truss extension 532, and a transitional truss region 570 within which the truss extension is connected to the truss frame. As can be appreciated from FIG. 34, the support structure 530 takes the form of an elongated tower (or tower structure) in which the truss frame 531 is the lower portion of the tower, the truss extension 532 is the upper portion of the tower, and the transitional truss region 570 is a medial zone of the tower in which the lower and upper portions of the tower overlap. The truss frame 531 can be said to comprise twelve vertical sections, the top three of these sections forming the transitional truss region 570. The truss extension 532 comprises eight vertical sections 1002, the bottom two of these sections being positioned within and overlapping with the top two vertical sections 1000 of the truss frame 531.

With further reference to FIG. 34, the truss frame 531 is relatively wide as compared to the truss extension 532. By way of example, the truss frame 531 can be approximately 32 feet×32 feet in cross-section while the truss extension 532 can be approximately 10 feet×10 feet in cross-section. By further way of example, the truss fame 531 can be approximately 120 feet tall, the truss extension 532 can be approximately 80 feet tall, and the transitional truss region 570 can be approximately 30 feet tall or long. These dimensions are just examples, however, and other dimensions can be used depending upon the particular application.

As mentioned above, the support structure 530 is comprised by various components, including various elongated structural members (alternatively referred to above as pillars, beams, or bars), gusset plates, and fasteners. As was also mentioned above, each of these components is made of a non-conductive material such that no component of the support structure 530 below the bottom edge of the toroid portion 681 of the charge terminal 520 is electrically conductive. In some embodiments, each of the structural members, gusset plates, and fasteners is made of a pultruded fiber reinforced polymer (FRP) composite material, such as fiberglass.

Because the support structure 530 is tall (e.g., over 100 feet tall) and must withstand potentially strong wind forces and further because the FRP composite material is not as strong as other more conventional building materials, such as steel, which are typically used to construct towers of similar size, the support structure has a unique configuration. As described below, the support structure 530 is specifically designed such that the great majority of the fasteners of the structure are not subjected to tensile forces. Instead, the forces transmitted to the fasteners are only shear forces. This takes advantage of the fact that FRP fasteners are much stronger in shear than in tension.

The goal of limiting or eliminating the transmission of tensile force to the fasteners is in part achieved through the design of the individual components of the support structure 530. Two of these components are elongated structural members in the form of corner columns 1004 and intermediate columns 1006 that vertically extend along the lengths of the truss frame 531 and the truss extension 532. As is apparent from FIG. 34, the corner columns 1004 are positioned at each corner of the truss frame 531 and each corner of the truss extension 532, and the intermediate columns 1006 are positioned at intermediate points between adjacent corners of the truss frame. Given that, in the illustrated embodiment, both the truss frame 531 and the truss extension 532 are rectangular (e.g., square) in cross-section, at any given point along the lengths of the truss frame and the truss extension there are four corner columns 1004. In the case of the truss frame 531, there are also four intermediate columns 1106 at any given point along the length of the truss frame, except in the transitional truss region 570 at which pairs of intermediate columns are positioned between adjacent corner columns. Together, the corner columns 1004 and the intermediate columns 1006 define the general shape of the support structure 530. In some embodiments, the columns 1004, 1006 are arranged end-to-end along the lengths of the truss frame 531 and the truss extension 532.

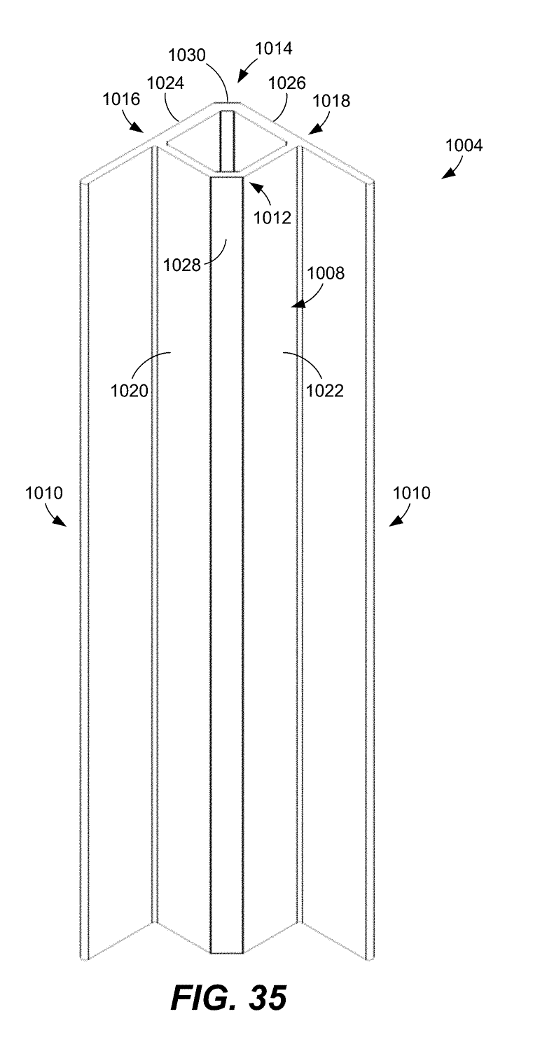

FIG. 35 shows an example configuration for the corner columns 1004 in detail. The corner columns 1004 generally comprise an elongated, central tubular member 1008 from which laterally extend two elongated flanges 1010, which also extend along the entire length of the tubular member. The tubular member 1008 provides the structural strength to the corner column 1004 while, as described below, the flanges 1010 facilitate connection of other structural members to the column. The entire corner column 1004, including the tubular member 1008 and the flanges 1010, is unitarily formed from a single piece of non-conductive material, such as an FRP composite material.

As can be appreciated from FIG. 35, the tubular member 1008 is generally rectangular (e.g., square) in cross-section and therefore comprises four corners and four orthogonally arranged sides. The corners comprise an inner corner 1012 that faces inward toward the center of the support structure 530, an outer corner 1014 that faces outward away from the center of the support structure, and two opposed lateral corners 1016 and 1018 that are located between the inner and outer corners. The sides include two inner sides 1020 and 1022 that face inward toward the center of the support structure 530 and two outer sides 1024 and 1026 that face outward away from the center of the support structure. Together, these sides 1020-1026 define an elongated inner channel of the tubular member. As shown in FIG. 35, both the inner corner 1012 and the outer corner 1014 of the tubular member 1008 are chamfered so as to form two opposed, parallel planar outer surfaces 1028 and 1030 that are orthogonal to the sides 1020-1026 of the tubular member. As described below, other components of the support structure 530 can be attached to the planar outer surfaces 1028, 1030 with diagonal fasteners that pass through the center of the tubular member.

The flanges 1010 extend from the lateral corners 1016, 1018 of the tubular member 1008 in a manner in which one flange generally lies in the same plane as one outer side 1024 and the other flange 1010 generally lies in the same plane as the other outer side 1026. With this configuration, the flanges 1010 are generally orthogonal to each other, just as the outer sides 1024, 1026 are generally orthogonal to each other. As is apparent from FIG. 35, the outer surfaces of the outer sides 1024, 1026 are located in the same plane as and are continuous with the outer surfaces of their respective flanges 1010. The outer surfaces of the flanges 1010 are planar and are parallel to opposed, planar inner surfaces of the flanges. In some embodiments, each flange 1010 is approximately wide as its associated outer side 1024, 1026.

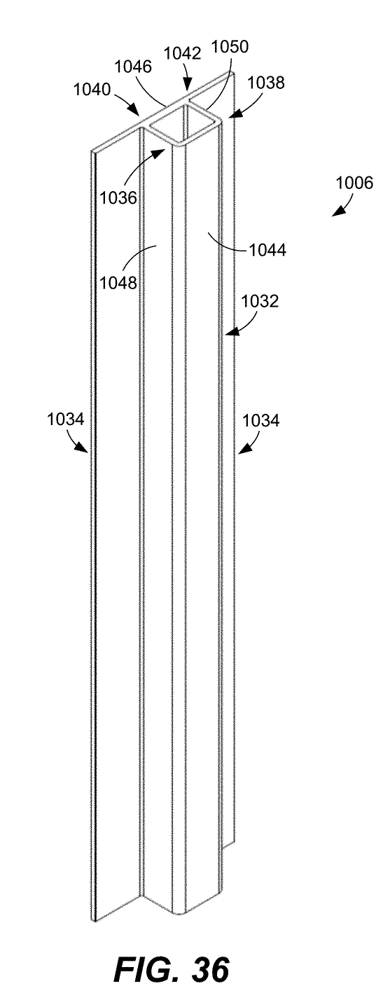

FIG. 36 shows an example configuration for the intermediate columns 1006. The intermediate columns 1006 also comprise an elongated, central tubular member 1032 from which laterally extend two elongated flanges 1034, which also extend along the entire length of the tubular member. As with the corner column 1004, the tubular member 1032 provides the structural strength to the column while, as described below, the flanges 1034 facilitate connection of other structural members to the column. The entire intermediate column 1006, including the tubular member 1032 and the flanges 1034, is unitarily formed from a single piece of non-conductive material, such as an FRP composite material.

As can be appreciated from FIG. 36, the tubular member 1032 is generally rectangular in cross-section and therefore comprises four corners and four orthogonally arranged sides. The corners comprise two inner corners 1036 and 1038 that are positioned on an inner side of the intermediate column 1006 and two outer corners 1040 and 1042 that are positioned on an outer side of the intermediate column. The sides include an inner side 1044 that faces inward toward the center of the support structure 530, an outer side 1046 that faces outward away from the center of the support structure, and two lateral sides 1048 and 1050 that are located between the inner and outer sides. Together, these sides 1044-1050 define an elongated inner channel of the tubular member.

The flanges 1034 extend from the outer corners 1040, 1042 associated with the outer side 1046 of the tubular member 1032 in a manner in which both flanges generally lie in the same plane the outer side. As is apparent from FIG. 36, the outer surface of the outer side 1046 is located in the same plane as and is continuous with the outer surfaces of flanges 1034. Accordingly, the flanges 1034 both lie in the same plane. The outer surfaces of the flanges 1034 are planar and are parallel to opposed, planar inner surfaces of the flanges. In some embodiments, each flange 1034 is generally as wide as the outer side 1046.

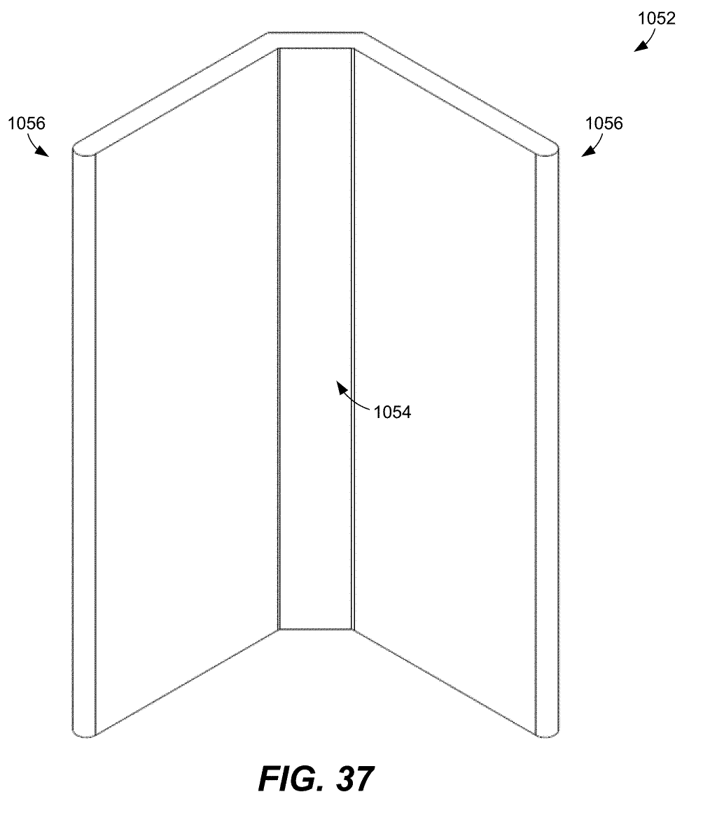

FIG. 37 illustrates another component that is repeatedly used in the construction of the support structure 530. In particular, FIG. 37 illustrates a corner angle member 1052 that is used to connect framing members to the corner columns 1004. As shown in the figure, the corner angle member 1052 generally comprises three planar elements, including a central element 1054 and two angled flanges 1056. Each of the central element 1054 and the flanges 1056 is made of a non-conductive material, such as an FRP composite material.

As shown in FIG. 37, the central element 1054 is relatively narrow as compared to the lateral flanges 1056. In some embodiments, the angled flanges 1056 are approximately three times as wide as the central element 1054. The angled flanges 1056 extend outwardly from the lateral edges of the central element 1054 at an angle of approximately 45 degrees. Given that the angled flanges 1056 extend outward from the same side of the central element 1054 but in different directions, the flanges are generally orthogonal to each other.

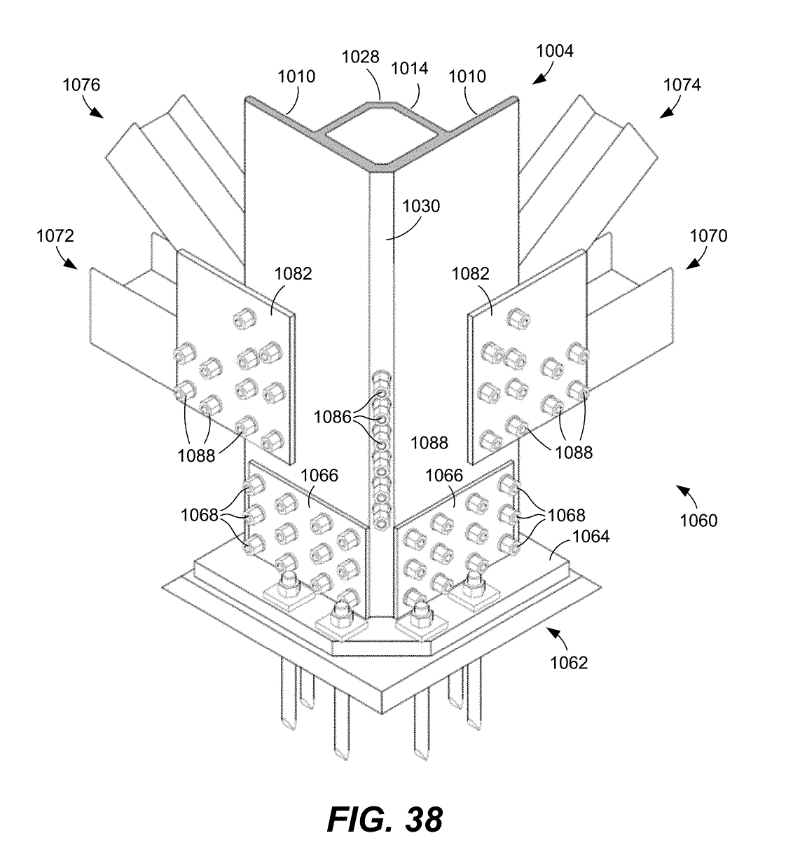

In addition to the design of the individual components of the support structure 530, the goal of limiting or eliminating the transmission of tensile force to the fasteners used in the structure is also in part achieved because of the configuration of the various junctions of the structure at which the multiple structural members are connected together. FIGS. 38-52 illustrate multiple examples of these junctions. Although there are many different configurations of junctions used in the construction of the support structure 530, each uses the same principles to avoid transmission of tensile forces to the fasteners. In the interest of brevity, not every junction of the support structure 530 is illustrated and described.

FIGS. 38-40 show an embodiment of a first junction 1060 used in the support structure 530. This type of junction is used at each corner of the bottom of the truss frame 531. At this junction 1060, multiple elongated structural members, in the form of framing members, connect to a corner column 1004, which is mounted to the support slab 510 with an anchorage assembly 1062. The anchorage assembly 1062 includes horizontal platform 1064 that is bolted to the support slab 510 and multiple vertical plates 1066 that extend upwardly from the platform and are bolted to the corner column 1004 with multiple threaded fasteners 1068. Unlike the components of the support structure 530, the components of the anchorage assembly 1062 can be made of a metal material, such as stainless steel, as greater strength is needed to anchor the structure than to construct it.

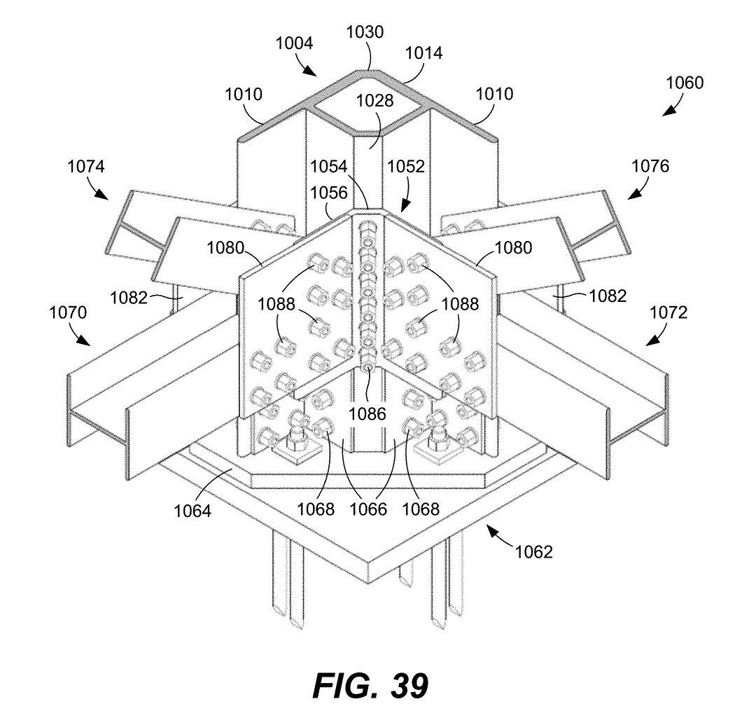

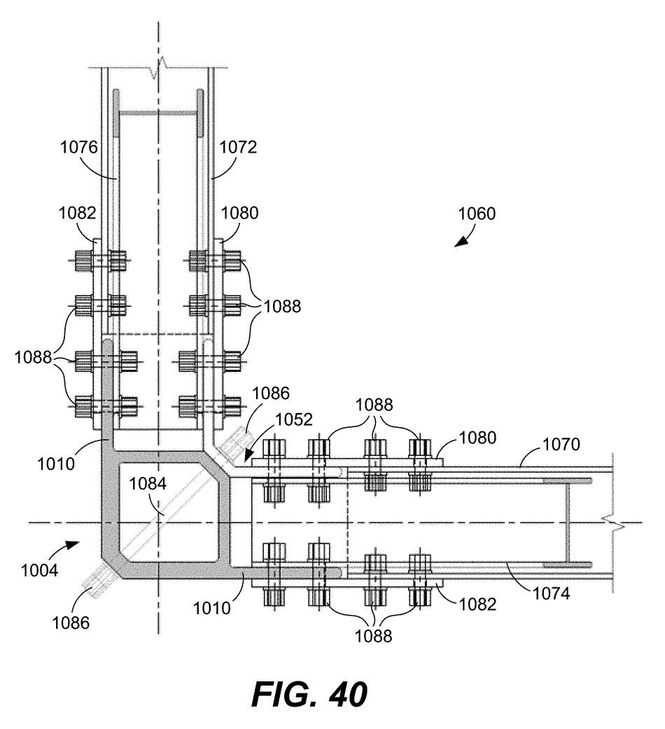

As is most clearly apparent from FIG. 39, the framing members connected to the corner column 1004 include two horizontal framing members 1070 and 1072 and two diagonal framing members 1074 and 1076. Each of these framing members 1070-1076 is made of a non-conductive material, such as an FRP composite material, and is configured as an H-beam having two parallel flanges that are joined by a perpendicularly oriented central web. As is most clearly shown in FIG. 40, the horizontal framing members 1070, 1072 are slightly wider than the diagonal framing members 1074, 1076 to facilitate their connection to the corner column 1004. Unlike as in conventional tower structures, the framing members 1070-1076, as well as the majority of other framing members of the support structure 530, are configured such that their webs are generally horizontal and their flanges are generally vertical. This configuration prevents inward or outward buckling of the framing members, which are stronger in the horizontal direction as compared to the vertical direction.

The framing members 1070-1076 connect to the corner column 1004 using the flanges 1010 of the column, a corner angle member 1052, inner and outer gusset plates 1080 and 1082, and multiple fasteners 1088. Like the other components of the support structure 530, the gusset plates 1080, 1082, and the fasteners 1088 are made of a non-conductive material, such as an FRP composite material. As shown most clearly in FIGS. 39 and 40, the central element 1054 of the corner angle member 1052 is secured to the inner planar outer surface 1028 of the corner column 1004 with bolts 1084 that diagonally pass through the column and multiple nuts 1086 that are threaded onto both ends of the bolts. The bolts 1084 and nuts 1086 are also made of a non-conductive material, such as an FRP composite material.

The inner gusset plates 1080 are mounted to the inner sides of the angled flanges 1056 of the corner angle member 1052 with threaded fasteners 1088 and the outer gusset plates 1082 are mounted to the outer sides of the flanges 1010 of the corner column 1004 with further threaded fasteners 1088. These threaded fasteners 1088 can comprise nuts and bolts, which can be made of a non-conductive material, such as an FRP composite material. The flanges of the horizontal framing members 1070, 1072 are connected to the inner sides of the gusset plates 1080, 1082 with further fasteners 1088. One flange of each of the diagonal framing members 1074, 1076 is connected to the inner side of a flange 1010 of the corner column 1004 with threaded fasteners 1088, and the other flange of each diagonal framing member is connected to the outer side of one of the angled flanges 1056 of the corner angle member 1052 with further threaded fasteners.

From the above discussion, it can be appreciated that the junction 1060 has a layered configuration in which multiple components, such as flanges, and gusset plates are layered on top of each other. An example of this layering is the “stack” comprised of the inner gusset plates 1080, the angled flanges 1056 of the corner angle member 1052, and the flanges of the diagonal framing members 1074, 1076. Another example is the stack comprised of the outer gusset plates 1082, the flanges 1010 of the corner column 1004, and the flanges of the horizontal framing members 1070, 1072. In both cases, multiple planar elements are layered together in a manner in which multiple interfaces of mating planar surfaces are formed. This layering or stacking increases the strength of the junction 1060. In some embodiments, adhesive, such as an epoxy or urethane adhesive, is applied between each pair of mating planar surfaces prior to fixation using the threaded fasteners 1088 to further increase this strength. Although the support structure 530 is designed to have sufficient strength without the use of such adhesive, adhesive may be desirable as it increases the stiffness of the structure and, therefore, its resistance to wind forces. In some embodiments, adhesive can also be provided on the threaded fasteners 1088 and/or nuts 1086 to further increase strength.

As noted above, the junctions of the support structure 530 are configured such that the threaded fasteners experience shear forces instead of tensile forces. This is achieved by ensuring that the forces that are transmitted to the fasteners by the framing members are perpendicular to the longitudinal axes of the fasteners. This phenomenon is apparent in FIGS. 38-40. As can be appreciated from these figures, tensile or compressive forces that may be imposed upon the framing members 1070-1076 due to external forces, such as wind, can only be transmitted to the threaded fasteners 1088 by the flanges of the framing members (the flanges being the elements that are connected to other components) along a direction that is perpendicular to the longitudinal axes of the fasteners. As such, the forces transmitted to the threaded fasteners are shear forces.

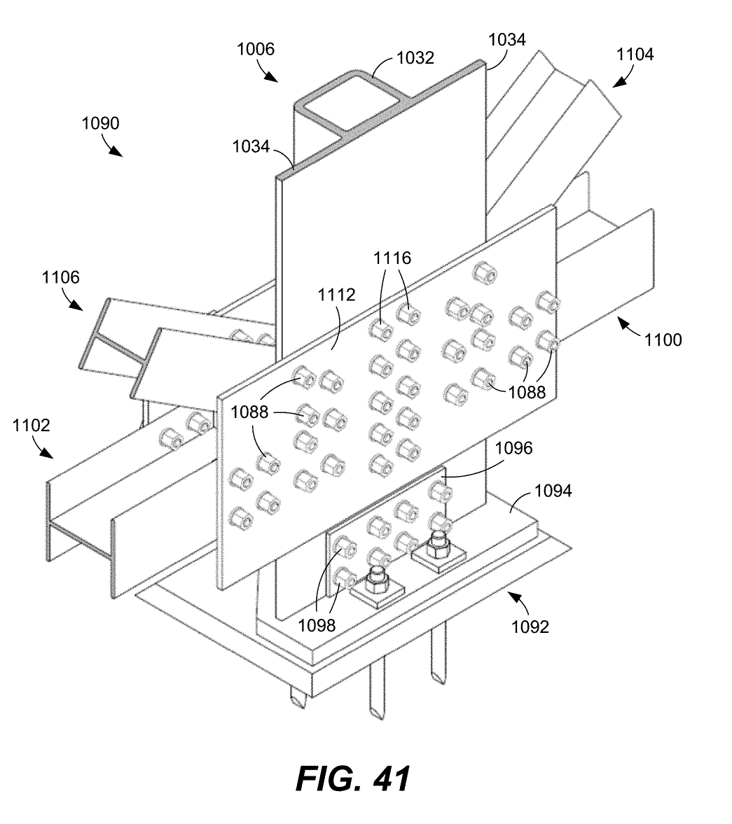

FIGS. 41-43 show an embodiment of a second junction 1090 used in the support structure 530. This type of junction is used at intermediate points between the corners of the truss frame 531 along the bottom of the support structure 530. At the junction 1090, multiple framing members are connected to an intermediate column 1006, which is also mounted to the support slab 510 with an anchorage assembly 1092. The anchorage assembly 1092 includes a horizontal platform 1094 that is bolted to the support slab 510 and multiple vertical plates 1096 that extend upwardly from the platform and are bolted to the corner column 1006 with multiple threaded fasteners 1098. As with the anchorage assembly 1062, the components of the anchorage assembly 1092 can be made of a metal material, such as stainless steel.

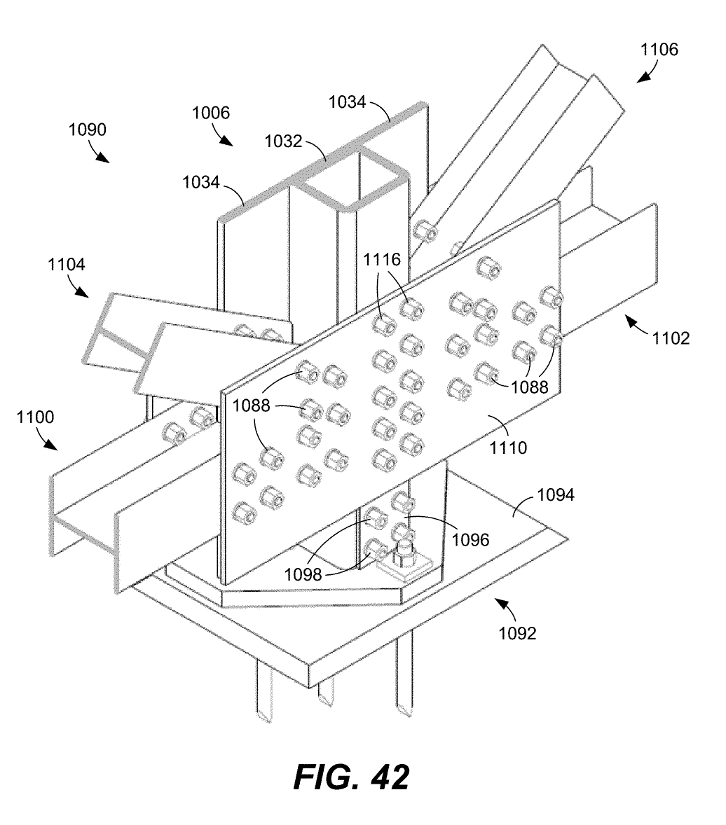

As is most clearly apparent from FIG. 42, the framing members connected to the intermediate column 1006 include two horizontal framing members 1100 and 1102 and two diagonal framing members 1104 and 1106. Each of these framing members 1100-1106 is made of a non-conductive material, such as an FRP composite material, and is configured as an H-beam having two parallel flanges that are joined by a perpendicularly oriented central web. As with the junction 1060, the horizontal framing members 1100, 1102 are slightly wider than the diagonal framing members 1104, 1106 to facilitate their connection to the column 1006.

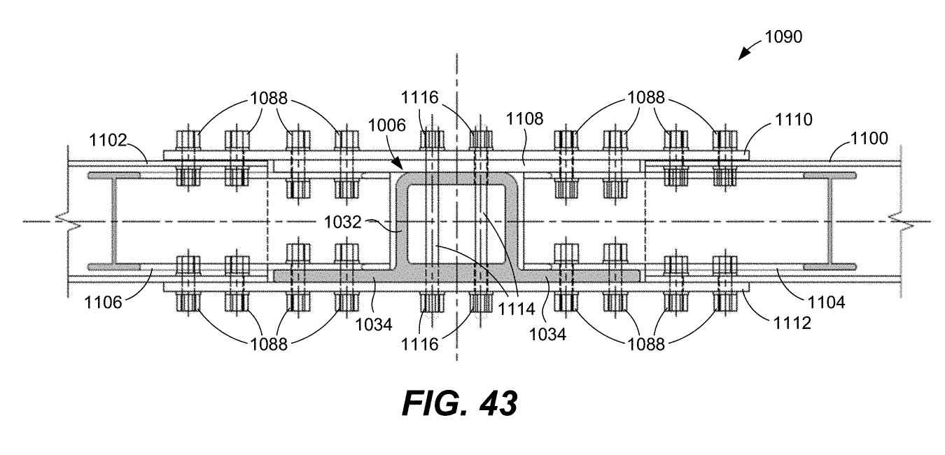

With particular reference to FIG. 43, the framing members 1100-1106 connect to the intermediate column 1006 using the flanges 1034 of the column, a spacer plate 1108, and inner and outer gusset plates 1110 and 1112. Like the other components of the support structure 530, the spacer plate 1108 and gusset plates 1110, 1112 are made of a non-conductive material, such as an FRP composite material. The spacer plate 1108, the inner gusset plate 1110, and the outer gusset plate 1112 are all mounted to the intermediate column 1006 with bolts 1114 that extend through the tubular member 1032 of the intermediate column and nuts 1116 that thread onto the bolts, the bolts and nuts also being made of a non-conductive material, such as an FRP composite material. The flanges of the horizontal framing members 1100, 1102 are connected to the inner sides of the gusset plates 1110, 1112 with fasteners 1088. One flange of each of the diagonal framing members 1104, 1106 is connected to the inner side of the spacer plate 1108, and the other flange of each diagonal framing member is connected to the inner side of one of the flanges 1034 of the intermediate column 1006.

Like junction 1060, the junction 1090 has a layered configuration in which multiple components are layered on top of each other. An example of this layering is the stack comprised of the inner gusset plate 1110, the spacer plate 1108, and the flanges of the horizontal framing members 1104, 1106. Another example is the stack comprised of the outer gusset plate 1112, the flanges 1034 of the intermediate column 1006, and the flanges of the diagonal framing members 1104, 1106. In some embodiments, adhesive is applied between each pair of mating planar surfaces in the junction 1090 prior to fixation using the threaded fasteners 1088 to increase this strength of the junction 1090. As noted above, adhesive can also be provided on the threaded fasteners 1088 and/or nuts 1086 to further increase strength. Again, the threaded fasteners 1088 experience shear forces instead of tensile forces because the forces that are transmitted to the fasteners by the framing members 1100-1106 are perpendicular to the longitudinal axes of the fasteners.

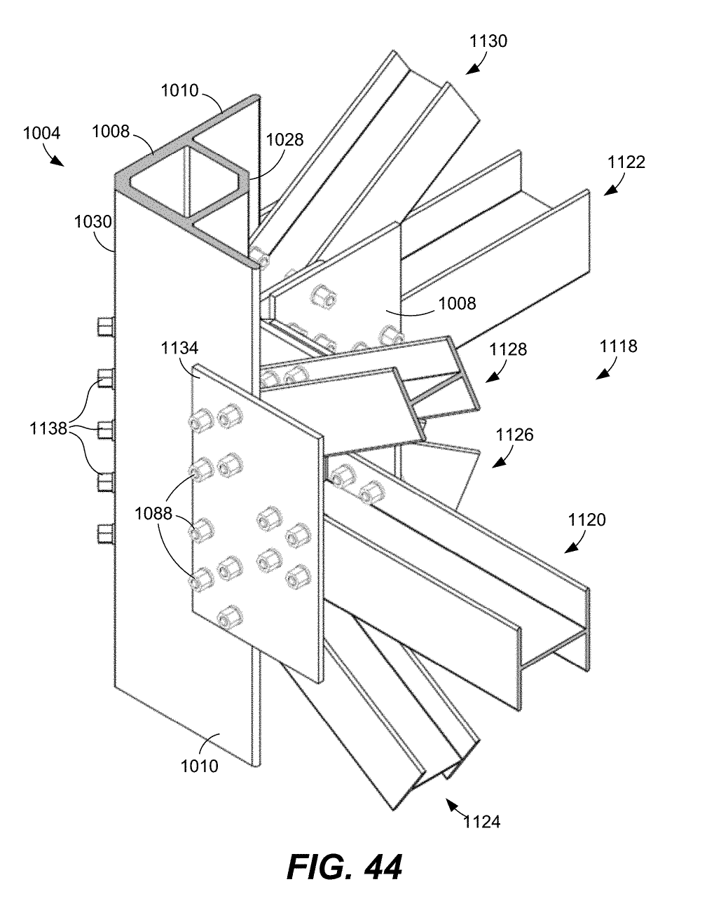

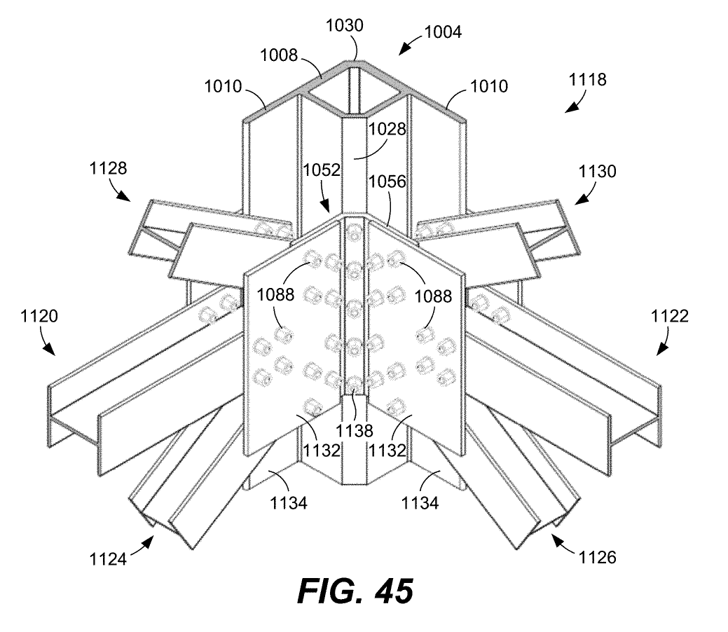

FIGS. 44-46 show an embodiment of a third junction 1118 used in the support structure 530. This type of junction is used at each corner of the truss frame 531 along the medial portion of the support structure 530 above the bottom of the structure but below the transitional truss region 570 of the structure (see FIG. 34). At this junction 1118, multiple framing members connect to a corner column 1004. As is most clearly apparent from FIG. 45, the framing members include two horizontal framing members 1120 and 1122, two lower diagonal framing members 1124 and 1126, and two upper diagonal framing members 1128 and 1130. Each of these framing members 1120-1130 is made of a non-conductive material, such as an FRP composite material, and is configured as an H-beam having two parallel flanges that are joined by a perpendicularly oriented central web. As with other junctions, the horizontal framing members 1120, 1122 are slightly wider than the diagonal framing members 1124-1130 to facilitate their connection to the column 1004.

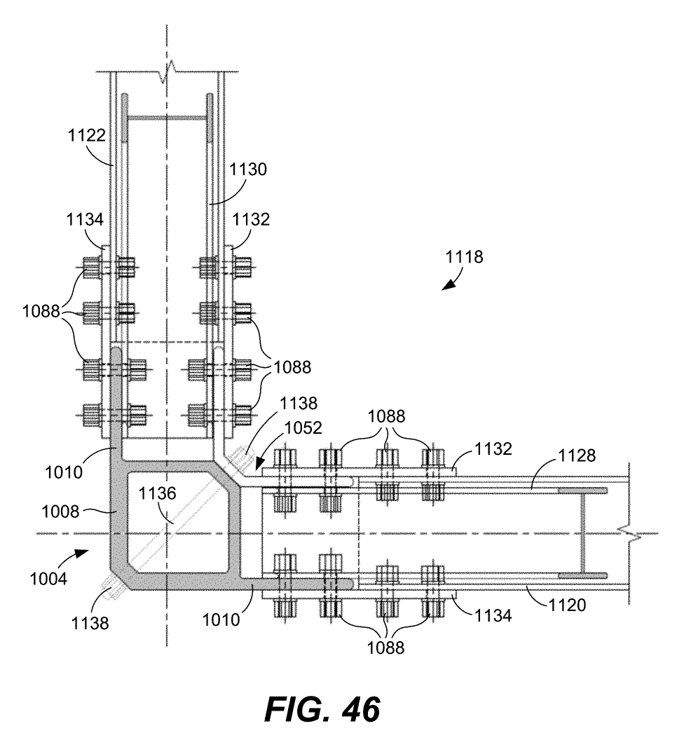

With reference to FIGS. 45 and 46, the framing members 1120-1130 connect to the corner column 1004 using the flanges 1010 of the column, a corner angle member 1052, inner and outer gusset plates 1132 and 1134, and multiple fasteners 1088. The central element 1054 of the corner angle member 1052 is secured to the inner planar outer surface 1028 of the corner column 1004 with bolts 1136 that diagonally pass through the column and multiple nuts 1138 that are threaded onto both ends of the bolts. As with the other junctions, each of these components is made of a non-conductive material, such as an FRP composite material.

The inner gusset plates 1132 are mounted to the inner sides of the angled flanges 1056 of the corner angle member 1052 and the outer gusset plates 1134 are mounted to the outer sides of the flanges 1010 of the corner column 1004. The flanges of the horizontal framing members 1120, 1122 are connected to the inner sides of the gusset plates 1132, 1134, while one flange of each of the diagonal framing members 1124-1130 is connected to the inner side of a flange 1010 of the corner column 1004 and the other flange is connected to the outer side of one of the angled flanges 1056 of the corner angle member 1052.

As with the other junctions, the junction 1118 has a layered configuration in which multiple components are layered on top of each other. An example of this layering is the stack comprised of the inner gusset plates 1132, the angled flanges 1056 of the corner angle member 1052, and the flanges of the diagonal framing members 1124-1130. Another example is the stack comprised of the outer gusset plates 1134, the flanges 1010 of the corner column 1004, and the flanges of the diagonal framing members 1124-1130. In some embodiments, adhesive is applied between each pair of mating planar surfaces in the junction 1118 prior to fixation using the threaded fasteners 1088. As noted above, adhesive can also be provided on the threaded fasteners 1088 and/or nuts 1086 to further increase strength. Again, the threaded fasteners 1088 experience shear forces instead of tensile forces because the forces that are transmitted to the fasteners by the framing members 1120-1130 are perpendicular to the longitudinal axes of the fasteners. It is also noted that the tensile and compressive forces within the diagonal framing members 1124-1130 above and below the centerline of the junction 1118 generally cancel each other out so as to reduce the amount of force that acts on the junction as a whole.

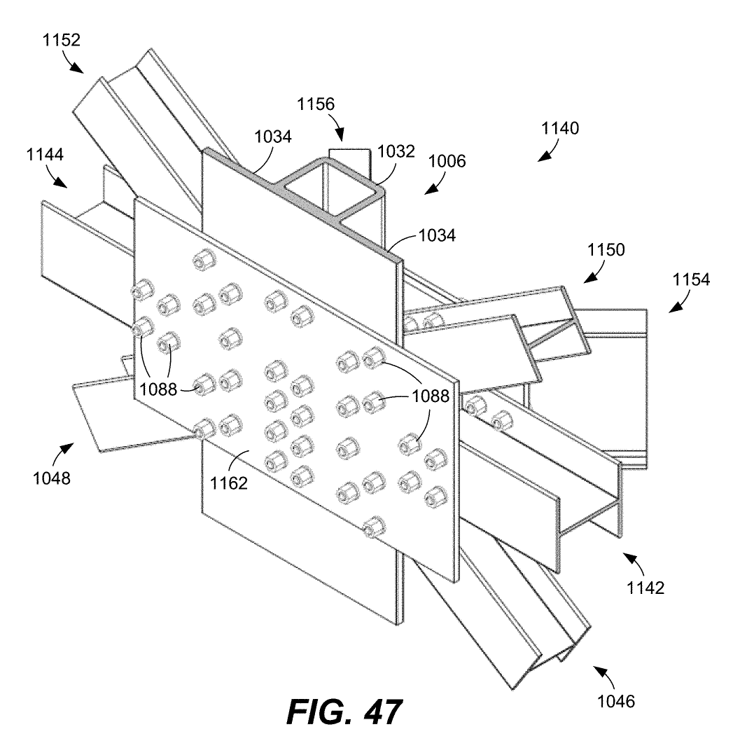

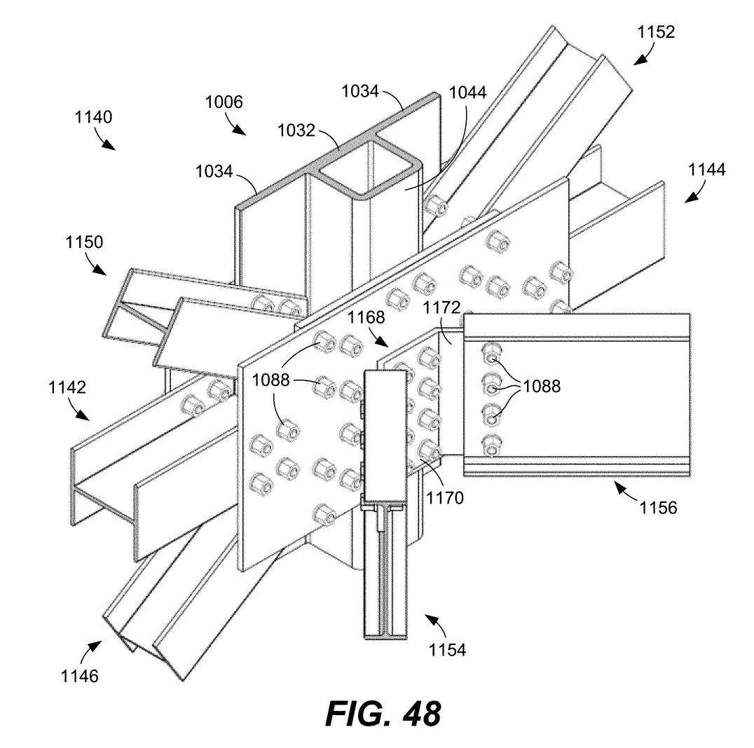

FIGS. 47-49 show an embodiment of a fourth junction 1140 used in the support structure 530. This type of junction is used between the corners of the truss frame 531 along the medial portion of the support structure 530 above the bottom of the structure but below the transitional truss region 570 of the structure (see FIG. 34). Multiple framing members are connected to an intermediate column 1006 at the junction 1140. As is most clearly apparent from FIG. 48, the framing members include two horizontal framing members 1142 and 1144, two lower diagonal framing members 1146 and 1148, and two upper diagonal framing members 1150 and 1152. In addition, there are first and second inwardly extending horizontal framing members 1154 and 1156 that extend into the interior of the support structure 530 from the intermediate column 1006 in opposite directions, each at an angle of approximately 45 degrees.

Each of the framing members 1143-1156 is made of a non-conductive material, such as an FRP composite material, and is configured as an H-beam having two parallel flanges that are joined by a perpendicular central web. While each of the framing members 1142-1152 is oriented within the support structure 530 such that their central webs are generally horizontal as in other junctions described herein, the framing members 1154 and 1156 are oriented such that their central webs are generally vertical. As with other junctions, the horizontal framing members 1142, 1144 are slightly wider than the diagonal framing members 1146-1152 to facilitate their connection to the column 1006.

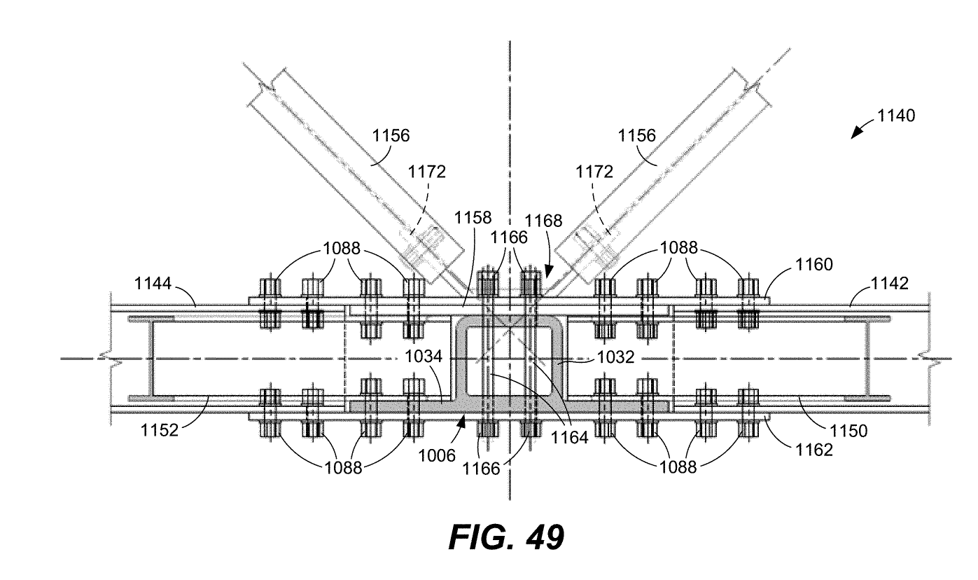

With reference to FIG. 49, the framing members 1142-1152 connect to the intermediate column 1006 using the flanges 1034 of the column, a spacer plate 1158, inner and outer gusset plates 1160 and 1162, and threaded fasteners 1088, each of which is made of a non-conductive material, such as an FRP composite material. The spacer plate 1158, the inner gusset plate 1160, and the outer gusset plate 1162 are all mounted to the intermediate column 1006 with bolts 1164 that extend through the tubular member 1032 of the intermediate column and nuts 1166 that thread onto the bolts, the bolts and nuts also being made of a non-conductive material, such as an FRP composite material. The flanges of the horizontal framing members 1142, 1144 are connected to the inner sides of the gusset plates 1160, 1162. One flange of each of the diagonal framing members 1146-1152 is connected to the inner side of the spacer plate 1158, and the other flange of each diagonal framing member is connected to the inner side of one of the flanges 1034 of the intermediate column 1006. The inwardly extending horizontal framing members 1154, 1156 are each connected to a corner angle member 1168 that, like the corner angle members 1052, includes a central element 1170 and angled flanges 1172. The central element 1170 is mounted to the inner gusset plate 1160 with the bolts 1164 and nuts 1166, and the webs of the framing members 1154, 1156 are secured to the angled flanges 1172 with threaded fasteners 1088.

Like the other junctions, the junction 1140 has a layered configuration in which multiple components are layered on top of each other. An example of this layering is the stack comprised of the central element 1170 of the corner angle member 1168 (see FIG. 48), the inner gusset plate 1160, the spacer plate 1158, and the inner side 1044 of the intermediate column 1006 (see FIG. 48. Another example is the stack comprised of the inner gusset plate 1160, the spacer plate 1158, and the flanges of the horizontal framing members 1146-1152. Yet another example is the stack comprised of the outer gusset plate 1162, the flanges 1034 of the intermediate column 1006, and the flanges of the diagonal framing members 1146-1152. As noted above, adhesive can be applied between each pair of mating planar surfaces in the junction 1140 prior to fixation using the threaded fasteners 1088 to increase strength. As also noted above, adhesive can also be provided on the threaded fasteners 1088 and/or nuts 1086 to further increase strength. Again, the threaded fasteners 1088 experience shear forces instead of tensile forces because the forces that are transmitted to the fasteners by the framing members 1100-1106 are perpendicular to the longitudinal axes of the fasteners. It is also noted that the tensile and compressive forces within the diagonal framing members 1146-1152 above and below the centerline of the junction 1140 generally cancel each other out so as to reduce the amount of force that acts on the junction as a whole.

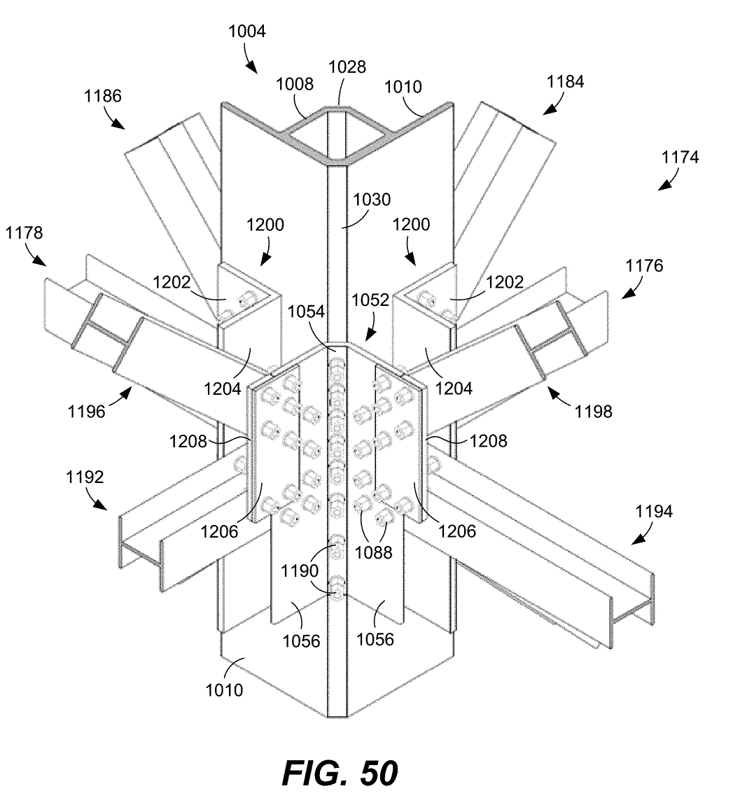

FIGS. 50-52 show an embodiment of a fifth junction 1174 used in the support structure 530. This type of junction is used in the transitional truss region 570 of the support structure and is centered on one of the corner columns 1004 of the truss extension 532 within that region. More particularly, the junction 1174 is used within the top two sections 1000 of the truss frame 531 (see FIG. 34). Multiple framing members connect to the corner column 1004 at this junction 1174 and extend therefrom in both inward and outward directions. As such, these framing members can be designated inner framing members and outer framing members.

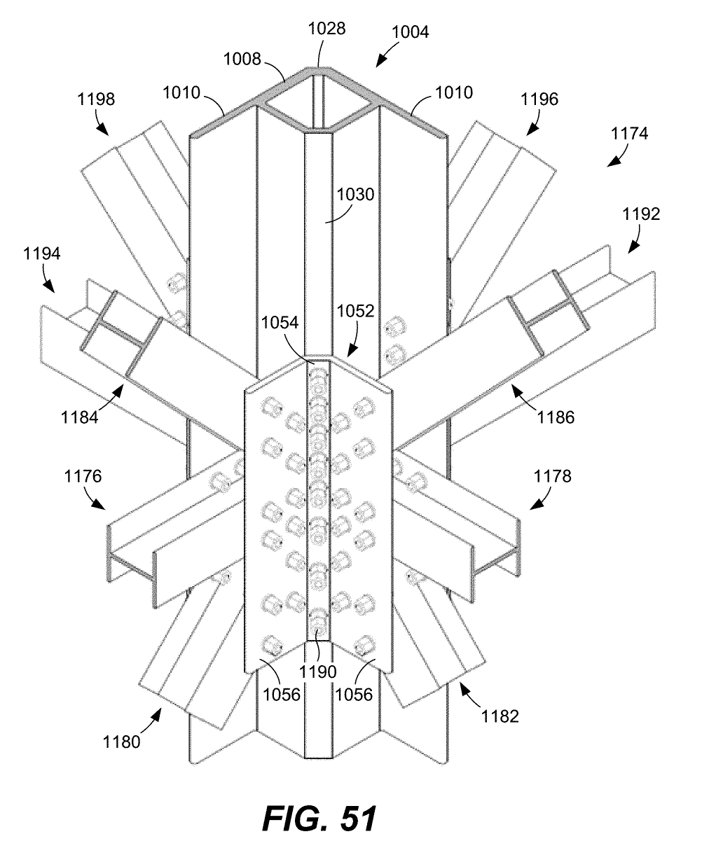

As shown in FIG. 51, the inner framing members include two horizontal framing members 1176 and 1178, two lower diagonal framing members 1180 and 1182, and two upper diagonal framing members 1184 and 1186. Each of these framing members 1176-1186 is made of a non-conductive material, such as an FRP composite material, and is configured as an H-beam having two parallel flanges that are joined by a perpendicularly oriented central web. Unlike other junctions, each of these framing members 1176-1186 is the same width.

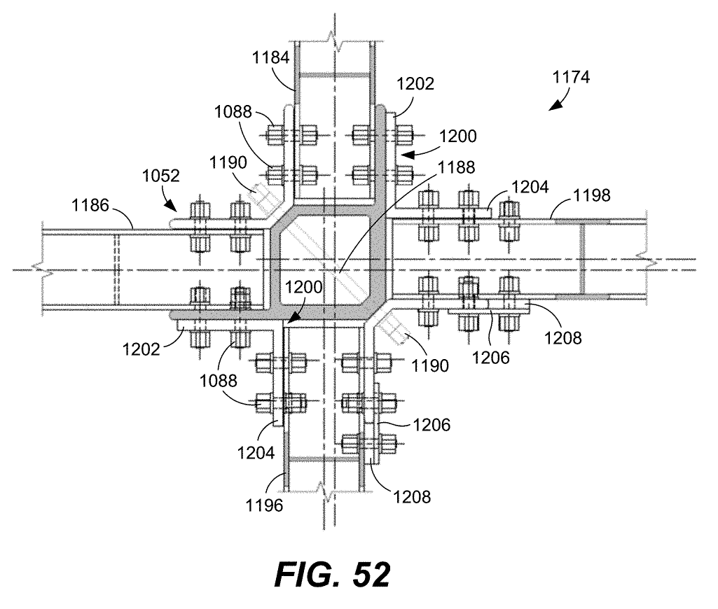

With further reference to FIG. 51, the framing members 1176-1186 connect to the corner column 1004 using the flanges 1010 of the column and a corner angle member 1052. The central element 1054 of the corner angle member 1052 is secured to the inner planar outer surface 1028 of the corner column 1004 with bolts 1188 (see FIG. 52) that diagonally pass through the column and multiple nuts 1190 that are threaded onto both ends of the bolts. As with the other junctions, each of these components is made of a non-conductive material, such as an FRP composite material. One of the flanges of each of the framing members 1176-1186 is connected to an angled flange 1056 of the corner angle member 1052 and the other of the flanges is connected to a flange 1010 of the corner column 1004.

Referring to FIG. 50, the outer framing members include horizontal framing members 1192 and 1194 and upper diagonal framing members 1196 and 1198, each made of a non-conductive material, such as an FRP composite material, and configured as an H-beam having two parallel flanges that are joined by a perpendicularly oriented central web. These framing members 1192-1198 connect to the corner column 1004 using the flanges 1056 of a further corner angle member 1052 whose central element 1054 is secured to the outer planar outer surface 1030 of the corner column 1004 with the bolts 1188 and nuts 1190 identified above. The framing members 1192-1198 are also connected to the corner column 1004 using right-angle corner members 1200 that are attached to the flanges 1010 of the corner column 1004. In particular, first sides 1202 of the corner members 1200 are secured to the outer sides of the flanges 1010 of the corner column 1004 with threaded fasteners 1088 and flanges of the framing members 1192-1198 are connected to second sides 1204 of the corner members with further threaded fasteners 1088. As is further shown in FIG. 50, gusset plates 1206 and spacer plates 1208 can be used with the corner angle member 1052 to increase the number of threaded fasteners that are used to secure the framing members 1192-1198 to the corner column 1004. Again, each of the components is made of a non-conductive material, such as an FRP composite material.

As with the other junctions, the junction 1174 has a layered configuration in which multiple components are layered on top of each other, as is apparent from FIG. 52. An example of this layering is the stack comprised of the gusset plates 1206, the spacer plates 1208, and the flanges of the diagonal framing members 1192-1198. In some embodiments, adhesive is applied between each pair of mating planar surfaces in the junction 1174 prior to fixation using the threaded fasteners 1088 to further increase this strength. As noted above, adhesive can also be provided on the threaded fasteners 1088 and/or nuts 1086 to further increase strength. While the majority of the threaded fasteners 1088 of the junction 1174 experience shear forces instead of tensile forces as in the other junctions described above, it is noted that the fasteners 1088 that secure the right-angle corner members 1200 to the flanges 1010 of the corner column 1004 experience and resist direct tension. It is also noted that the tensile and compressive forces within the diagonal framing members 1180-1186 above and below the centerline of the junction 1174 generally cancel each other out so as to reduce the amount of force that acts on the junction as a whole.

During fabrication of support structure 530, individual parts of the structure can be separately assembled and these parts can later be connected together to form the completed structure in a prefabrication process. As an example, each side of the truss frame 531, or portions thereof, can be separately assembled using a jig or other appropriate structure and, once the side is completed, it can be connected with other sides of the truss frame. When adhesive is used in the construction of the support structure 530, the adhesive can be applied to the appropriate surfaces of the components of the structure and then threaded fasteners can be used to clamp the components together while the adhesive cures. Once the various sides of the support structure have been completed, they can be assembled together using a temporary steel construction tower.

Therefore, the following is claimed:

1. A column for use in constructing a tower structure, the column comprising:
an elongated tubular member; and
two elongated flanges that extend laterally from the tubular member and along a length of the tubular member.

2. The column of claim 1, wherein the elongated tubular member and the elongated flanges are unitarily formed from a single piece of material.

3. The column of claim 1, wherein the elongated tubular member and the elongated flanges are unitarily formed from a single piece of non-conductive material.

4. The column of claim 3, wherein the non-conductive material is a fiber-reinforced polymer (FRP) composite material.

5. The column of claim 1, wherein the elongated tubular member comprises four corners and four sides that together define an elongated inner channel of the tubular member.

6. The column of claim 5, wherein the elongated tubular member is rectangular in cross-section.

7. The column of claim 5, wherein the elongated tubular member is square in cross-section.

8. The column of claim 5, wherein an inner corner and an outer corner of the elongated tubular member are chamfered so as to form two opposed, parallel planar outer surfaces that are orthogonal to the sides of the tubular member.

9. The column of claim 1, wherein the flanges extend from lateral corners of the elongated tubular member in a manner in which one flange generally lies in the same plane as a first outer side of the tubular member and the other flange generally lies in the same plane as a second outer side of the tubular member.

10. The column of claim 9, wherein the elongated flanges are orthogonal to each other.

11. The column of claim 10, wherein outer surfaces of the elongated flanges are located in the same plane as and are continuous with outer surfaces of the outer sides of the elongated tubular member.

12. The column of claim 9, wherein each elongated flange is approximately as wide as its associated outer side.

13. The column of claim 1, wherein the elongated flanges extend from outer corners of the elongated tubular member associated with an outer side of the elongated tubular member.

14. The column of claim 13, wherein the elongated flanges both generally lie in the same plane as the outer side of the elongated tubular member.

15. The column of claim 14, wherein an outer surface of each elongated flange is located in the same plane as and is continuous with an outer surface of the outer side of the elongated tubular member.

16. The column of claim 15, wherein the elongated flanges lie in the same plane.

17. The claim 16, wherein each elongated flange is approximately as wide as the outer side of the elongated tubular member.

18. A corner angle member for use in constructing a tower structure, the member comprising:
a planar central element;
a first planar angled flange extending laterally outward in a first direction from the central element; and
a second planar angled flange extending laterally outward in a second direction from the central element;
wherein the planar central element and the angled flanges are unitarily formed from a single piece of fiber-reinforced polymer (FRP) composite material.

19. The corner angle member of claim 18, wherein the planar angled flanges extend outward from lateral edges of the central element at an angle of approximately 45 degrees and are orthogonal to each other.

20. The corner angle member of claim 18, wherein the planar angled flanges are approximately three times wider than the planar central element.
